(19) United States
(12) Patent Application Publication
(10) Pub. No.: US 2013/0292654 A1
(43) Pub. Date: Nov. 7, 2013

(54) Organic Electroluminescent Element

(71) Applicants: Atsushi Matsunaga, Kanagawa (JP); Toshihiro Ise, Kanagawa (JP)

(72) Inventors: Atsushi Matsunaga, Kanagawa (JP); Toshihiro Ise, Kanagawa (JP)

(73) Assignee: UDC IRELAND LIMITED, Dublin 4 (IE)

(21) Appl. No.: 13/809,073

(22) PCT Filed: Jun. 30, 2011
(86) PCT No.: PCT/JP2011/065123

§ 371 Date: Jul. 3, 2013

(30) Foreign Application Priority Data
Jul. 9, 2010 (JP) 2010-157351

(51) Int. Cl. H01L 51/00

(52) U.S. Cl. CPC H01L 51/0085; H01L 51/0072
USPC 257/40; 252/301.16

(57) ABSTRACT

Disclosed is an organic electroluminescent element that has the characteristic of excellent blue chromaticity, achieves a higher level of both external quantum efficiency and driving durability compared to conventional organic electroluminescent elements, and has a low change in chromaticity before and after driving the element. The organic electroluminescent element has a pair of electrodes and a light-emitting layer between said electrodes on a substrate, and the aforementioned light-emitting layer contains: a carbazole compound having a particular structure; and an iridium complex having a particular structure as a blue phosphorescent light-emitting material.

### TECHNICAL FIELD

The present invention relates to an organic electroluminescence device (hereinafter, also referred to as a “device” or an “organic EL device”), and more particularly, an organic electroluminescence device containing a carbazole compound having a specific structure and an iridium complex having a specific structure as a blue phosphorescent light emitting material.

### BACKGROUND ART

Organic electroluminescence devices are capable of obtaining light emission with high luminance intensity with low voltage driving, and thus have been actively researched and developed. Generally, organic electroluminescence devices are composed of an organic layer including a light emitting layer, and a pair of electrodes having the layer therebetween, and utilize, for light emission, energy of the exciton generated as a result of recombination of electrons injected from a cathode and holes injected from an anode in the light emitting layer.

Improvement in the efficiency of devices has been recently made by using a phosphorescent light emitting material. For example, an organic electroluminescence device having improved light emission efficiency and heat resistance has been studied, using an iridium complex or a platinum complex as a phosphorescent light emitting material.

Further, doping-type devices, which utilize light emitting layers in which a light emitting material is doped in a host material, have been widely employed.

For a light emitting material, Patent Document 1 discloses a blue phosphorescent light emitting material having properties such as high color purity and low power consumption, in which the material is used as a dopant together with a general phosphorescent host material to form a light emitting layer, thereby manufacturing an organic electroluminescence device having high luminent intensity, high efficiency, low driving voltage, high color purity and long life property.

Further, recently, development of host materials has been actively performed, and for example, Patent Document 2 discloses that a compound in which a nitrogen-containing heterocyclic group is bonded to an arylcarbazolyl group or a carbazolylalkylene group, is used as a host material, and discloses that the compound is used as a host material to obtain an organic electroluminescent device with high blue purity.

However, it is required to develop an organic electroluminescent device whose efficiency and durability are compatible with each other at a higher level, while having an excellent property of blue chromaticity.

### RELATED ART

### Patent Document

Patent Document 1: U.S. Patent Application Laid-Open No. 2005/0170209
Patent Document 2: Japanese Patent Application Laid-Open No. 2009-088538

### DISCLOSURE OF INVENTION

### Problems to be Solved by the Invention

The present inventors have found that an organic electroluminescence device whose external quantum efficiency and driving durability are compatible with each other at a higher level compared to the conventional organic electroluminescence devices, while having an excellent property of blue chromaticity, is obtained by using a combination of a carbazole compound having a specific structure and an iridium complex having a specific structure as a blue phosphorescent light emitting material in a light emitting layer.

Further, in the organic electroluminescence device having a configuration of the present invention, in addition to the above-described property, it is found that a property of a small change in chromaticity before and after driving the device is provided. Such properties are not described in Patent Documents 1 and 2.

That is, an object of the present invention is to provide an organic electroluminescence device whose external quantum efficiency and driving durability are compatible with each other at a higher level compared to the conventional organic electroluminescence devices, and which has a small change in chromaticity before and after driving the device, while having an excellent property of blue chromaticity.

Further, another object of the present invention is to provide a light emission apparatus, a display apparatus and an illumination apparatus including the organic electroluminescence device.

### Means for Solving the Problems

That is, the present invention may be accomplished by the following means.

[1] An organic electroluminescence device including a pair of electrodes and a light emitting layer between the electrodes, on a substrate,

in which a compound represented by the following Formula (1) and a compound represented by Formula (E-I) are contained in the light emitting layer.

[Chem. 1]

(Cz)p-L-(A)q (1)

In Formula (1), Cz represents a substituted or unsubstituted arylcarbazolyl group or carbazolylaryl group, L represents a single bond, a substituted or unsubstituted arylene group, a substituted or unsubstituted cycloalkylene group or a substituted or unsubstituted aromatic heterocyclic ring, A represents a substituted or unsubstituted nitrogen-containing 6-membered aromatic heterocyclic ring, and each of p and q independently represents an integer of 1 to 6.

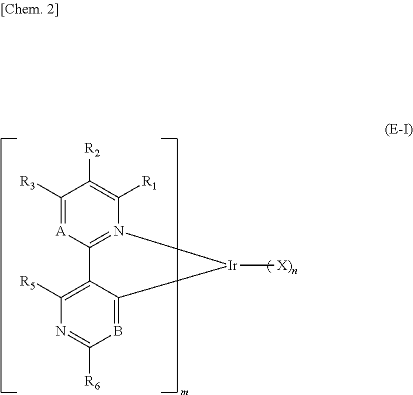

In Formula (E-I), A is C(R₄) or N,

B is C(R₇) or N,

each of R₁ to R₇ is independently a hydrogen atom, a cyano group, a hydroxyl group, a nitro group, a halogen atom, a substituted or unsubstituted alkyl group, a substituted or unsubstituted alkoxy group, a substituted or unsubstituted aryl group, a substituted or unsubstituted aryloxy group, a substituted or unsubstituted arylalkyl group, a substituted or unsubstituted arylalkoxy group, a substituted or unsubstituted arylamino group, a substituted or unsubstituted alkylamino group or a substituted or unsubstituted heterocyclic group, and each of any two or more adjacent substituents selected from the group consisting of R₁ to R₄, R₄ and R₅, and R₆ and R₇ may be linked with each other to form a saturated or unsaturated carbocyclic ring, or a saturated or unsaturated heterocyclic ring,

X is a monoanionic bidentate ligand,

m is 2 or 3, n is 0 or 1, and the sum of m and n is 3.

[2] The organic electroluminescence device of [1], in which the compound represented by Formula (1) is a compound represented by the following Formula (2).

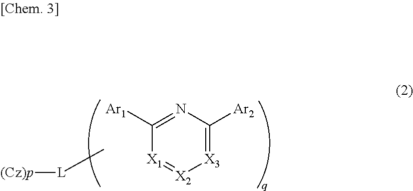

In Formula (2), in the formula, Cz represents a substituted or unsubstituted arylcarbazolyl group or carbazolylaryl group. L represents a single bond, a substituted or unsubstituted arylene group, a substituted or unsubstituted cycloalkylene group or a substituted or unsubstituted aromatic heterocyclic ring, and is linked with a carbon atom of Ar₁, Ar₂, X₁, X₂ or X₃. Each of Ar₁ and Ar₂ independently represents a substituted or unsubstituted aryl group or a substituted or unsubstituted aromatic heterocyclic group, and each of X₁, X₂ or X₃ independently represents a nitrogen atom or a carbon atom having a hydrogen atom or a substituent bonded thereto. Each of p and q independently represents an integer of 1 to 6.

[3] The organic electroluminescence device of [2], in which the compound represented by Formula (2) is a compound represented by the following Formula (3).

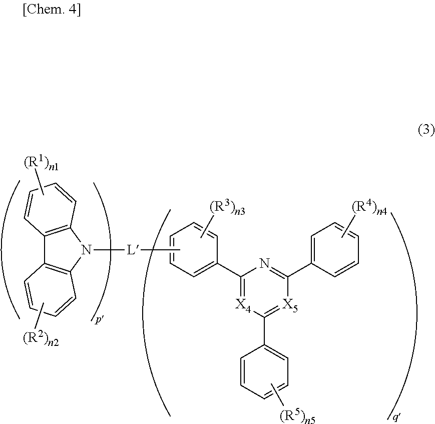

In Formula (3), each of X₄ and X₅ independently represents a nitrogen atom or a carbon atom having a hydrogen atom bonded thereto, and the ring containing X₄ and X₅ is pyridine or pyrimidine. L′ represents a single bond or a phenylene group. Each of R¹ to R⁵ independently represents a fluorine atom, a methyl group, a phenyl group, a cyano group, a pyridyl group, a pyrimidyl group, a silyl group, a carbazolyl group or a tert-butyl group. Each of n1 to n5 independently represents 0 or 1, and each of p′ and q′ independently represents 1 or 2.

[4] The organic electroluminescence device of any one of [1] to [3], in which the compound represented by Formula (E-I) is a compound represented by the following Formula (E-II).

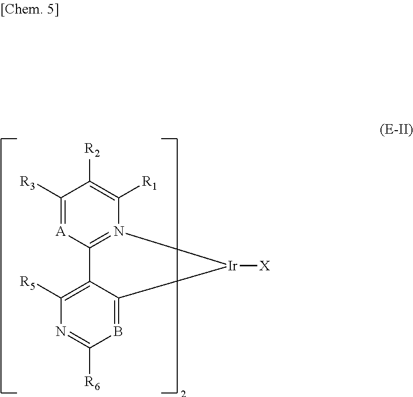

In Formula (E-II), A is C(R₄) or N,

all of R₁, R₂ and R₄ are a hydrogen atom,

R₃ is a hydrogen atom, or an electron donating group selected from the group consisting of a methyl group, a methoxy group, an isopropyl group, a phenyloxy group, a benzyloxy group, a dimethylamino group, a diphenylamino group, a pyrrolidinyl and a phenyl group,

B is C(R₇) or N,

each of R₅, R₆ and R₇ is independently a hydrogen atom, or an electron withdrawing group selected from the group consisting of a fluorine atom, a cyano group, a nitro group, a phenyl group substituted with a fluorine atom or a trifluoromethyl group and a trifluoromethyl group, and

X is selected from the group consisting of acetylacetonate, hexafluoroacetylacetonate, picolinate, salicylanilide, quinolinecarboxylate, 8-hydroxyquinolinate, L-proline, 1,5-dimethyl-3-pyrazolecarboxylate, imineacetylacetonate, dibenzoylmethane, tetramethylheptandionate, 1-(2-hydroxyphenyl)pyrazolate and phenylpyrazole.

[5] The organic electroluminescence device of any one of [1] to [3], in which the compound represented by Formula (E-I) is a compound represented by the following Formula (E-III).

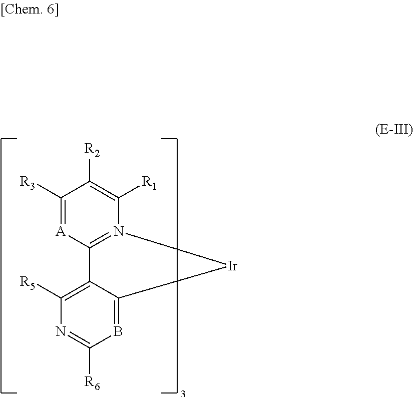

In Formula (E-III), A is C(R₄) or N,

all of R₁, R₂ and R₄ are a hydrogen atom,

R₃ is a hydrogen atom, or an electron donating group selected from the group consisting of a methyl group, a methoxy group, an isopropyl group, a phenyloxy group, a benzyloxy group, a dimethylamino group, a diphenylamino group, a pyrrolidinyl and a phenyl group,

B is C(R₇) or N,

each of R₅, R₆ and R₇ is independently a hydrogen atom, or an electron withdrawing group selected from the group consisting of a fluorine atom, a cyano group, a nitro group, a phenyl group substituted with a fluorine atom or a trifluoromethyl group and a trifluoromethyl group.

[6] The organic electroluminescence device of any one of [1] to [3], in which in Formula (E-I), A is C(R₄) or N, all of R₁, R₂ and R₄ are a hydrogen atom, R₃ is a hydrogen atom, or an electron donating group selected from the group consisting of a methyl group and a dimethylamino group, B is C(R₇) or N, R₅ is a fluorine atom, R₆ is a fluorine atom or a cyano group, R₇ is a hydrogen atom or a cyano group, and X is a monoanionic bidentate ligand selected from the group consisting of acetylacetonate, picolinate and 1,5-dimethyl-3-pyrazolecarboxylate.

[7] The organic electroluminescence device of any one of [1] to [6], in which the sum of the mass concentration of halogen elements selected from the group consisting of bromine, iodine and chlorine, which is contained in any of Formulas (1) to (3) contained in the light emitting layer, is 100 ppm or less.

[8] A light emitting layer containing the compound represented by any one of Formulas (1) to (3) and the compound represented by any one of Formulas (E-I) to (E-III), as described in any one of [1] to [7].

[9] A composition containing the compound represented by any one of Formulas (1) to (3) and the compound represented by any one of Formulas (E-I) to (E-III), as described in any one of [1] to [7].

[10] A light emission apparatus using the organic electroluminescence device of any one of [1] to [7].

[11] A display apparatus using the organic electroluminescence device of any one of [1] to [7].

[12] An illumination apparatus using the organic electroluminescence device of any one of [1] to [7].

Further, the present invention preferably adopts the aspects as follows.

<1> An organic electroluminescence device including a pair of electrodes and a light emitting layer between the electrodes, on a substrate,

in which a compound represented by the following Formula (3) and a compound represented by Formula (E-I) are contained in the light emitting layer.

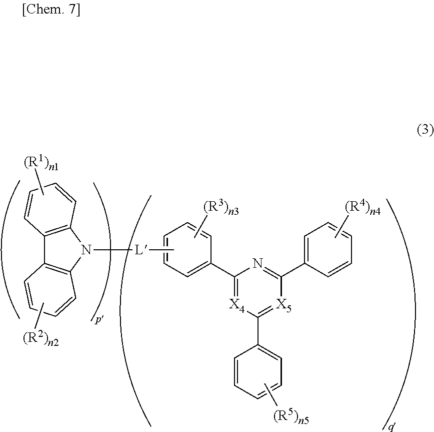

In Formula (3), each of X₄ and X₅ independently represents a nitrogen atom or a carbon atom having a hydrogen atom bonded thereto, and the ring containing X₄ and X₅ is pyridine or pyrimidine. L′ represents a single bond or a phenylene group. Each of R¹ to R⁵ independently represents a fluorine atom, a methyl group, a phenyl group, a cyano group, a pyridyl group, a pyrimidyl group, a silyl group, a carbazolyl group or a tert-butyl group. Each of n1 to n5 independently represents 0 or 1, and each of p′ and q′ independently represents 1 or 2.

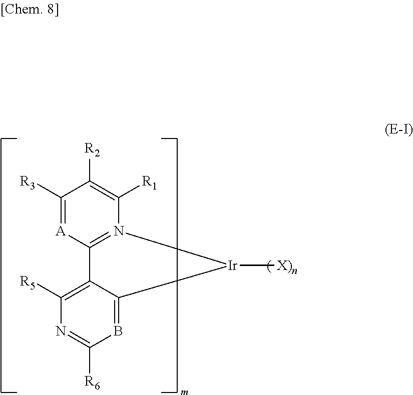

In Formula (E-I), A is C(R₄) or N,

all of R₁, R₂ and R₄ are a hydrogen atom,

R₃ is a hydrogen atom, or an electron donating group selected from the group consisting of a methyl group, a methoxy group, a dimethylamino group, a pyrrolidinyl and a phenyl group,

B is C(R₇) or N,

R₅ is a hydrogen atom or a fluorine atom,

R₆ is a hydrogen atom, a fluorine atom or a cyano group,

R₇ is a hydrogen atom or a cyano group,

X is a monoanionic bidentate ligand selected from the group consisting of acetylacetonate, picolinate, 1,5-dimethyl-3-pyrazolecarboxylate and phenylpyrazole.

m is 2 or 3, n is 0 or 1, and the sum of m and n is 3.

<2> The organic electroluminescence device of <1>, in which the compound represented by Formula (E-I) is a compound represented by the following Formula (E-II).

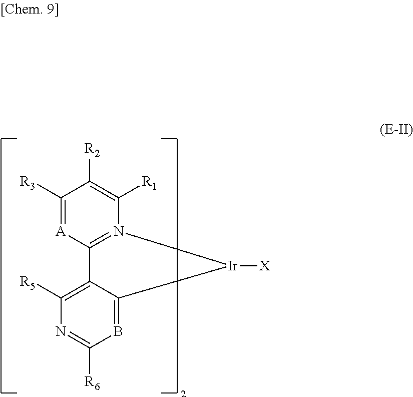

In Formula (E-II), A is C(R₄) or N,

all of R₁, R₂ and R₄ are a hydrogen atom,

R₃ is a hydrogen atom, or an electron donating group selected from the group consisting of a methyl group, a methoxy group, a dimethylamino group, a pyrrolidinyl and a phenyl group,

B is C(R₇) or N,

R₅ is a hydrogen atom or a fluorine atom,

R₆ is a hydrogen atom, a fluorine atom or a cyano group,

R₇ is a hydrogen atom or a cyano group,

X is a monoanionic bidentate ligand selected from the group consisting of acetylacetonate, picolinate, 1,5-dimethyl-3-pyrazolecarboxylate and phenylpyrazole.

<3> The organic electroluminescence device of <1>, in which the compound represented by Formula (E-I) is a compound represented by the following Formula (E-III).

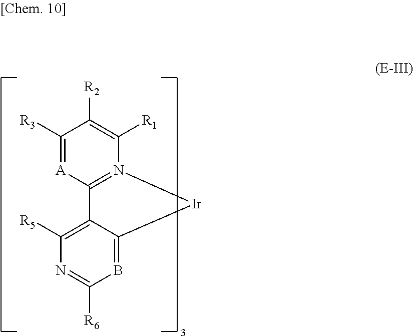

In Formula (E-III), A is C(R₄) or N,

all of R₁, R₂ and R₄ are a hydrogen atom,

R₃ is a hydrogen atom, or an electron donating group selected from the group consisting of a methyl group, a methoxy group, a dimethylamino group, a pyrrolidinyl and a phenyl group,

B is C(R₇) or N,

R₅ is a hydrogen atom or a fluorine atom,

R₆ is a hydrogen atom, a fluorine atom or a cyano group,

R₇ is a hydrogen atom or a cyano group.

<4> The organic electroluminescence device of <1>, in which in Formula (E-I), A is C(R₄) or N, all of R₁, R₂ and R₄ are a hydrogen atom, R₃ is a hydrogen atom, or an electron donating group selected from the group consisting of a methyl group and a dimethylamino group, B is C(R₇) or N, R₅ is a fluorine atom, R₆ is a fluorine atom or a cyano group, R₇ is a hydrogen atom or a cyano group, and X is a monoanionic bidentate ligand selected from the group consisting of acetylacetonate, picolinate and 1,5-dimethyl-3-pyrazolecarboxylate.

<5> The organic electroluminescence device of any one of <1> to <4>, in which the sum of the mass concentration of halogen elements selected from the group consisting of bromine, iodine and chlorine, which is contained in Formula (3) contained in the light emitting layer, is 100 ppm or less.

<6> A light emitting layer containing the compound represented by Formula (3) and the compound represented by any one of Formulas (E-I) to (E-III), as described in any one of <1> to <5>.

<7> A light emission apparatus using the organic electroluminescence device of any one of <1> to <5>.

<8> A display apparatus using the organic electroluminescence device of any one of <1> to <5>.

<9> An illumination apparatus using the organic electroluminescence device of any one of <1> to <5>.

### EFFECTS OF THE INVENTION

According to the present invention, it is possible to provide an organic electroluminescence device whose external quantum efficiency and driving durability are compatible with each other at a higher level compared to the conventional organic electroluminescence devices, and which has a small change in chromaticity before and after driving the device, while having an excellent property of blue chromaticity.

### BRIEF DESCRIPTION OF DRAWINGS

FIG. 1 is a schematic view illustrating an example (first embodiment) of a configuration of an organic electroluminescent device according to the present invention.

FIG. 2 is a schematic view illustrating an example (second embodiment) of a light emission apparatus according to the present invention.

FIG. 3 is a schematic view illustrating an example (third embodiment) of an illumination apparatus according to the present invention.

### EMBODIMENTS FOR CARRYING OUT THE INVENTION

The hydrogen atoms in the explanation of Formulas (1) to (3) and Formulas (E-I) to (E-III) include isotopes (deuterium and the like), and furthermore, atoms constituting a substituent include isotopes thereof.

In the present invention, Groups A of substituents and Substituent Z will be defined as follows.

(Group A of Substituents)

An alkyl group (having preferably 1 to 30 carbon atoms, more preferably 1 to 20 carbon atoms, and particularly preferably 1 to 10 carbon atoms, and examples thereof include methyl, ethyl, isopropyl, t-butyl, n-octyl, n-decyl, n-hexadecyl, cyclopropyl, cyclopentyl, cyclohexyl, neopentyl and the like), an alkenyl group (having preferably 2 to 30 carbon atoms, more preferably 2 to 20 carbon atoms, and particularly preferably 2 to 10 carbon atoms, and examples thereof include vinyl, allyl, 2-butenyl, 3-pentenyl and the like), an alkynyl group (having preferably 2 to 30 carbon atoms, more preferably 2 to 20 carbon atoms, and particularly preferably 2 to 10 carbon atoms, and examples thereof include propargyl, 3-pentynyl and the like), an aryl group (having preferably 6 to 30 carbon atoms, more preferably 6 to 20 carbon atoms, and particularly preferably 6 to 12 carbon atoms, and examples thereof include phenyl, 4-methylphenyl, 2,6-dimethylphenyl and the like), an amino group (having preferably 0 to 30 carbon atoms, more preferably 0 to 20 carbon atoms, and particularly preferably 0 to 10 carbon atoms, and examples thereof include amino, methylamino, dimethylamino, diethylamino, dibenzylamino, diphenylamino, ditolylamino and the like), an alkoxy group (having preferably 1 to 30 carbon atoms, more preferably 1 to 20 carbon atoms, and particularly preferably 1 to 10 carbon atoms, and examples thereof include methoxy, ethoxy, butoxy, 2-ethylhexyloxy and the like), an aryloxy group (having preferably 6 to 30 carbon atoms, more preferably 6 to 20 carbon atoms, and particularly preferably 6 to 12 carbon atoms, and examples thereof include phenyloxy, 1-naphthyloxy, 2-naphthyloxy and the like), a heterocyclic oxy group (having preferably 1 to 30 carbon atoms, more preferably 1 to 20 carbon atoms, and particularly preferably 1 to 12 carbon atoms, and examples thereof include pyridyloxy, pyrazyloxy, pyrimidyloxy, quinolyloxy and the like), an acyl group (having preferably 2 to 30 carbon atoms, more preferably 2 to 20 carbon atoms, and particularly preferably 2 to 12 carbon atoms, and examples thereof include acetyl, benzoyl, formyl, pivaloyl and the like), an alkoxycarbonyl group (having preferably 2 to 30 carbon atoms, more preferably 2 to 20 carbon atoms, and particularly preferably 2 to 12 carbon atoms, and examples thereof include methoxycarbonyl, ethoxycarbonyl and the like), an aryloxycarbonyl group (having preferably 7 to 30 carbon atoms, more preferably 7 to 20 carbon atoms, and particularly preferably having 7 to 12 carbon atoms, and examples thereof include phenyloxycarbonyl and the like), an acyloxy group (having preferably 2 to 30 carbon atoms, more preferably 2 to 20 carbon atoms, and particularly preferably 2 to 10 carbon atoms, and examples thereof include acetoxy, benzoyloxy and the like), an acylamino group (having preferably 2 to 30 carbon atoms, more preferably 2 to 20 carbon atoms, and particularly preferably 2 to 10 carbon atoms, and examples thereof include acetylamino, benzoylamino and the like), an alkoxycarbonylamino group (having preferably 2 to 30 carbon atoms, more preferably 2 to 20 carbon atoms, and particularly preferably 2 to 12 carbon atoms, and examples thereof include methoxycarbonylamino and the like), an aryloxycarbonylamino group (having preferably 7 to 30 carbon atoms, more preferably 7 to 20 carbon atoms, and particularly preferably 7 to 12 carbon atoms, and examples thereof include phenyloxycarbonylamino and the like), a sulfonylamino group (having preferably 1 to 30 carbon atoms, more preferably 1 to 20 carbon atoms, and particularly preferably 1 to 12 carbon atoms, and examples thereof include methanesulfonylamino, benzenesulfonylamino and the like), a sulfamoyl group (having preferably 0 to 30 carbon atoms, more preferably 0 to 20 carbon atoms, and particularly preferably 0 to 12 carbon atoms, and examples thereof include sulfamoyl, methylsulfamoyl, dimethylsulfamoyl, phenylsulfamoyl and the like), a carbamoyl group (having preferably 1 to 30 carbon atoms, more preferably 1 to 20 carbon atoms, and particularly preferably 1 to 12 carbon atoms, and examples thereof include carbamoyl, methylcarbamoyl, diethylcarbamoyl, phenylcarbamoyl and the like), an alkylthio group (having preferably 1 to 30 carbon atoms, more preferably 1 to 20 carbon atoms, and particularly preferably 1 to 12 carbon atoms, and examples thereof include methylthio, ethylthio and the like), an arylthio group (having preferably 6 to 30 carbon atoms, more preferably 6 to 20 carbon atoms, and particularly preferably 6 to 12 carbon atoms, and examples thereof include phenylthio and the like), a heterocyclic thio group (having preferably 1 to 30 carbon atoms, more preferably 1 to 20 carbon atoms, and particularly preferably 1 to 12 carbon atoms, and examples thereof include pyridylthio, 2-benzimidazolylthio, 2-benzoxazolylthio, 2-benzthiazolylthio and the like), a sulfonyl group (having preferably 1 to 30 carbon atoms, more preferably 1 to 20 carbon atoms, and particularly preferably 1 to 12 carbon atoms, and examples thereof include mesyl, tosyl and the like), a sulfinyl group (having preferably 1 to 30 carbon atoms, more preferably 1 to 20 carbon atoms, and particularly preferably 1 to 12 carbon atoms, and examples thereof include methanesulfinyl, benzenesulfinyl and the like), a ureido group (having preferably 1 to 30 carbon atoms, more preferably 1 to 20 carbon atoms, and particularly preferably 1 to 12 carbon atoms, and examples thereof include ureido, methylureido, phenylureido and the like), a phosphoric acid amide group (having preferably 1 to 30 carbon atoms, more preferably 1 to 20 carbon atoms, and particularly preferably 1 to 12 carbon atoms, and examples thereof include diethylphosphoric acid amide, phenylphosphoric acid amide and the like), a hydroxyl group, a mercapto group, a halogen atom (for example, a fluorine atom, a chlorine atom, a bromine atom and an iodine atom), a cyano group, a sulfo group, a carboxyl group, a nitro group, a hydroxamic acid group, a sulfino group, a hydrazino group, an imino group, a heterocyclic group (also includes an aromatic heterocyclic group, having preferably 1 to 30 carbon atoms, and more preferably 1 to 12 carbon atoms, and examples of the hetero atom include a nitrogen atom, an oxygen atom, a sulfur atom, a phosphorus atom, a silicon atom, a selenium atom and a tellurium atom, and specifically pyridyl, pyrazinyl, pyrimidyl, pyridazinyl, pyrrolyl, pyrazolyl, triazolyl, imidazolyl, oxazolyl, thiazolyl, isoxazolyl, isothiazolyl, quinolyl, furyl, thienyl, selenophenyl, tellurophenyl, piperidyl, piperidino, morpholino, pyrrolidyl, pyrrolidino, benzoxazolyl, benzoimidazolyl, benzothiazolyl, a carbazolyl group, an azepinyl group and the like), a silyl group (having preferably 3 to 40 carbon atoms, more preferably 3 to 30 carbon atoms, and particularly preferably 3 to 24 carbon atoms, and examples thereof include trimethylsilyl, triphenylsilyl and the like), a silyloxy group (having preferably 3 to 40 carbon atoms, more preferably 3 to 30 carbon atoms, and particularly preferably 3 to 24 carbon atoms, and examples thereof include trimethylsilyloxy, triphenylsilyloxy and the like) and a phosphoryl group (examples thereof include diphenylphosphoryl, dimethylphosphoryl and the like). These substituents may be further substituted, and examples of a further substituent include groups selected from Group A of substituents as described above.

(Substituent Z)

Substituent Z represents an alkyl group, alkenyl group, aryl group, aromatic heterocyclic group, alkoxy group, aryloxy group, fluorine atom, silyl group, amino group, cyano group or a combination thereof, and a plurality of Substituents Z may be bonded to each other to form an aryl ring.

The alkyl group represented by Substituent Z is an alkyl group preferably having 1 to 8 carbon atoms, more preferably 1 to 6 carbon atoms, and examples thereof include a methyl group, an ethyl group, an n-propyl group, an isopropyl group, an isobutyl group, a t-butyl group, an n-butyl group, a cyclopropyl group and the like, preferably a methyl group, an ethyl group, an isobutyl group or a t-butyl group, and more preferably a methyl group.

The alkenyl group represented by Substituent Z is an alkenyl group preferably having 2 to 8 carbon atoms, more preferably 2 to 6 carbon atoms, and examples thereof include a vinyl group, an n-propenyl group, an isopropenyl group, an isobutenyl group, an n-butenyl group and the like, preferably a vinyl group or an n-propenyl group, and more preferably a vinyl group.

The aryl group represented by Substituent Z is an aryl group preferably having 6 to 18 carbon atoms, more preferably 6 to 12 carbon atoms, examples thereof include a phenyl group, a biphenyl group, a naphthyl group, a tolyl group, z xylyl group and the like, and among them, a phenyl and a biphenyl group are preferred, and a phenyl group is more preferred.

The aromatic heterocyclic group represented by Substituent Z is an aromatic heterocyclic group preferably having 4 to 12 carbon atoms, and examples thereof include a pyridyl group, a furyl group, a thienyl group and the like, preferably a pyridyl group or a furyl group, and more preferably a pyridyl group.

The alkoxy group represented by Substituent Z is an alkoxy group preferably having 1 to 8 carbon atoms, more preferably 1 to 4 carbon atoms, and examples thereof include a methoxy group, an ethoxy group, an n-propyloxy group, an isopropyloxy group, an isobutoxy group, a t-butoxy group, an n-butoxy group, a cyclopropyloxy group and the like, preferably a methoxy group, an ethoxy group, an isobutoxy group or a t-butoxy group, and more preferably a methoxy group.

The silyl group and the amino group represented by Substituent Z may include the same silyl group and the same amino group in Group A of substituents.

The aryl group fanned by a plurality of substituents Z bound with each other may include a benzene ring, a naphthalene ring and the like, preferably a benzene ring.

The organic electroluminescence device of the present invention is an organic electroluminescence device including a pair of electrodes and a light emitting layer between the electrodes, on a substrate, in which a compound represented by the following Formula (1) and a compound represented by Formula (E-I) are contained in the light emitting layer.

Although it is not clear why an organic electroluminescence device whose external quantum efficiency and driving durability are compatible with each other at a higher level compared to the conventional organic electroluminescence devices, and which has a small change in chromaticity before and after driving the device, while having an excellent property of blue chromaticity, is obtained by the configuration of the present invention using a combination of the compound represented by Formula (1) and the compound represented by Formula (E-I) in the light emitting layer, it is assumed as follows.

Although the compound represented by Formula (E-I) makes it possible to provide an organic electroluminescence device of deep blue chromaticity, it is considered that deterioration in external quantum efficiency and driving durability due to the association of the compounds, which are an emitter, among themselves, and a large change in chromaticity due to a change in light emission position (exciton producing position) with the lapse of device driving time have been generated in the conventional devices using the compound. Meanwhile, in the present invention, by using the compound represented by Formula (E-I) in combination with a specific host material, that is, the compound represented by Formula (1), it is supposed that some effects are obtained, in which the above-mentioned association of emitters or change in light emission position is suitably suppressed, and in the organic electroluminescence device of deep blue chromaticity, the external quantum efficiency and driving durability are further enhanced, compared to the conventional devices, and a small change in chromaticity before and after driving the device. Further, the effect of the small change in chromaticity before and after driving the device cannot be expected from the conventional devices at all.

[Compound Represented by Formula (E-I)]

Hereinafter, the compound represented by Formula (E-I) will be described.

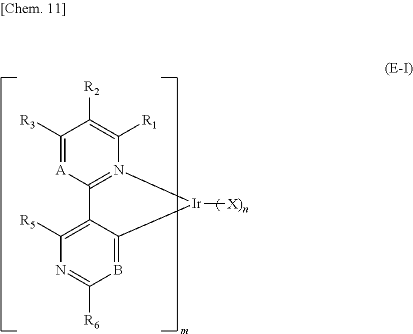

In Formula (E-I), A is C(R₄) or N,

B is C(R₇) or N,

each of R₁ to R₇ is independently a hydrogen atom, a cyano group, a hydroxyl group, a nitro group, a halogen atom, a substituted or unsubstituted alkyl group, a substituted or unsubstituted alkoxy group, a substituted or unsubstituted aryl group, a substituted or unsubstituted aryloxy group, a substituted or unsubstituted arylalkyl group, a substituted or unsubstituted arylalkoxy group, a substituted or unsubstituted arylamino group, a substituted or unsubstituted alkylamino group or a substituted or unsubstituted heterocyclic group, and each of any two or more adjacent substituents selected from the group consisting of R₁ to R₄, R₄ and R₅, and R₆ and R₇ may be linked with each other to form a saturated or unsaturated carbocyclic ring, or a saturated or unsaturated heterocyclic ring,

X is a monoanionic bidentate ligand,

m is 2 or 3, n is 0 or 1, and the sum of m and n is 3.

When the substituted or unsubstituted alkyl group represented by R₁ to R₇ has a substituent, the substituent may be exemplified by Substituent Z as described above, and Substituent Z is preferably a fluorine atom. The substituted or unsubstituted alkyl group represented by R₁ to R₇ is preferably an alkyl group having 1 to 20 carbon atoms, more preferably 1 to 12 carbon atoms, and still more preferably 1 to 6 carbon atoms.

When the substituted or unsubstituted alkoxy group represented by R₁ to R₇ has a substituent, the substituent may be exemplified by Substituent Z as described above, and Substituent Z is preferably a fluorine atom. The substituted or unsubstituted alkoxy group represented by R₁ to R₇ is preferably an alkoxy group having 1 to 20 carbon atoms, more preferably 1 to 12 carbon atoms, and still more preferably 1 to 6 carbon atoms.

When the substituted or unsubstituted aryl group represented by R₁ to R₇ has a substituent, the substituent may be exemplified by Substituent Z as described above, and Substituent Z is preferably an alkyl group or a fluorine atom. The substituted or unsubstituted aryl group represented by R₁ to R₇ is preferably an aryl group having 6 to 20 carbon atoms, more preferably 6 to 18 carbon atoms, and still more preferably 6 to 12 carbon atoms.

The aryl group in the substituted or unsubstituted aryloxy group represented by R₁ to R₇ is the same as the substituted or unsubstituted aryl group represented by R₁ to R₇ as described above.

The aryl group and the alkyl group in the substituted or unsubstituted arylalkyl group represented by R₁ to R₇ are the same as the substituted or unsubstituted aryl group and the substituted or unsubstituted alkyl group represented by R₁ to R₇, respectively, as described above. The substituted or unsubstituted arylalkyl group represented by R₁ to R₇ is preferably an arylalkyl group having 7 to 20 carbon atoms, more preferably 7 to 18 carbon atoms, and still more preferably 7 to 12 carbon atoms.

The aryl group and the alkoxy group in the substituted or unsubstituted arylalkoxy group represented by R₁ to R₇ are the same as the substituted or unsubstituted aryl group and the substituted or unsubstituted alkoxy group represented by R₁ to R₇, respectively, as described above. The substituted or unsubstituted arylalkoxy group represented by R₁ to R₇ is preferably an arylalkoxy group having 7 to 20 carbon atoms, more preferably 7 to 18, and still more preferably 7 to 12.

When the substituted or unsubstituted arylamino group represented by R₁ to R₇ has a substituent, the substituent may be exemplified by Substituent Z as described above, and Substituent Z is preferably an alkyl group or a fluorine atom. The aryl group in the substituted or unsubstituted arylamino group represented by R₁ to R₇ is the same as the substituted or unsubstituted aryl group represented by R₁ to R₇ as described above, and the substituted or unsubstituted arylamino group represented by R₁ to R₇ is preferably an arylamino group having 6 to 20 carbon atoms, more preferably 6 to 18 carbon atoms, and still more preferably 6 to 12 carbon atoms. The substituted or unsubstituted arylamino group represented by R₁ to R₇ is preferably a substituted or unsubstituted diarylamino group.

When the substituted or unsubstituted alkylamino group represented by R₁ to R₇ has a substituent, the substituent may be exemplified by Substituent Z as described above, and Substituent Z is preferably a fluorine atom. The alkyl group in the substituted or unsubstituted alkylamino group represented by R₁ to R₇ is the same as the alkyl group represented by R₁ to R₇ as described above, and the substituted or unsubstituted alkylamino group represented by R₁ to R₇ is preferably an alkylamino group having 1 to 20 carbon atoms, more preferably 1 to 12 carbon atoms, still more preferably 1 to 6 carbon atoms. The substituted or unsubstituted alkylamino group represented by R₁ to R₇ is preferably a substituted or unsubstituted dialkylamino group.

When the substituted or unsubstituted heterocyclic group represented by R₁ to R₇ has a substituent, the substituent may be exemplified by Substituent Z as described above, and Substituent Z is preferably an alkyl group or a fluorine atom. The substituted or unsubstituted heterocyclic group represented by R₁ to R₇ is preferably a heterocyclic group having 2 to 20 carbon atoms, more preferably 4 to 12, still more preferably 4 to 6 carbon atoms.

The saturated or unsaturated carbocyclic ring formed by any two or more adjacent substituents selected from the group consisting of R₁ to R₄, R₄ and R₅, or R₆ and R₇ linked with each other has preferably 3 to 20 carbon atoms, and more preferably 5 to 12 carbon atoms.

The saturated or unsaturated heterocyclic ring formed by any two or more adjacent substituents selected from the group consisting of R₁ to R₄, R₄ and R₅, or R₆ and R₇ linked with each other has preferably 2 to 20 carbon atoms, and more preferably 4 to 12 carbon atoms.

In Formula (E-I), X is a monoanionic bidentate ligand, and particular examples thereof preferably include those selected from the group consisting of acetylacetonate (acac), hexafluoroacetylacetonate (hfacac), picolinate (pic), salicylanilide (sal), quinolinecarboxylate (quin), 8-hydroxyquinolinate (hquin), L-proline (L-pro), 1,5-dimethyl-3-pyrazolecarboxylate (dm3 pc), imineacetylacetonate (imineacac), dibenzoylmethane (dbm), tetramethylheptandionate (tmd), 1-(2-hydroxyphenyl)pyrazolate (oppz), phenylpyrazole (ppz) and tetrakispyrazolylborate (pz₂ Bpz₂) as shown below.

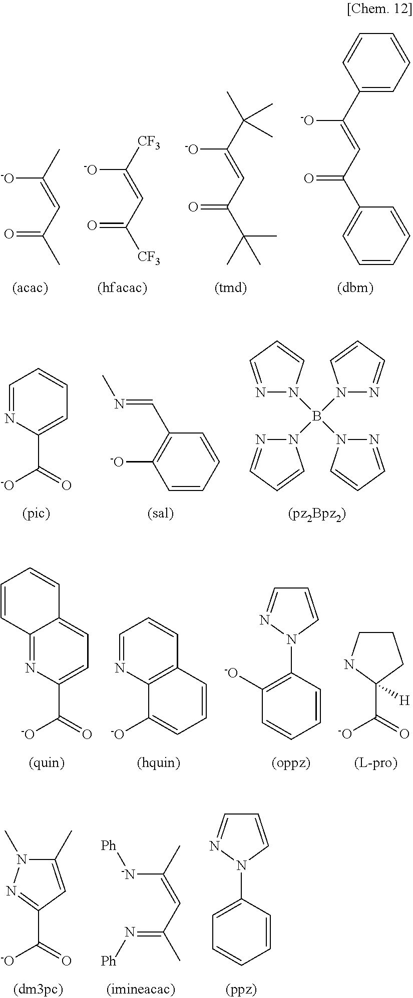

In Formula (E-I), it is preferred that A is C(R₄) or N, all of R₁, R₂ and R₄ are a hydrogen atom, R₃ is a hydrogen atom, or an electron donating group selected from the group consisting of a methyl group, a methoxy group, an isopropyl group, a phenyloxy group, a benzyloxy group, a dimethylamino group, a diphenylamino group, a pyrrolidinyl group and a phenyl group, B is C(R₇) or N, and R₅, R₆ and R₇ are a hydrogen atom, or an electron withdrawing group selected from the group consisting of a fluorine atom, a cyano group, a nitro group, a phenyl group substituted with a fluorine atom or a trifluoromethyl group, and a trifluoromethyl group.

More preferably, in Formula (E-I), A is C(R₄) or N, all of R₁, R₂ and R₄ are a hydrogen atom, R₃ is a hydrogen atom, or an electron donating group selected from the group consisting of a methyl group, a methoxy group, a dimethylamino group, a pyrrolidinyl group and a phenyl group, B is C(R₇) or N, R₅ is a hydrogen atom or a fluorine atom, R₆ is a hydrogen atom, a fluorine atom or a cyano group, R₇ is a hydrogen atom or a cyano group, and X is a monoanionic bidentate ligand selected from the group consisting of acetylacetonate (acac), picolinate (pic), 1,5-dimethyl-3-pylazolecarboxylate (dm3 pc) and phenylpyrazole (ppz).

Still more preferably, in Formula (E-I), A is C(R₄) or N, all of R₁, R₂ and R₄ are a hydrogen atom, R₃ is a hydrogen atom, or an electron donating group selected from the group consisting of a methyl group and a dimethylamino group, B is C(R₇) or N, R₅ is a fluorine atom, R₆ is a fluorine atom or a cyano group, R₇ is a hydrogen atom or a cyano group, and X is acetylacetonate (acac), picolinate (pic) and 1,5-dimethyl-3-pylazolecarboxylate (dm3 pc).

In the present invention, the iridium compound represented by Formula (E-I) may be classified as a blue phosphorescent compound of the following Formula (E-II) or (E-III) by the combination of m and n.

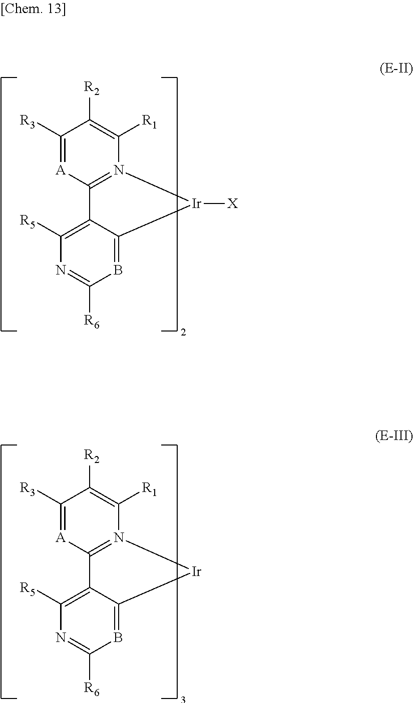

In Formula (E-II) and (E-III),

A is C(R₄) or N,

B [symbol] , C(R₇) or N,

each of R₁ to R₇ independently represents a hydrogen atom, a cyano group, a hydroxyl group, a nitro group, a halogen atom, a substituted or unsubstituted alkyl group, a substituted or unsubstituted alkoxy group, a substituted or unsubstituted aryl group, a substituted or unsubstituted aryloxy group, a substituted or unsubstituted arylalkyl group, a substituted or unsubstituted arylalkoxy group, a substituted or unsubstituted arylamino group, a substituted or unsubstituted alkylamino group or a substituted or unsubstituted heterocyclic group, and each of any two or more adjacent substituents selected from the group consisting of R₁ to R₄, R₄ and R₅, and R₆ and R₇ may be linked with each other to form a saturated or unsaturated carbocyclic ring, or a saturated or unsaturated heterocyclic ring,

X is a monoanionic bidentate ligand.

Specific examples and preferred ranges of A, B, R₁ to R₇ and X in Formula (E-II) and (E-III) are the same as the specific examples and preferred ranged of those in Formula (E-I).

In Formula (E-II) or (E-III), preferably, A is C(R₄) or N, all of R₁, R₂ and R₄ are a hydrogen atom, R₃ is a hydrogen atom, or an electron donating group selected from the group consisting of a methyl group, a methoxy group, an isopropyl group, a phenyloxy group, a benzyloxy group, a dimethylamino group, a diphenylamino group, a pyrrolidinyl group and a phenyl group, B is C(R₇) or N, each of R₅, R₆ and R₇ is independently a hydrogen atom, or an electron withdrawing group selected from the group consisting of a fluorine atom, a cyano group, a nitro group, a phenyl group substituted with a fluorine atom or a trifluoromethyl group, and a trifluoromethyl group, and X is selected from the group consisting of acetylacetonate (acac), hexafluoroacetylacetonate (hfacac), picolinate (pic), salicylanilide (sal), quinolinecarboxylate (quin), 8-hydroxyquinolinate (hquin), L-proline (L-pro), 1,5-dimethyl-3-pyrazolecarboxylate (dm3 pc), imineacetylacetonate (imineacac), dibenzoylmethane (dbm), tetramethylheptandionate (tmd), 1-(2-hydroxyphenyl)pyrazolate (oppz), phenylpyrazole (ppz) and tetrakispyrazolylborate (pz₂Bpz₂).

In Formula (E-II), more preferably, A is C(R₄) or N, all of R₁, R₂ and R₄ is a hydrogen atom, R₃ is a hydrogen atom, or an electron donating group selected from the group consisting of a methyl group, a methoxy group, a dimethylamino group, a pyrrolidinyl group and a phenyl group, B is C(R₇) or N, R₅ is a hydrogen atom or a fluorine atom, R₆ is a hydrogen atom, a fluorine atom or a cyano group, R₇ is a hydrogen atom or a cyano group, X is a monoanionic bidentate selected from the group consisting of acetylacetonate(acac), picolinate(pic), 1,5-dimethyl-3-pylazolecarboxylate (dm3 pc) and phenylpyrazole (ppz).

In Formula (E-II), still more preferably, A is C(R₄) or N, all of R₁, R₂ and R₄ are a hydrogen atom, R₃ is a hydrogen atom or a methyl group, B is C(R₇) or N, R₅ is a fluorine atom, R₆ is a fluorine atom or a cyano group, R₇ is a hydrogen atom or a cyano group, and X a monoanionic bidentate ligand selected from the group consisting of acetylacetonate (acac), picolinate (pic) and 1,5-dimethyl-3-pylazolecarboxylate (dm3 pc).

Further, in Formula (E-III), more preferably, A is C(R₄) or N, all of R₁, R₂ and R₄ are a hydrogen atom, R₃ is a hydrogen atom, or an electron donating group selected from the group consisting of a methyl group, a methoxy group, a dimethylamino group, a pyrrolidinyl group and a phenyl group, B is C(R₇) or N, R₅ is a hydrogen atom or a fluorine atom, R₆ is a hydrogen atom, a fluorine atom or a cyano group, and R₇ is a hydrogen atom or a cyano group.

In Formula (E-III), still more preferably, A is C(R₄) or N, all of R₁, R₂ and R₄ are a hydrogen atom, R₃ is a hydrogen atom, or an electron donating group selected from the group consisting of a methyl group and a dimethylamino group, B is C(R₇) or N, R₅ is a fluorine atom, R₆ is a fluorine atom or a cyano group, and R₇ is a hydrogen atom.

In Formula (E-I) to (E-III), when A is C(R₄) or N, and R₁, R₂ and R₄ are a hydrogen atom, then, R₃ is a hydrogen atom, or an electron donating group selected from the group consisting of a methyl group, a methoxy group, an isopropyl group, a phenyloxy group, a benzyloxy group, a dimethylamino group, a diphenylamino group, a pyrrolidinyl group and a phenyl group, B is C(R₇) or N, R₅, R₆ and R₇ are a hydrogen atom, or may form an electron withdrawing group selected from the group consisting of a fluorine atom, a cyano group, a nitro group, a phenyl group substituted with a fluorine atom or a trifluoromethyl group, and a trifluoromethyl group.

Representative examples of the compound represented by Formula (E-I) as described above include preferably Compound (19), Compound (33), Compound (136), Compound (138), Compound (142) and the like used in Examples as described below.

Further, as specific examples of the compounds, preferred combinations of A, B, R₁ to R₇ and X are shown in the following tables.

Further, in the following tables, “C” as described as A refers to a group represented by C(R₄) and, “C” as described as B refers to a group represented by C(R₇).

TABLE 1

| Com- | | | | | | | | | | |
|---|---|---|---|---|---|---|---|---|---|---|
| pound | A | B | R₁ | R₂ | R₃ | R₄ | R₅ | R₆ | R₇ | X |
| 1 | C | C | H | H | H | H | F | H | H | acac |
| 2 | C | C | H | H | H | H | F | F | H | acac |
| 3 | C | C | H | H | H | H | F | F | CN | acac |
| 4 | C | C | H | H | Methyl group | H | F | H | H | acac |
| 5 | C | C | H | H | Methyl group | H | F | F | H | acac |
| 6 | C | C | H | H | Methyl group | H | F | F | CN | acac |
| 7 | C | C | H | H | Dimethylamino | H | F | H | H | acac |
| | | | | | group | | | | | |
| 8 | C | C | H | H | Dimethylamino | H | F | F | H | acac |
| | | | | | group | | | | | |
| 9 | C | C | H | H | Pyrrolidinyl | H | F | H | H | acac |
| | | | | | group | | | | | |
| 10 | C | C | H | H | Pyrrolidinyl | H | F | F | H | acac |
| | | | | | group | | | | | |
| 11 | C | C | H | H | Phenyl group | H | F | H | H | acac |
| 12 | C | C | H | H | Phenyl group | H | F | F | H | acac |
| 13 | C | C | H | H | CH₃O | H | F | H | H | acac |
| 14 | C | C | H | H | CH₃O | H | F | F | H | acac |
| 15 | C | C | H | H | H | H | F | H | H | pic |
| 16 | C | C | H | H | H | H | F | F | H | pic |
| 17 | C | C | H | H | H | H | F | F | CN | pic |
| 18 | C | C | H | H | Methyl group | H | F | H | H | pic |
| 19 | C | C | H | H | Methyl group | H | F | F | H | pic |
| 20 | C | C | H | H | Methyl group | H | F | F | CN | pic |
| 21 | C | C | H | H | Dimethylamino | H | F | H | H | pic |
| | | | | | group | | | | | |
| 22 | C | C | H | H | Dimethylamino | H | F | F | H | pic |
| | | | | | group | | | | | |
| 23 | C | C | H | H | Pyrrolidinyl | H | F | H | H | pic |
| | | | | | group | | | | | |
| 24 | C | C | H | H | Pyrrolidinyl | H | F | F | H | pic |
| | | | | | group | | | | | |
| 25 | C | C | H | H | Phenyl group | H | F | H | H | pic |
| 26 | C | C | H | H | Phenyl group | H | F | F | H | pic |
| 27 | C | C | H | H | CH₃O | H | F | H | H | pic |
| 28 | C | C | H | H | CH₃O | H | F | F | H | pic |

TABLE 2

| Com- | | | | | | | | | | |
|---|---|---|---|---|---|---|---|---|---|---|
| pound | A | B | R₁ | R₂ | R₃ | R₄ | R₅ | R₆ | R₇ | X |
| 29 | C | C | H | H | H | H | F | H | H | dm3pc |
| 30 | C | C | H | H | H | H | F | F | H | dm3pc |
| 31 | C | C | H | H | H | H | F | F | CN | dm3pc |
| 32 | C | C | H | H | Methyl | H | F | H | H | dm3pc |
| | | | | | group | | | | | |
| 33 | C | C | H | H | Methyl | H | F | F | H | dm3pc |
| | | | | | group | | | | | |
| 34 | C | C | H | H | Methyl | H | F | F | CN | dm3pc |
| | | | | | group | | | | | |
| 35 | C | C | H | H | Dimethyl- | H | F | H | H | dm3pc |
| | | | | | amino group | | | | | |
| 36 | C | C | H | H | Dimethyl- | H | F | F | H | dm3pc |
| | | | | | amino group | | | | | |
| 37 | C | C | H | H | Pyrroli- | H | F | H | H | dm3pc |
| | | | | | dinyl group | | | | | |
| 38 | C | C | H | H | Pyrroli- | H | F | F | H | dm3pc |
| | | | | | dinyl group | | | | | |
| 39 | C | C | H | H | Phenyl group | H | F | H | H | dm3pc |
| 40 | C | C | H | H | Phenyl group | H | F | F | H | dm3pc |
| 41 | C | C | H | H | CH₃O | H | F | H | H | dm3pc |
| 42 | C | C | H | H | CH₃O | H | F | F | H | dm3pc |
| 43 | C | C | H | H | H | H | F | H | H | ppz |
| 44 | C | C | H | H | H | H | F | F | H | ppz |
| 45 | C | C | H | H | H | H | F | F | CN | ppz |
| 46 | C | C | H | H | Methyl | H | F | H | H | ppz |
| | | | | | group | | | | | |
| 47 | C | C | H | H | Methyl | H | F | F | H | ppz |
| | | | | | group | | | | | |
| 48 | C | C | H | H | Methyl | H | F | F | CN | ppz |
| | | | | | group | | | | | |
| 49 | C | C | H | H | Dimethyl- | H | F | H | H | ppz |
| | | | | | amino group | | | | | |
| 50 | C | C | H | H | Dimethyl- | H | F | F | H | ppz |
| | | | | | amino group | | | | | |
| 51 | C | C | H | H | Pyrroli- | H | F | H | H | ppz |
| | | | | | dinyl group | | | | | |
| 52 | C | C | H | H | Pyrroli- | H | F | F | H | ppz |
| | | | | | dinyl group | | | | | |
| 53 | C | C | H | H | Phenyl group | H | F | H | H | ppz |
| 54 | C | C | H | H | Phenyl group | H | F | F | H | ppz |
| 55 | C | C | H | H | CH₃O | H | F | H | H | ppz |
| 56 | C | C | H | H | CH₃O | H | F | F | H | ppz |

TABLE 3

| Compound | A | B | R₁ | R₂ | R₃ | R₄ | R₅ | R₆ | X |
|---|---|---|---|---|---|---|---|---|---|
| 57 | C | N | H | H | H | H | F | H | acac |
| 58 | C | N | H | H | H | H | H | F | acac |
| 59 | C | N | H | H | H | H | F | F | acac |
| 60 | C | N | H | H | Methyl group | H | F | H | acac |
| 61 | C | N | H | H | Methyl group | H | H | F | acac |
| 62 | C | N | H | H | Methyl group | H | F | F | acac |
| 63 | C | N | H | H | Dimethylamino | H | F | H | acac |
| | | | | | group | | | | |
| 64 | C | N | H | H | Dimethylamino | H | F | F | acac |
| | | | | | group | | | | |
| 65 | C | N | H | H | Pyrrolidinyl | H | F | H | acac |
| | | | | | group | | | | |
| 66 | C | N | H | H | Pyrrolidinyl | H | F | F | acac |
| | | | | | group | | | | |
| 67 | C | N | H | H | Phenyl group | H | F | H | acac |
| 68 | C | N | H | H | Phenyl group | H | F | F | acac |
| 69 | C | N | H | H | CH₃O | H | F | H | acac |
| 70 | C | N | H | H | CH₃O | H | F | F | acac |
| 71 | C | N | H | H | H | H | F | H | pic |
| 72 | C | N | H | H | H | H | F | F | pic |
| 73 | C | N | H | H | H | H | F | H | pic |
| 74 | C | N | H | H | Methyl group | H | F | F | pic |
| 75 | C | N | H | H | Methyl group | H | F | H | pic |
| 76 | C | N | H | H | Methyl group | H | F | F | pic |
| 77 | C | N | H | H | Dimethylamino | H | F | H | pic |
| | | | | | group | | | | |
| 78 | C | N | H | H | Dimethylamino | H | F | F | pic |
| | | | | | group | | | | |
| 79 | C | N | H | H | Pyrrolidinyl | H | F | H | pic |
| | | | | | group | | | | |
| 80 | C | N | H | H | Pyrrolidinyl | H | F | F | pic |
| | | | | | group | | | | |
| 81 | C | N | H | H | Phenyl group | H | F | H | pic |
| 82 | C | N | H | H | Phenyl group | H | F | F | pic |
| 83 | C | N | H | H | CH₃O | H | F | H | pic |
| 84 | C | N | H | H | CH₃O | H | F | F | pic |

TABLE 4

| Compound | A | B | R₁ | R₂ | R₃ | R₄ | R₅ | R₆ | X |
|---|---|---|---|---|---|---|---|---|---|
| 85 | C | N | H | H | H | H | F | H | dm3pc |
| 86 | C | N | H | H | H | H | H | F | dm3pc |
| 87 | C | N | H | H | H | H | F | F | dm3pc |
| 88 | C | N | H | H | Methyl group | H | F | H | dm3pc |
| 89 | C | N | H | H | Methyl group | H | H | F | dm3pc |
| 90 | C | N | H | H | Methyl group | H | F | F | dm3pc |
| 91 | C | N | H | H | Dimethylamino | H | F | H | dm3pc |
| | | | | | group | | | | |
| 92 | C | N | H | H | Dimethylamino | H | F | F | dm3pc |
| | | | | | group | | | | |
| 93 | C | N | H | H | Pyrrolidinyl | H | F | H | dm3pc |
| | | | | | group | | | | |
| 94 | C | N | H | H | Pyrrolidinyl | H | F | F | dm3pc |
| | | | | | group | | | | |
| 95 | C | N | H | H | Phenyl group | H | F | H | dm3pc |
| 96 | C | N | H | H | Phenyl group | H | F | F | dm3pc |
| 97 | C | N | H | H | CH₃O | H | F | H | dm3pc |
| 98 | C | N | H | H | CH₃O | H | F | F | dm3pc |
| 99 | C | N | H | H | H | H | F | H | ppz |
| 100 | C | N | H | H | H | H | F | F | ppz |
| 101 | C | N | H | H | H | H | F | H | ppz |
| 102 | C | N | H | H | Methyl group | H | F | F | ppz |
| 103 | C | N | H | H | Methyl group | H | F | H | ppz |
| 104 | C | N | H | H | Methyl group | H | F | F | ppz |
| 105 | C | N | H | H | Dimethylamino | H | F | H | ppz |
| | | | | | group | | | | |
| 106 | C | N | H | H | Dimethylamino | H | F | F | ppz |
| | | | | | group | | | | |
| 107 | C | N | H | H | Pyrrolidinyl | H | F | H | ppz |
| | | | | | group | | | | |
| 108 | C | N | H | H | Pyrrolidinyl | H | F | F | ppz |
| | | | | | group | | | | |
| 109 | C | N | H | H | Phenyl group | H | F | H | ppz |
| 110 | C | N | H | H | Phenyl group | H | F | F | ppz |
| 111 | C | N | H | H | CH₃O | H | F | H | ppz |
| 112 | C | N | H | H | CH₃O | H | F | F | ppz |

TABLE 5

| Compound | A | B | R₁ | R₂ | R₃ | R₅ | R₆ | R₇ | X |
|---|---|---|---|---|---|---|---|---|---|
| 113 | N | C | H | H | H | F | H | H | acac |
| 114 | N | C | H | H | H | F | F | H | acac |
| 115 | N | C | H | H | H | F | F | CN | acac |
| 116 | N | C | H | H | H | F | H | H | pic |
| 117 | N | C | H | H | H | F | F | H | pic |
| 118 | N | C | H | H | H | F | F | CN | pic |
| 119 | N | C | H | H | H | F | H | H | dm3pc |
| 120 | N | C | H | H | H | F | F | H | dm3pc |
| 121 | N | C | H | H | H | F | F | CN | dm3pc |
| 122 | N | C | H | H | H | F | H | H | ppz |
| 123 | N | C | H | H | H | F | F | H | ppz |
| 124 | N | C | H | H | H | F | F | CN | ppz |
| Compound | A | B | R₁ | R₂ | R₃ | R₄ | R₅ | R₆ | X |
| 125 | C | N | H | H | H | H | H | H | pic |
| 126 | C | N | H | H | H | H | F | H | pic |
| 127 | C | N | H | H | H | H | H | F | pic |
| 128 | C | N | H | H | H | H | F | F | pic |
| 129 | C | N | H | H | H | H | F | CN | pic |
| 130 | C | N | H | H | H | H | H | H | ppz |
| 131 | C | N | H | H | H | H | F | H | ppz |
| 132 | C | N | H | H | H | H | H | F | ppz |
| 133 | C | N | H | H | H | H | F | F | ppz |
| 134 | C | N | H | H | H | H | F | CN | ppz |

TABLE 6

| Compound | A | B | R₁ | R₂ | R₃ | R₄ | R₅ | R₆ | R₇ |
|---|---|---|---|---|---|---|---|---|---|
| 135 | C | C | H | H | H | H | F | H | H |
| 136 | C | C | H | H | H | H | H | F | H |
| 137 | C | C | H | H | H | H | F | F | CN |
| 138 | C | C | H | H | Methyl group | H | F | H | H |
| 139 | C | C | H | H | Methyl group | H | H | F | H |
| 140 | C | C | H | H | Methyl group | H | F | F | CN |
| 141 | C | C | H | H | Dimethylamino | H | F | H | H |
| | | | | | group | | | | |
| 142 | C | C | H | H | Dimethylamino | H | F | F | H |
| | | | | | group | | | | |
| 143 | C | C | H | H | Pyrrolidinyl group | H | F | H | H |
| 144 | C | C | H | H | Pyrrolidinyl group | H | F | F | H |
| 145 | C | C | H | H | Phenyl group | H | F | H | H |
| 146 | C | C | H | H | Phenyl group | H | F | F | H |
| 147 | C | C | H | H | CH₃O | H | F | H | H |
| 148 | C | C | H | H | CH₃O | H | F | F | H |
| 149 | C | C | H | H | H | H | F | H | H |
| 150 | C | C | H | H | H | H | F | F | H |
| 151 | C | C | H | H | H | H | F | F | CN |
| 152 | C | C | H | H | Methyl group | H | F | H | H |
| 153 | C | C | H | H | Methyl group | H | F | F | H |
| 154 | C | C | H | H | Methyl group | H | F | F | CN |
| 155 | C | C | H | H | Dimethylamino | H | F | H | H |
| | | | | | group | | | | |
| 156 | C | C | H | H | Dimethylamino | H | F | F | H |
| | | | | | group | | | | |
| 157 | C | C | H | H | Pyrrolidinyl group | H | F | H | H |
| 158 | C | C | H | H | Pyrrolidinyl group | H | F | F | H |
| 159 | C | C | H | H | Phenyl group | H | F | H | H |
| 160 | C | C | H | H | Phenyl group | H | F | F | H |
| 161 | C | C | H | H | CH₃O | H | F | H | H |
| 162 | C | C | H | H | CH₃O | H | F | F | H |

TABLE 7

| Compound | A | B | R₁ | R₂ | R₃ | R₄ | R₅ | R₆ |
|---|---|---|---|---|---|---|---|---|
| 163 | C | N | H | H | H | H | F | H |
| 164 | C | N | H | H | H | H | H | F |
| 165 | C | N | H | H | H | H | F | F |
| 166 | C | N | H | H | Methyl group | H | F | H |
| 167 | C | N | H | H | Methyl group | H | H | F |
| 168 | C | N | H | H | Methyl group | H | F | F |
| 169 | C | N | H | H | Dimethylamino group | H | F | H |
| 170 | C | N | H | H | Dimethylamino group | H | F | F |
| 171 | C | N | H | H | Pyrrolidinyl group | H | F | H |
| 172 | C | N | H | H | Pyrrolidinyl group | H | F | F |
| 173 | C | N | H | H | Phenyl group | H | F | H |
| 174 | C | N | H | H | Phenyl group | H | F | F |
| 175 | C | N | H | H | CH₃O | H | F | H |
| 176 | C | N | H | H | CH₃O | H | F | F |
| 177 | C | N | H | H | H | H | F | H |
| 178 | C | N | H | H | H | H | F | F |
| 179 | C | N | H | H | H | H | F | H |
| 180 | C | N | H | H | Methyl group | H | F | F |
| 181 | C | N | H | H | Methyl group | H | F | H |
| 182 | C | N | H | H | Methyl group | H | F | F |
| 183 | C | N | H | H | Dimethylamino group | H | F | H |
| 184 | C | N | H | H | Dimethylamino group | H | F | F |
| 185 | C | N | H | H | Pyrrolidinyl group | H | F | H |
| 186 | C | N | H | H | Pyrrolidinyl group | H | F | F |
| 187 | C | N | H | H | Phenyl group | H | F | H |
| 188 | C | N | H | H | Phenyl group | H | F | F |
| 189 | C | N | H | H | CH₃O | H | F | H |
| 190 | C | N | H | H | CH₃O | H | F | F |

| Compound | A | B | R₁ | R₂ | R₃ | R₅ | R₆ | R₇ |
|---|---|---|---|---|---|---|---|---|
| 191 | N | C | H | H | H | F | H | H |
| 192 | N | C | H | H | H | F | F | H |
| 193 | N | C | H | H | H | F | F | CN |

TABLE 8

| Compound | A | B | R₁ | R₂ | R₃ | R₄ | R₅ | R₆ |
|---|---|---|---|---|---|---|---|---|
| 194 | C | N | H | H | H | H | H | H |
| 195 | C | N | H | H | H | H | F | H |
| 196 | C | N | H | H | H | H | H | F |
| 197 | C | N | H | H | H | H | F | F |
| 198 | C | N | H | H | H | H | F | CN |

| Compound | A | B | R₁ | R₂ | R₃ | R₅ | R₆ |
|---|---|---|---|---|---|---|---|
| 199 | N | N | H | H | H | H | H |
| 200 | N | N | H | H | H | F | H |
| 201 | N | N | H | H | H | H | F |
| 202 | N | N | H | H | H | F | F |
| 203 | N | N | H | H | H | F | CN |

| Compound | A | B | R₁ | R₂ | R₃ | R₄ | R₅ | R₆ | R₇ | X |
|---|---|---|---|---|---|---|---|---|---|---|
| 204 | C | C | H | H | Dimethylamino group | H | H | H | H | acac |
| 205 | C | C | H | H | H | H | CH₃O | CH₃O | H | pz₂Bpz₂ |

The compound represented by Formula (E-I) may be synthesized by, for example, the method described in paragraphs Nos. [0028] to [0032] of U.S. Patent Application Laid-Open No. 2005/0170209.

The compound represented by Formula (E-I) is preferably contained in an amount of 0.1% by mass to 30% by mass, more preferably 1% by mass to 20% by mass, and still more preferably 3% by mass to 15% by mass based on the total mass of the light emitting layer.

[Compound Represented by Formula (1)]

Hereinafter, the compound represented by Formula (1) will be described.

[Chem. 14]

(Cz)p-L-(A)q (1)

In Formula (1), Cz represents a substituted or unsubstituted arylcarbazolyl group or carbazolylaryl group, L represents a single bond, a substituted or unsubstituted arylene group, a substituted or unsubstituted cycloalkylene group or a substituted or unsubstituted aromatic heterocyclic ring, A represents a substituted or unsubstituted nitrogen-containing 6-membered aromatic heterocyclic ring, and each of p and q independently represents an integer of 1 to 6.

Hereinafter, the compound represented by Formula (1) will be described.

Cz is a substituted or unsubstituted arylcarbazolyl group or carbazolylaryl group.

The aryl group in the arylcarbazolyl group and the carbazolylaryl group has preferably 6 to 30 carbon atoms, and examples thereof include a phenyl group, a naphthyl group, an anthryl group, a phenanthryl group, a naphthacenyl group, a pyrenyl group, a fluorenyl group, a biphenyl group, a terphenyl group and the like, and among them, a phenyl group, a naphthyl group, a biphenyl group and a terphenyl group are preferred, and a phenyl group and a biphenyl group are more preferred.

The substitution position of the aryl group on the carbazole ring (carbazolyl group) in the arylcarbazolyl group and the carbazolylaryl group is not particularly limited, but, from the viewpoint of chemical stability or carrier transportability, the aryl group is preferably substituted at the 2-, 3-, 6-, 7- or 9-position of the carbazole ring, more preferably at the 3-, 6- or 9-position of the carbazole ring, and most preferably at the 9-position (N-position) of the carbazole ring.

In the case where Cz is an arylcarbazolyl group, it is not particularly limited, but from the viewpoint of chemical stability or carrier transportability, it is preferred to link to L at the 2-, 3-, 6-, 7- or 9-position (N-position) of the carbazole ring, it is more preferred to link to L at the 3-, 6- or 9-position (N-position) of the carbazole ring, and it is most preferred to link to L at the 9-position (N-position) of the carbazole ring.

Specifically, Cz is preferably a group formed when a phenyl group is substituted at the 9-position (N-position) of the carbazolyl group or a group formed when phenyl groups are substituted at the 3- and 6-positions of N-carbazolyl group.

Further, Cz is preferably a carbazolylaryl group.

A is a substituted or unsubstituted nitrogen-containing 6-membered heteroaromatic ring, and preferably a nitrogen-containing 6-membered heteroaromatic ring having 2 to 40 carbon atoms. A may have a plurality of substituents, and substituents may be bonded to each other to form a ring.

Examples of a nitrogen-containing 6-membered heteroaromatic ring or a nitrogen-containing heteroaromatic ring containing a nitrogen-containing 6-membered heteroaromatic ring include pyridine, pyrimidine, pyrazine, pyridazine, triazine, azaindolizine, indolizine, purine, pteridine, β-carboline, naphthyridine, quinoxaline, terpyridine, bipyridine, acridine, phenanthroline, phenazine, imidazopyridine and the like, and among them, pyridine, pyrimidine, pyrazine and triazine are more preferred, pyridine and pyrimidine are still more preferred, and pyrimidine is most preferred.

L is a single bond, a substituted or unsubstituted arylene group, a substituted or unsubstituted cycloarylene group, a substituted or unsubstituted heteroaromatic ring. In addition, when p+q in Formula (1) is 3 or more, L represents p+q-valent group in which p+q-2 of any hydrogen atoms are removed from the arylene group, p+q-valent group in which p+q-2 of any hydrogen atoms are removed from the cycloalkylene group or p+q-valent aromatic heterocyclic group. The substituent possessed by L may include those exemplified above as Group A of substituents, preferably a methyl group, an ethyl group, a propyl group, a butyl group, a cyclohexyl group, a cyclopentyl group, a phenyl group, a tolyl group, a xylyl group, a pyridyl group, a pyrimidyl group, a thienyl group, a fluoro group, a cyano group, a trifluoromethyl group, a pentafluorophenyl group, a triphenylsilyl group and a trimethylsilyl group, more preferably a methyl group, an ethyl group, a butyl group, a phenyl group, a pyridyl group, a pyrimidyl group, a fluoro group, a cyano group and a trifluoromethyl group, and still more preferably a methyl group, a phenyl group and a fluoro group.

The arylene group is preferably an arylene group having 6 to 30 carbon atoms, for example, a phenylene group, a biphenylene group, a terphenylene group, a naphthylene group, an anthranylene group, a phenanthrylene group, a pyrenylene group, a chrysenylene group, a fluoranthenylene group, a perfluoroarylene group and the like, and among them, a phenylene group, a biphenylene group, a terphenylene group and a perfluoroarylene group are preferred, a phenylene group, a biphenylene group and a terphenylene group are more preferred, and a phenylene group and a biphenylene group are still more preferred.

The cycloalkylene group is preferably a cycloalkylene group having 5 to 30 carbon atoms, for example, a cyclopentylene group, a cyclohexylene group, a cycloheptylene group and the like, and among them, a cyclopentylene group and a cyclohexylene group are preferred, and a cyclohexylene group is more preferred.

The heteroaromatic ring group is preferably a heteroaromatic ring group having 2 to 30 carbon atoms, and examples thereof include a 1-pyrrolyl group, a 2-pyrrolyl group, a 3-pyrrolyl group, a pyrazinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a 2-quinolyl group, a 3-quinolyl group, a 4-quinolyl group, a 5-quinolyl group, a 6-quinolyl group, a 7-quinolyl group, a 8-quinolyl group, a 1-isoquinolyl group, a 3-isoquinolyl group, a 4-isoquinolyl group, a 5-isoquinolyl group, a 6-isoquinolyl group, a 7-isoquinolyl group, a 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, a 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthrolin-2-yl group, a 1,7-phenanthrolin-3-yl group, a 1,7-phenanthrolin-4-yl group, a 1,7-phenanthrolin-5-yl group, a 1,7-phenanthrolin-6-yl group, a 1,7-phenanthrolin-8-yl group, a 1,7-phenanthrolin-9-yl group, a 1,7-phenanthrolin-10-yl group, a 1,8-phenanthrolin-2-yl group, a 1,8-phenanthrolin-3-yl group, a 1,8-phenanthrolin-4-yl group, a 1,8-phenanthrolin-5-yl group, a 1,8-phenanthrolin-6-yl group, a 1,8-phenanthrolin-7-yl group, a 1,8-phenanthrolin-9-yl group, a 1,8-phenanthrolin-10-yl group, a 1,9-phenanthrolin-2-yl group, a 1,9-phenanthrolin-3-yl group, a 1,9-phenanthrolin-4-yl group, a 1,9-phenanthrolin-5-yl group, a 1,9-phenanthrolin-6-yl group, a 1,9-phenanthrolin-7-yl group, a 1,9-phenanthrolin-8-yl group, a 1,9-phenanthrolin-10-yl group, a 1,10-phenanthrolin-2-yl group, a 1,10-phenanthrolin-3-yl group, a 1,10-phenanthrolin-4-yl group, a 1,10-phenanthrolin-5-yl group, a 2,9-phenanthrolin-1-yl group, a 2,9-phenanthrolin-3-yl group, a 2,9-phenanthrolin-4-yl group, a 2,9-phenanthrolin-5-yl group, a 2,9-phenanthrolin-6-yl group, a 2,9-phenanthrolin-7-yl group, a 2,9-phenanthrolin-8-yl group, a 2,9-phenanthrolin-10-yl group, a 2,8-phenanthrolin-1-yl group, a 2,8-phenanthrolin-3-yl group, a 2,8-phenanthrolin-4-yl group, a 2,8-phenanthrolin-5-yl group, a 2,8-phenanthrolin-6-yl group, a 2,8-phenanthrolin-7-yl group, a 2,8-phenanthrolin-9-yl group, a 2,8-phenanthrolin-10-yl group, a 2,7-phenanthrolin-1-yl group, a 2,7-phenanthrolin-3-yl group, a 2,7-phenanthrolin-4-yl group, a 2,7-phenanthrolin-5-yl group, a 2,7-phenanthrolin-6-yl group, a 2,7-phenanthrolin-8-yl group, a 2,7-phenanthrolin-9-yl group, a 2,7-phenanthrolin-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxazinyl group, a 2-phenoxazinyl group, a 3-phenoxazinyl group, a 4-phenoxazinyl group, a 10-phenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrole-1-yl group, a 2-methylpyrrole-3-yl group, a 2-methylpyrrole-4-yl group, a 2-methylpyrrole-5-yl group, a 3-methylpyrrole-1-yl group, a 3-methylpyrrole-2-yl group, a 3-methylpyrrol-4-yl group, a 3-methylpyrrol-5-yl group, a 2-t-butylpyrrol-4-yl group, a 3-(2-phenylpropyl)pyrrol-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t-butyl-1-indolyl group, a 2-t-butyl-3-indolyl group, a 4-t-butyl-3-indolyl group and the like, and among them, a pyridyl group, a quinolyl group, an indolyl group and a carbazolyl group are preferred, and a pyridyl group and a carbazolyl group are more preferred.

L is preferably a single bond, a phenylene group, a biphenylene group, a cyclohexylene group, a cyclohexylene group, a pyridyl group and a carbazolyl group, more preferably a single bond, a phenylene group and a biphenylene group, still more preferably a single bond and a phenylene group, and particularly preferably a phenylene group.

In addition, examples of substituents of Cz and A in Formula (1) include a halogen atom such as fluorine, chlorine, bromine and iodine, a carbazolyl group, a hydroxyl group, a substituted or unsubstituted amino group, a nitro group, a cyano group, a silyl group, a trifluoromethyl group, a carbonyl grpoup, a carboxyl group, a substituted or unsubstituted alkyl group, a substituted or unsubstituted alkenyl group, a substituted or unsubstituted arylalkyl group, a substituted or unsubstituted aromatic group, a substituted or unsubstituted aromatic heterocyclic group, a substituted or unsubstituted aralkyl group, a substituted or unsubstituted aryloxy group, a substituted or unsubstituted alkyloxy group and the like. Among them, a fluorine atom, a methyl group, a perfluorophenylene group, a phenyl group, a naphthyl group, a pyridyl group, a pyrazyl group, a pyrimidyl group, an adamantyl group, a benzyl group, a nitro group, a cyano group, a silyl group, a trifluoromethyl group, a carbazolyl group and a group formed by combining these groups are preferred, a fluorine atom, a methyl group, a phenyl group, a pyridyl group, a pyrimidyl group, a cyano group, a silyl group, a carbazolyl group and a group formed by combining these groups are more preferred, a phenyl group, a pyridyl group, a pyrimidyl group, a carbazolyl group and a group formed by combining these groups are still more preferred, and a phenyl group is most preferred. Further, when having a plurality of substituents, the substituents may be bonded to each other to form a ring.

Each of p and q is independently an integer of 1 to 6, each preferably 1 to 4, more preferably 1 to 3, and still more preferably 1 to 2.

The compound represented by Formula (1) is more preferably a compound represented by the following Formula (2) from the viewpoint of driving durability.

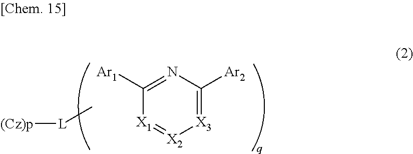

In Formula (2), Cz represents a substituted or unsubstituted arylcarbazolyl group or carbazolylaryl group. L represents a single bond, a substituted or unsubstituted arylene group, a substituted or unsubstituted cycloalkylene group or a substituted or unsubstituted aromatic heterocyclic ring, and is liked with a carbon atom of Ar₁, Ar₂, X₁, X₂ or X₃. Each of Ar₁ and Ar₂ independently represents a substituted or unsubstituted aryl group or a substituted or unsubstituted aromatic heterocyclic group, and each of X₁, X₂ or X₃ independently represents a nitrogen atom, or a carbon atom having a hydrogen atom or a substituent bonded thereto. Each of p and q independently represents an integer of 1 to 6.

Formula (2) will be described.

In Formula (2), the definitions of Cz, L, p and q are the same as those of Cz, L, p and q in Formula (1), and preferred are also the same.

Each of Ar₁ and Ar₂ independently represents a substituted or unsubstituted aryl group, arylene group or aromatic heterocyclic group.

The aryl group is preferably a substituted or unsubstituted aryl group having 6 to 30 carbon atoms, and examples thereof include a phenyl group, a biphenyl group, a terphenyl group, a naphthyl group, an anthranyl group, a phenanthryl group, a pyrenyl group, a chrysenyl group, a fluoranthenyl group, a perfluoroaryl group and the like, and among them, a phenyl group, a biphenyl group, a terphenyl group and a perfluoroaryl group are preferred, a phenyl group, a biphenyl group and a terphenyl group are more preferred, and a phenyl group and a biphenyl group are still more preferred.

The arylene group is preferably a substituted or unsubstituted arylene group having 6 to 30 carbon atoms, and specific examples or preferred groups are the same as those exemplified in the description of L in Formula (1) as described above. The aromatic heterocyclic group is preferably a substituted or unsubstituted aromatic heterocyclic group having 2 to 30 carbon atoms, and specific examples or preferred groups are the same as those exemplified in the description of L in Formula (1) as described above. When a substituent is bonded to them, specific examples or preferred groups of the substituent are the same as those exemplified as the substituent of Cz and A in Formula (1) as described above.

Each of Ar₁ and Ar₂ is preferably independently a phenyl group or a pyridyl group.

Each of X₁, X₂ and X₃ independently represents a nitrogen atom, or a carbon atom having a hydrogen atom or a substituent bonded thereto. Among X₁, X₂ and X₃, it is preferred that 0 to 2 are a nitrogen atom, it is more preferred that 0 to 1 is a nitrogen atom, and it is most preferred that 1 is a nitrogen atom. When any of X₁, X₂, X₃ is a nitrogen atom, it is preferred that any one of X₁ and X₃ is a nitrogen atom. The ring containing X₁ to X₃ in Formula (2) preferably represents pyridine or pyrimidine, and more preferably pyrimidine. Specific examples or preferred groups of the substituent bonded to the carbon atom are the same as those exemplified as the substituents of Cz and A in Formula (1) as described above. In addition, the linking position of L in Formula (2) is not particularly limited, but it is preferred to link to the carbon atom of Ar₁ from the viewpoint of chemical stability or carrier transportability.

The compound represented by Formula (2) is still more preferably a compound represented by the following Formula (3) from the viewpoint of driving durability.

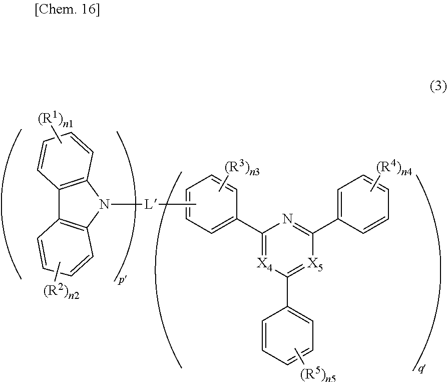

In Formula (3), each of X₄ and X₅ independently represents a nitrogen atom or a carbon atom having a hydrogen atom or a substituent bonded thereto, and any one of X₄ and X₅ is a nitrogen atom and the other is a carbon atom which may have a substituent. L′ represents a single bond, a substituted or unsubstituted aryl group or arylene group, a substituted or unsubstituted cycloalkylene group or a substituted or unsubstituted aromatic heterocyclic ring. Each of R′ to R⁵ independently represents a substituent. Each of n1 to n5 independently represents an integer of 0 to 5. Each of p′ and q′ independently represents an integer of 1 to 4.

Formula (3) will be described.

Each of X₄ and X₅ independently represents a nitrogen atom, or a carbon atom having a hydrogen atom or a substituent bonded thereto. It is preferred that any one of X₄ or X₅ is a nitrogen atom and the other is a carbon atom having a hydrogen atom or a substituent bonded thereto, and it is more preferred that one is a nitrogen atom and the other is a carbon atom having a hydrogen bonded thereto. The ring containing X₄ and X₅ in Formula (3) preferably represents pyridine or pyrimidine, and more preferably pyrimidine. Specific examples or preferred groups of the substituent bonded to the carbon atom are the same as those exemplified as the substituents of Cz and A in Formula (1) as described above.

The definition of L′ is the same as that of L in Formula (1) as described above, and preferred groups are also the same as L. L′ is linked to the benzene ring in the nitrogen-containing heteroaromatic structure in Formula (3).

Each of R¹ to R⁵ independently represents a substituent. Specific examples of the substituent are the same as those exemplified as the substituents of Cz and A in Formula (1) as described above. R¹ to R⁶ are preferably a fluorine atom, a methyl group, a t-butyl group, a phenyl group, a pyridyl group, a pyrazyl group, a pyrimidyl group, an adamantyl group, a cyano group, a trimethylsilyl group, a triphenylsilyl group, a trifluoromethyl group and a carbazolyl group, more preferably, a fluorine atom, a methyl group, a t-butyl group, a phenyl group, a pyridyl group, a cyano group, a trimethylsilyl group, a triphenylsilyl group, a trifluoromethyl group and a carbazolyl group, still more preferably a fluorine atom, a methyl group, a t-butyl group, a phenyl group, a cyano group, a silyl group, a triphenylsilyl group, a trifluoromethyl group and a carbazolyl group, and still yet more preferably a fluorine atom, a t-butyl group, a phenyl group, a cyano group, a triphenylsilyl group and a carbazolyl group. When R¹ to R⁵ are present in plural, each of R¹ to R⁵ may be the same as or different from every other R¹ to R⁵.

Each of n1 to n5 independently represents an integer of 0 to 5. Each is preferably 0 to 2, more preferably 0 to 1, and still more preferably 0.

Each of p′ and q′ independently represents an integer of 1 to 4. Each is preferably 1 to 3, and more preferably 1 to 2.

Preferably, In Formula (3), each of X₄ and X₅ independently represents a nitrogen atom, or a carbon atom having a hydrogen atom bonded thereto, the ring containing X₄ and X₅ is pyridine or pyrimidine, L′ represents a single bond or a phenylene group, each of R¹ to R⁵ independently represents a fluorine atom, a methyl group, a phenyl group, a cyano group, a pyridyl group, a pyrimidyl group, a silyl group, a carbazolyl group or a tert-butyl group, each of n1 to n5 independently represents 0 or 1, and each of p′ and q′ independently represents 1 or 2.

It is most preferred that the compound represented by Formula (1) is composed only of carbon atoms, hydrogen atoms and nitrogen atoms.

The compound represented by Formula (1) has a molecular weight of preferably 400 to 1,000, more preferably 450 to 800, and still more preferably 500 to 700.

The lowest triplet excited state (T₁) energy of the compound represented by Formula (1) in the state of film is preferably 2.61 eV (62 kcal/mol) to 3.51 eV (80 kcal/mol), more preferably 2.69 eV (63.5 kcal/mol) to 3.51 eV (80 kcal/mol), and still more preferably 2.76 eV (65 kcal/mol) to 3.51 eV (80 kcal/mol).

The glass transition temperature (Tg) of the compound represented by Formula (1) is preferably 80° C. to 400° C., more preferably 100° C. to 400° C., and still more preferably 120° C. to 400° C.

When Formula (1) has a hydrogen atom, an isotope (a deuterium atom and the like) is also included. In this case, all the hydrogen atoms in the compound may be substituted with the isotope and may also be a mixture in which a part thereof is a compound including the isotope.

Hereinafter, specific examples of the compound represented by Formula (1) will be exemplified, but the present invention is not limited thereto. In addition, Ph in the following specific examples represents a phenyl group.

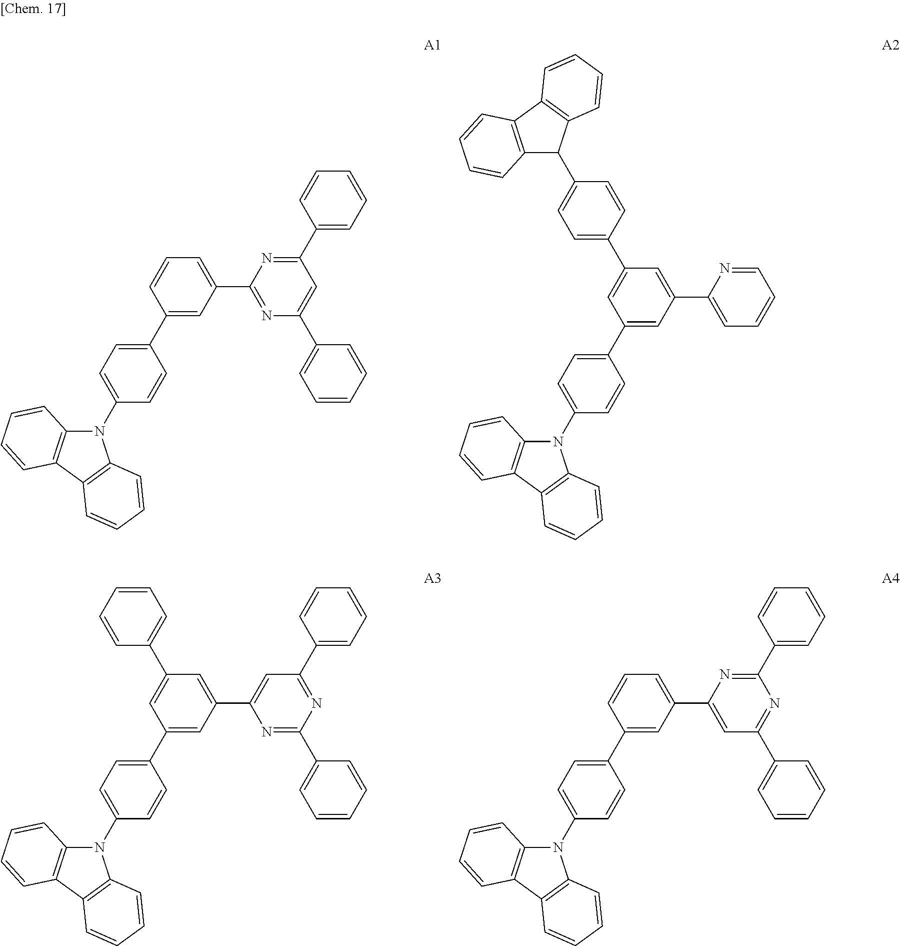 [SMILES: c1ccc(-c2cc(-c3ccccc3)nc(-c3cccc(-c4ccc(-n5c6ccccc6c6ccccc65)cc4)c3)n2)cc1 ; c1ccc(-c2cc(-c3ccc(C4c5ccccc5-c5ccccc54)cc3)cc(-c3ccc(-n4c5ccccc5c5ccccc54)cc3)c2)nc1 ; c1ccc(-c2cc(-c3ccc(-n4c5ccccc5c5ccccc54)cc3)cc(-c3cc(-c4ccccc4)nc(-c4ccccc4)n3)c2)cc1 ; c1ccc(-c2cc(-c3cccc(-c4ccc(-n5c6ccccc6c6ccccc65)cc4)c3)nc(-c3ccccc3)n2)cc1]

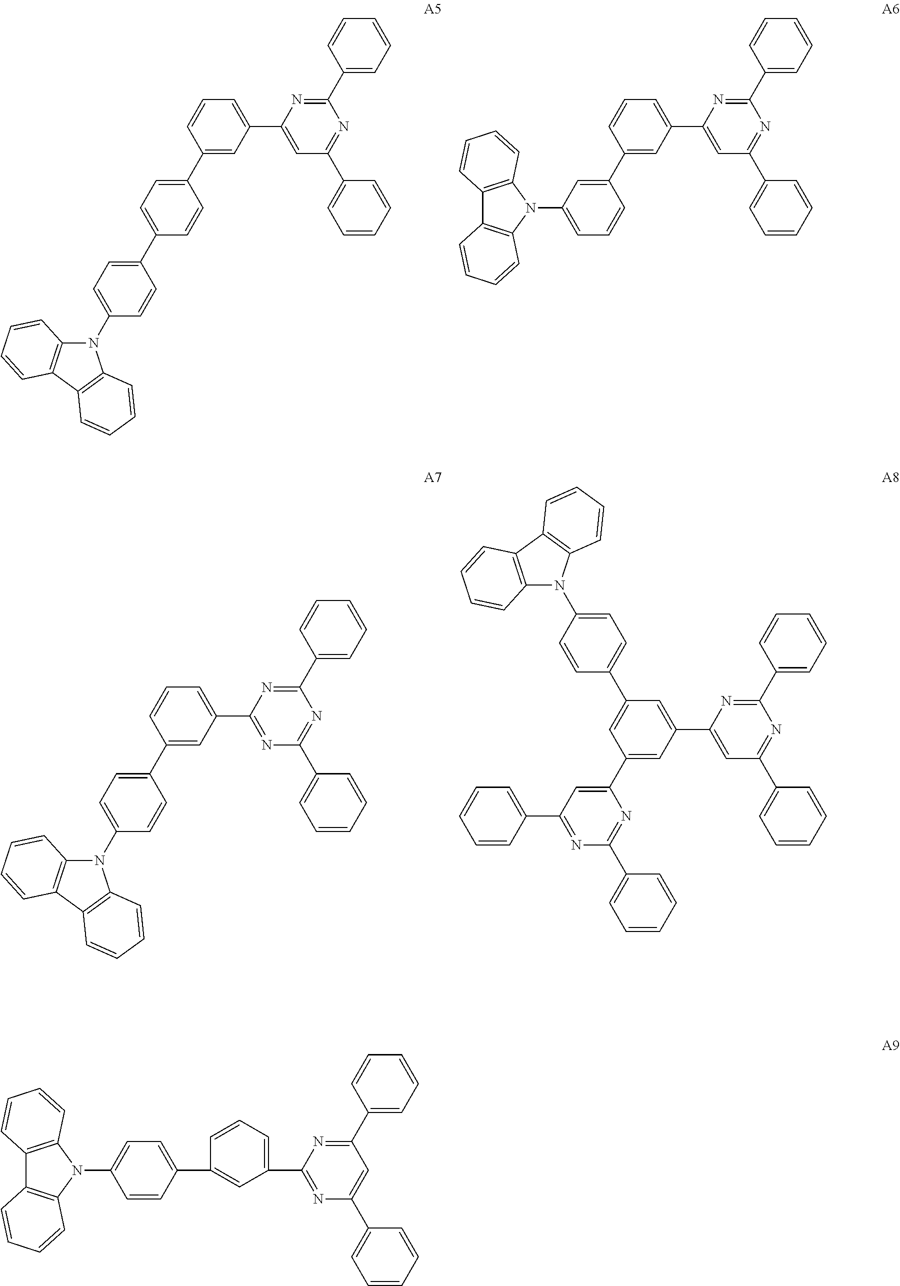 [SMILES: c1ccc(-c2cc(-c3cccc(-c4ccc(-c5ccc(-n6c7ccccc7c7ccccc76)cc5)cc4)c3)nc(-c3ccccc3)n2)cc1 ; c1ccc(-c2cc(-c3cccc(-c4cccc(-n5c6ccccc6c6ccccc65)c4)c3)nc(-c3ccccc3)n2)cc1 ; c1ccc(-c2nc(-c3ccccc3)nc(-c3cccc(-c4ccc(-n5c6ccccc6c6ccccc65)cc4)c3)n2)cc1 ; c1ccc(-c2cc(-c3cc(-c4ccc(-n5c6ccccc6c6ccccc65)cc4)cc(-c4cc(-c5ccccc5)nc(-c5ccccc5)n4)c3)nc(-c3ccccc3)n2)cc1 ; c1ccc(-c2cc(-c3ccccc3)nc(-c3cccc(-c4ccc(-n5c6ccccc6c6ccccc65)cc4)c3)n2)cc1]

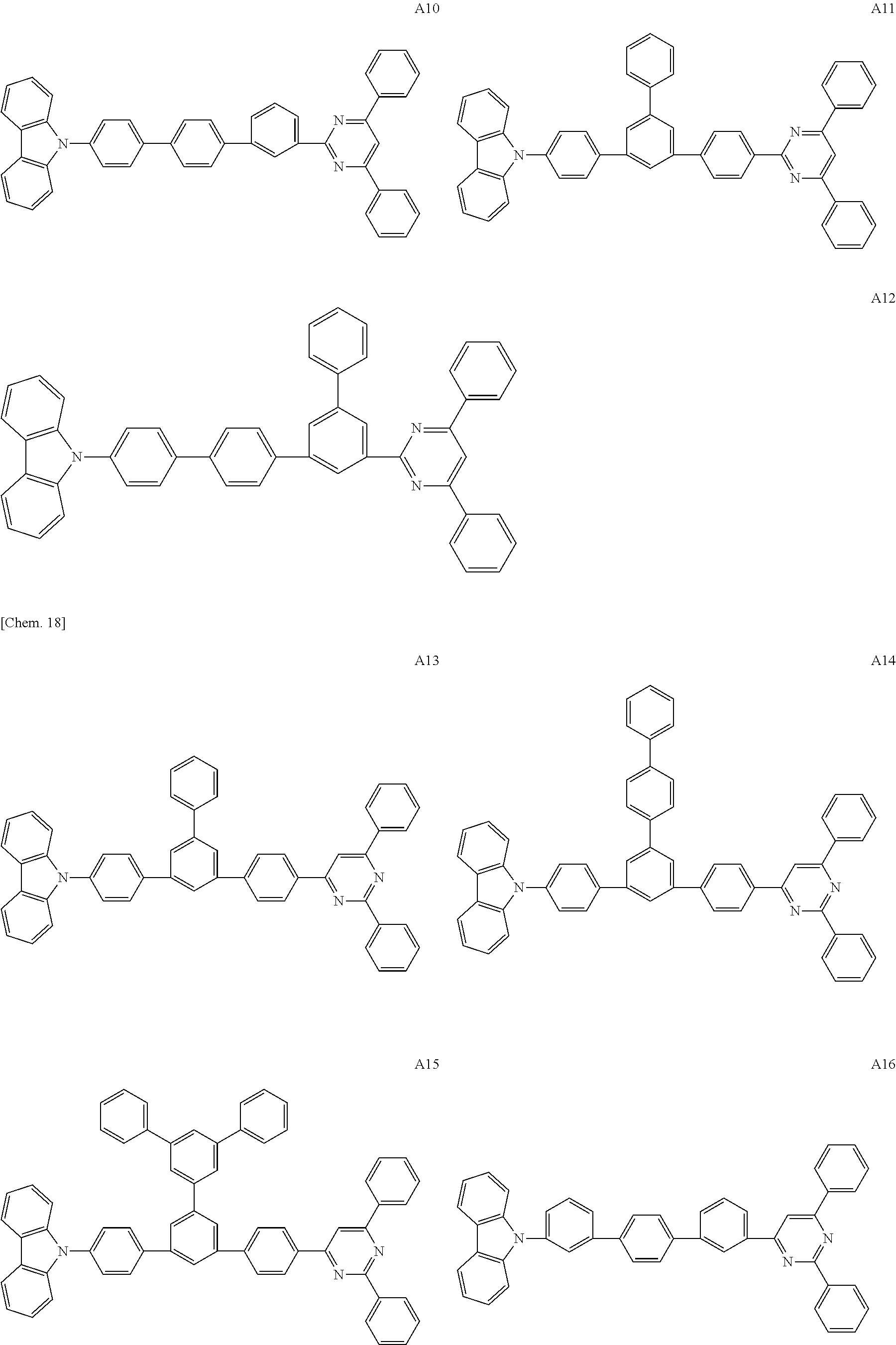

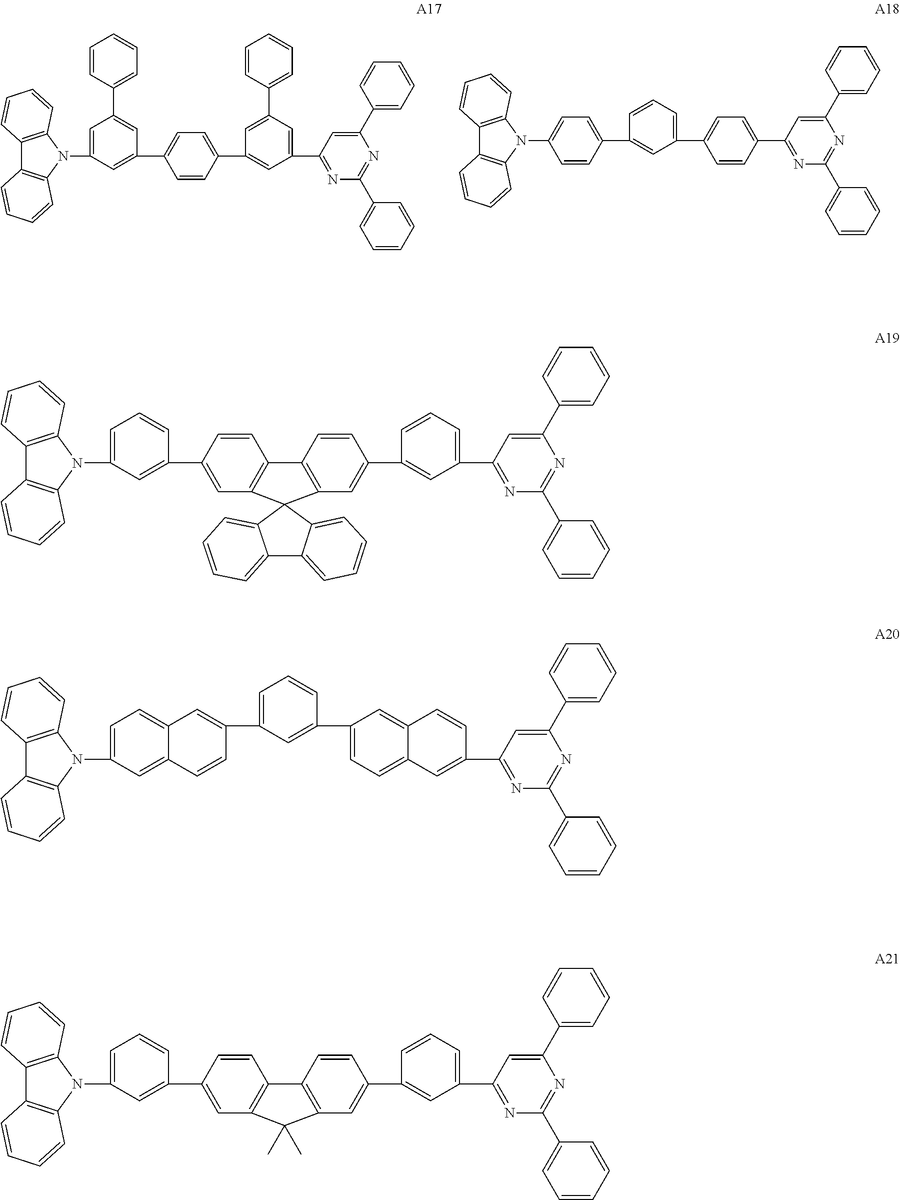

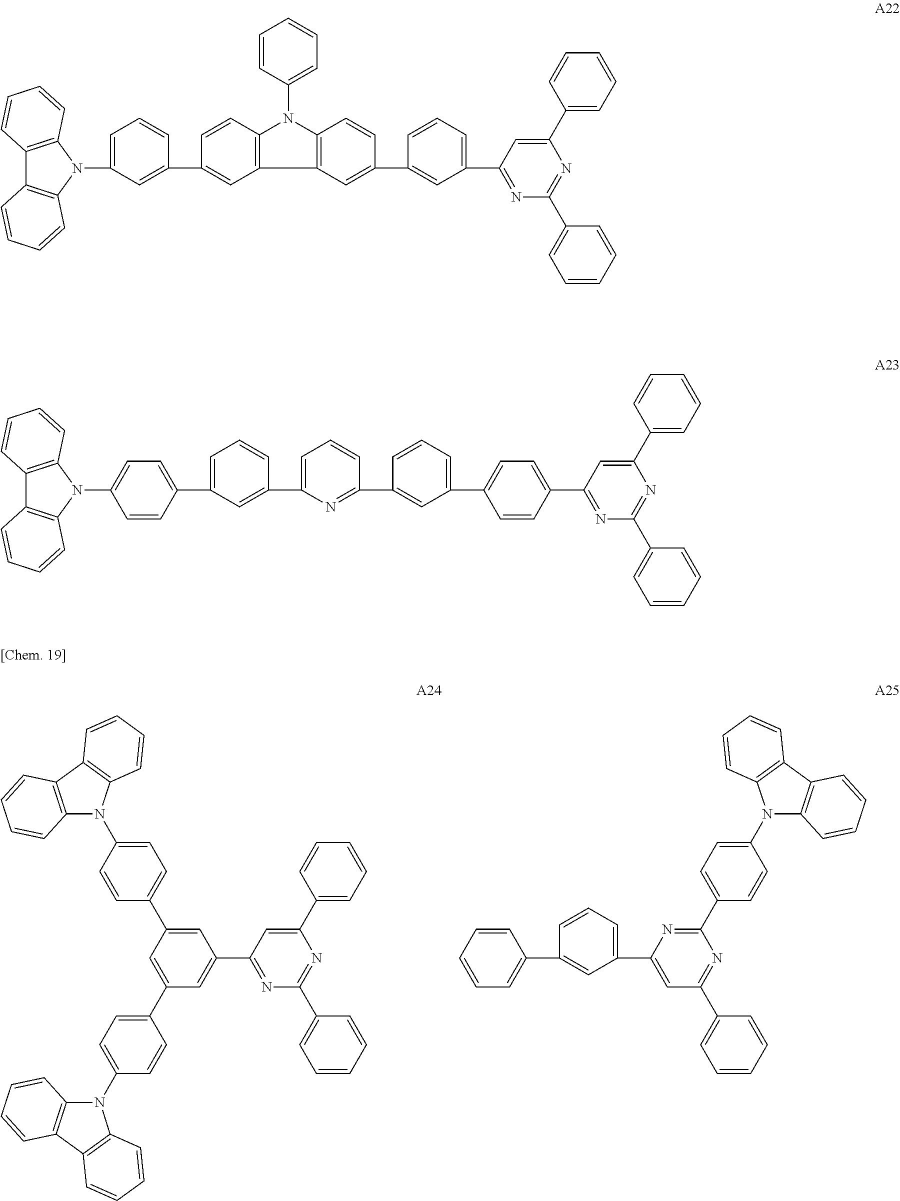 [SMILES: c1ccc(-c2cc(-c3cccc(-c4ccc5c(c4)c4cc(-c6cccc(-n7c8ccccc8c8ccccc87)c6)ccc4n5-c4ccccc4)c3)nc(-c3ccccc3)n2)cc1 ; c1ccc(-c2cc(-c3ccc(-c4cccc(-c5cccc(-c6cccc(-c7ccc(-n8c9ccccc9c9ccccc98)cc7)c6)n5)c4)cc3)nc(-c3ccccc3)n2)cc1 ; c1ccc(-c2cc(-c3cc(-c4ccc(-n5c6ccccc6c6ccccc65)cc4)cc(-c4ccc(-n5c6ccccc6c6ccccc65)cc4)c3)nc(-c3ccccc3)n2)cc1 ; c1ccc(-c2cccc(-c3cc(-c4ccccc4)nc(-c4ccc(-n5c6ccccc6c6ccccc65)cc4)n3)c2)cc1]

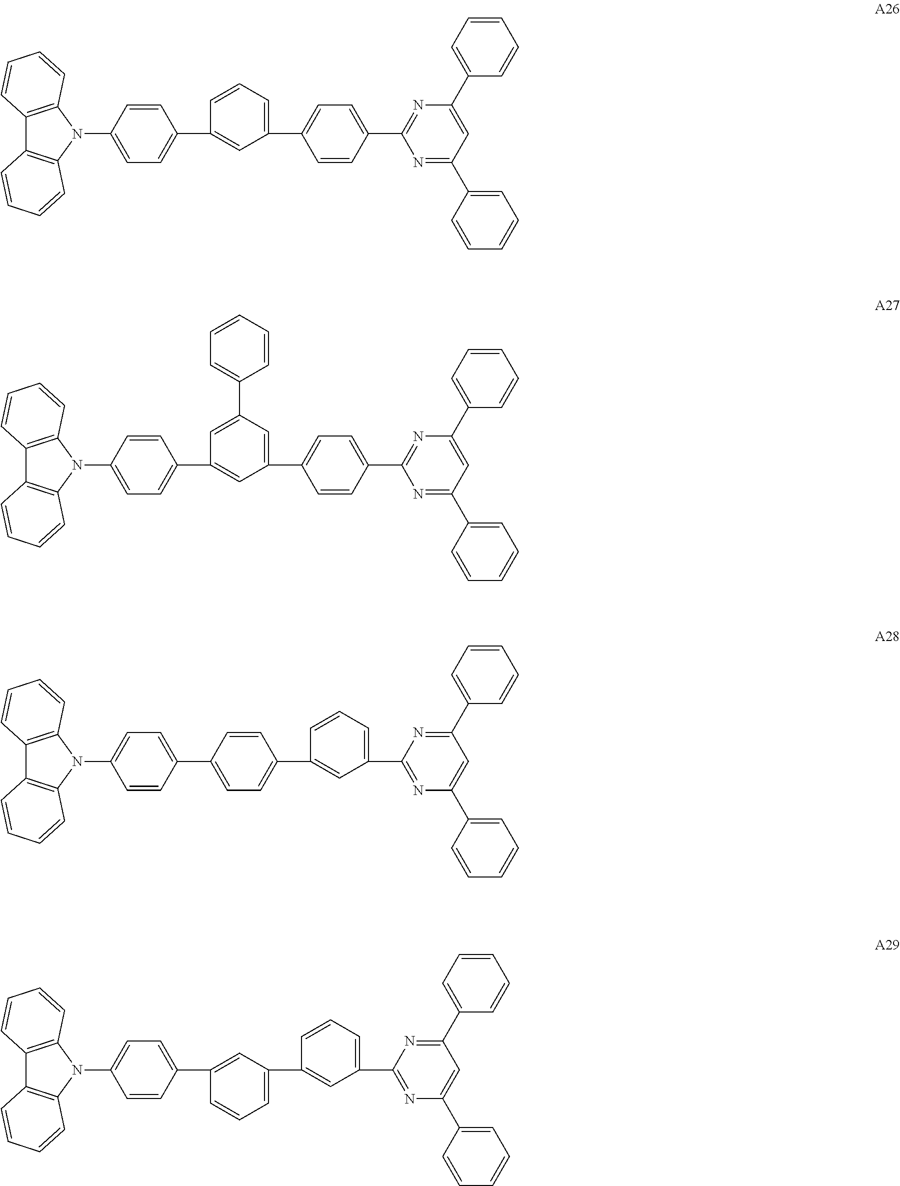 [SMILES: c1ccc(-c2cc(-c3ccccc3)nc(-c3ccc(-c4cccc(-c5ccc(-n6c7ccccc7c7ccccc76)cc5)c4)cc3)n2)cc1 ; c1ccc(-c2cc(-c3ccc(-c4nc(-c5ccccc5)cc(-c5ccccc5)n4)cc3)cc(-c3ccc(-n4c5ccccc5c5ccccc54)cc3)c2)cc1 ; c1ccc(-c2cc(-c3ccccc3)nc(-c3cccc(-c4ccc(-c5ccc(-n6c7ccccc7c7ccccc76)cc5)cc4)c3)n2)cc1 ; c1ccc(-c2cc(-c3ccccc3)nc(-c3cccc(-c4cccc(-c5ccc(-n6c7ccccc7c7ccccc76)cc5)c4)c3)n2)cc1]

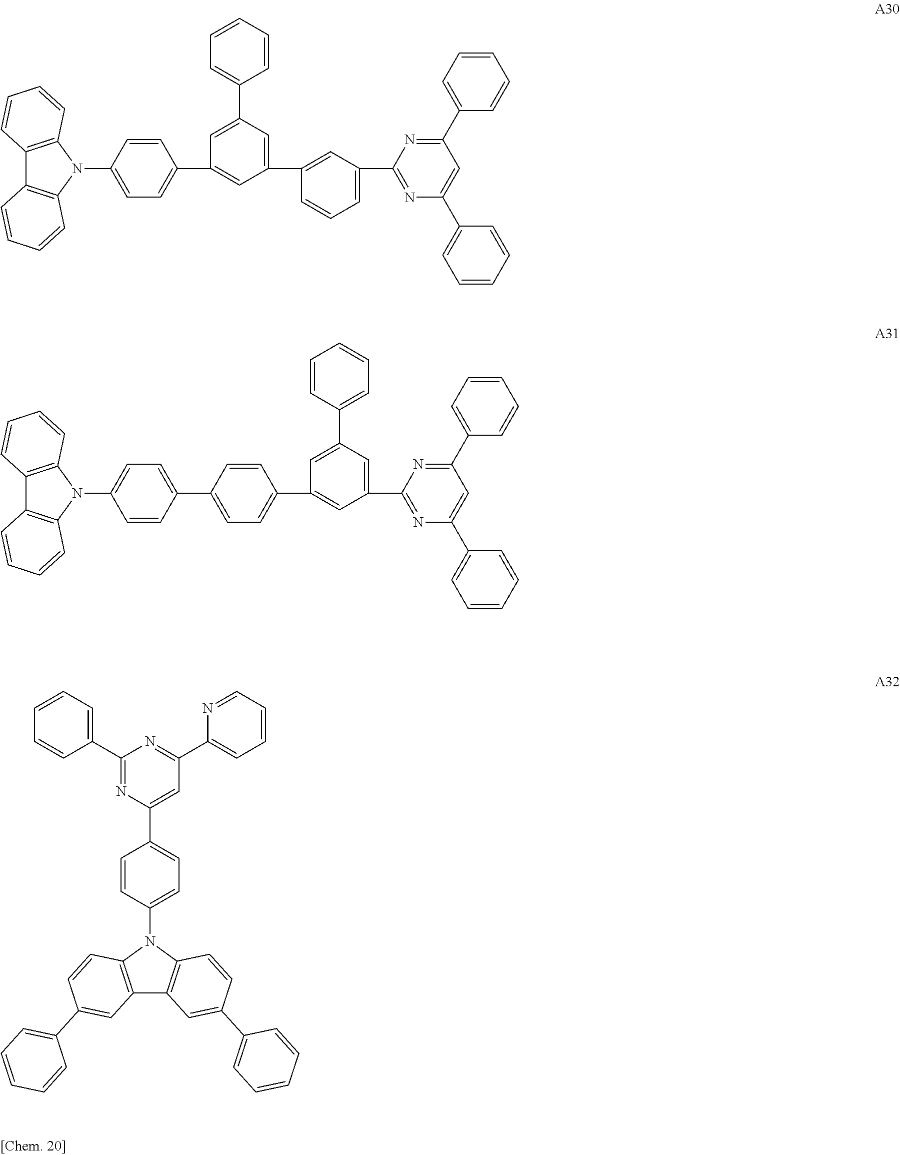 [SMILES: c1ccc(-c2cc(-c3ccc(-n4c5ccccc5c5ccccc54)cc3)cc(-c3cccc(-c4nc(-c5ccccc5)cc(-c5ccccc5)n4)c3)c2)cc1 ; c1ccc(-c2cc(-c3ccc(-c4ccc(-n5c6ccccc6c6ccccc65)cc4)cc3)cc(-c3nc(-c4ccccc4)cc(-c4ccccc4)n3)c2)cc1 ; c1ccc(-c2ccc3c(c2)c2cc(-c4ccccc4)ccc2n3-c2ccc(-c3cc(-c4ccccn4)nc(-c4ccccc4)n3)cc2)cc1]

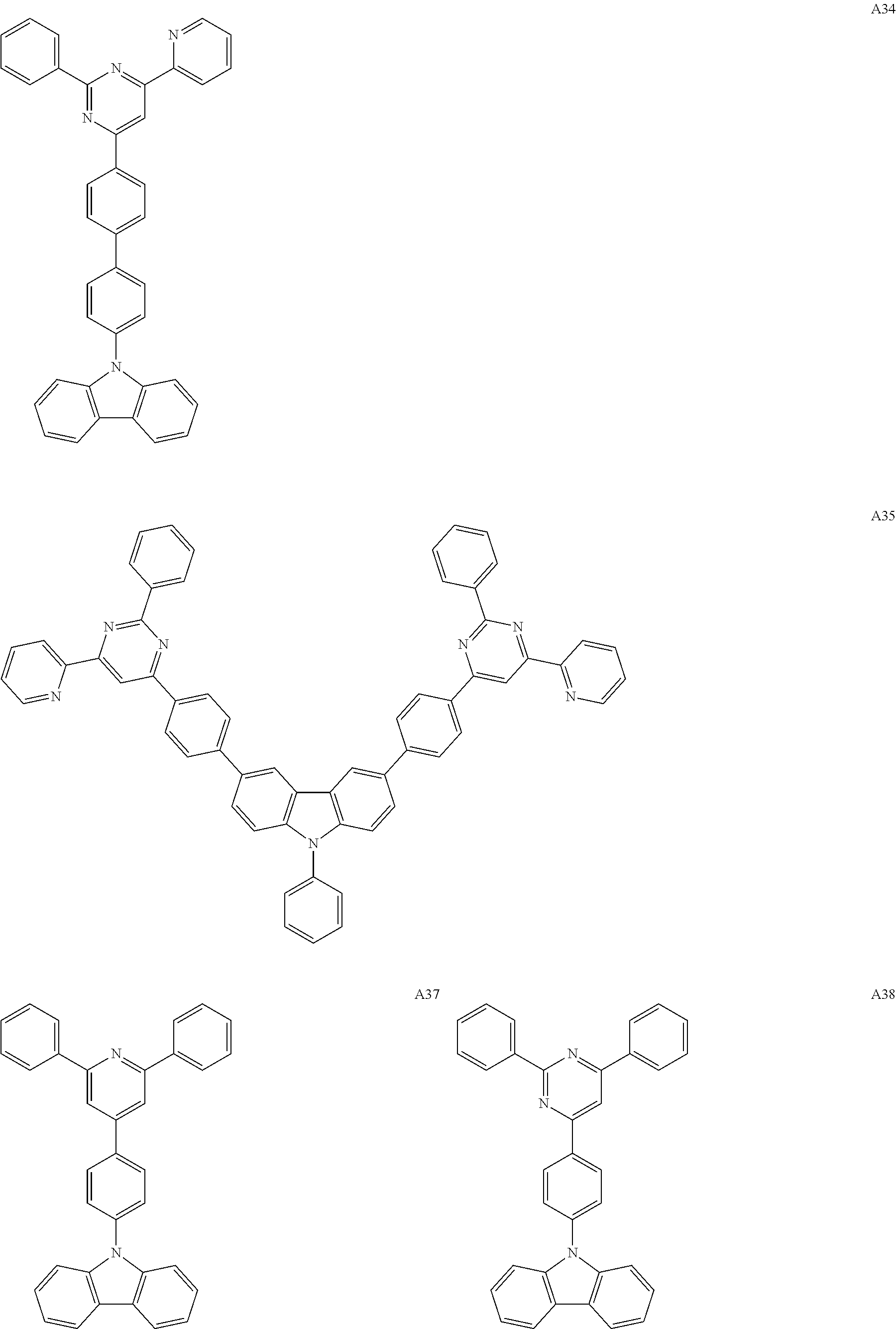 [SMILES: c1ccc(-c2nc(-c3ccc(-c4ccc(-n5c6ccccc6c6ccccc65)cc4)cc3)cc(-c3ccccn3)n2)cc1 ; c1ccc(-c2nc(-c3ccc(-c4ccc5c(c4)c4cc(-c6ccc(-c7cc(-c8ccccn8)nc(-c8ccccc8)n7)cc6)ccc4n5-c4ccccc4)cc3)cc(-c3ccccn3)n2)cc1 ; c1ccc(-c2cc(-c3ccc(-n4c5ccccc5c5ccccc54)cc3)cc(-c3ccccc3)n2)cc1 ; c1ccc(-c2cc(-c3ccc(-n4c5ccccc5c5ccccc54)cc3)nc(-c3ccccc3)n2)cc1]

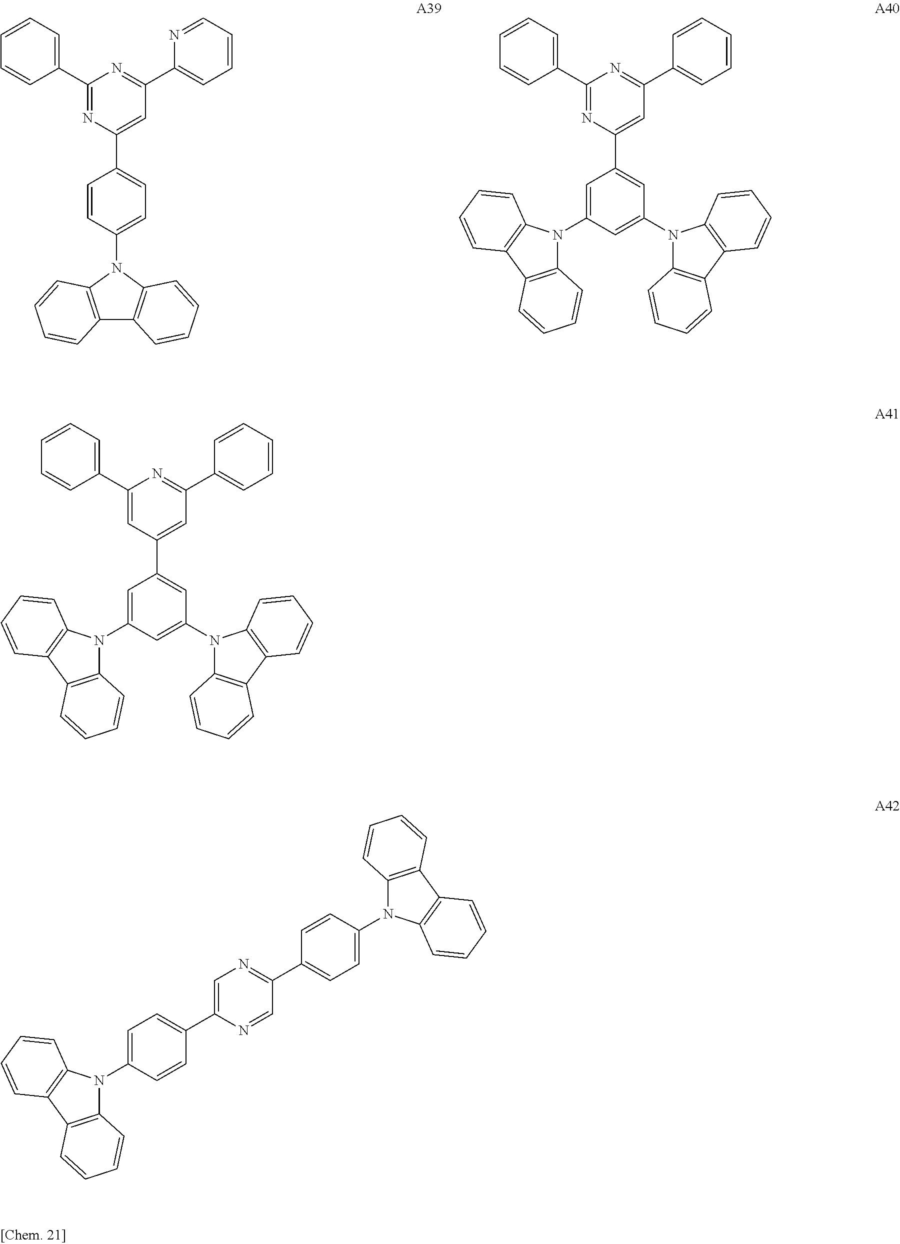 [SMILES: c1ccc(-c2nc(-c3ccc(-n4c5ccccc5c5ccccc54)cc3)cc(-c3ccccn3)n2)cc1 ; c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2cc(-c3cc(-n4c5ccccc5c5ccccc54)cc(-n4c5ccccc5c5ccccc54)c3)cc(-c3ccccc3)n2)cc1 ; c1ccc2c(c1)c1ccccc1n2-c1ccc(-c2cnc(-c3ccc(-n4c5ccccc5c5ccccc54)cc3)cn2)cc1]

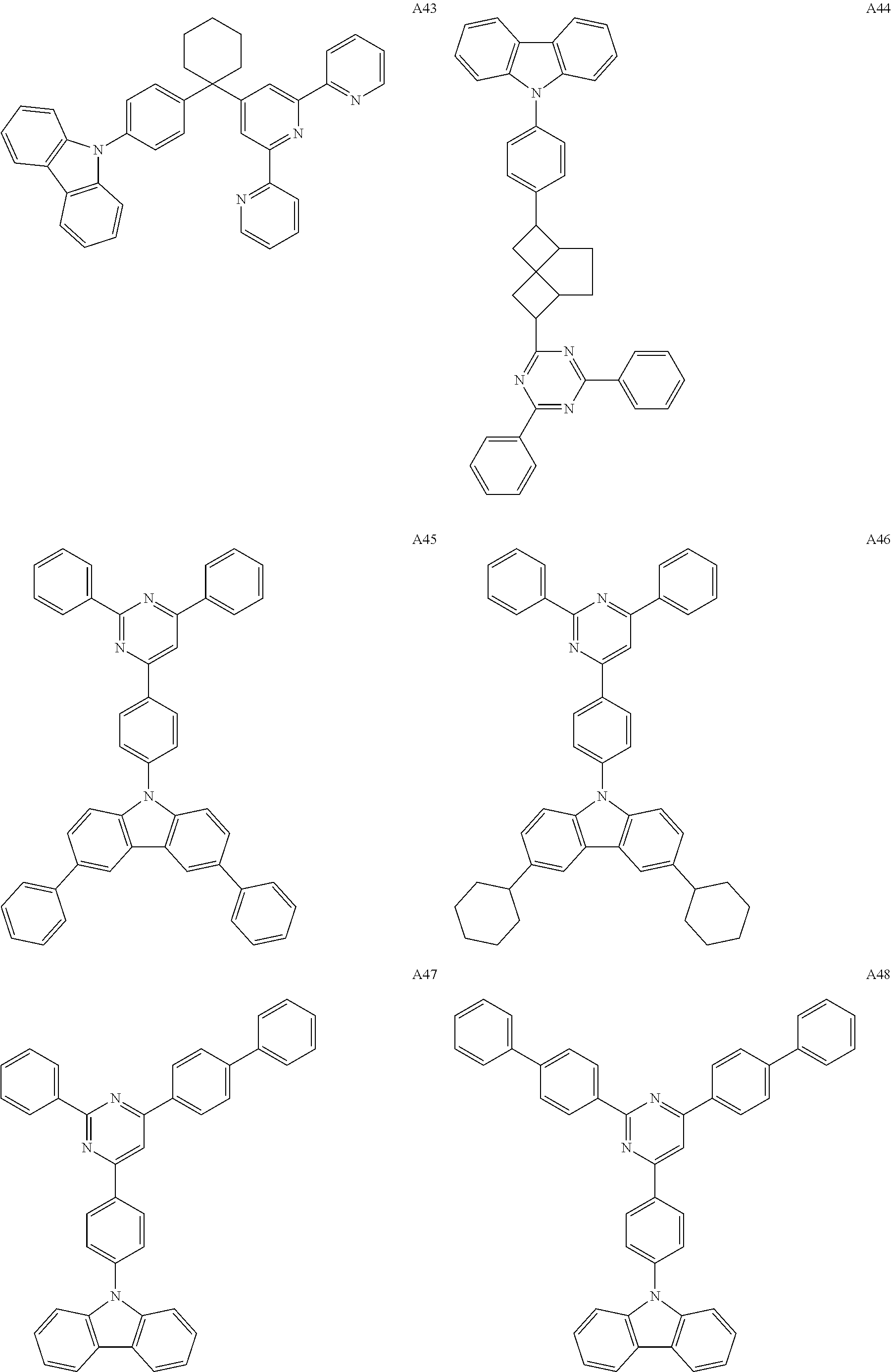 [SMILES: c1ccc(-c2cc(C3(c4ccc(-n5c6ccccc6c6ccccc65)cc4)CCCCC3)cc(-c3ccccn3)n2)nc1 ; c1ccc(-c2nc(-c3ccccc3)nc(C3CC45CC(c6ccc(-n7c8ccccc8c8ccccc87)cc6)C4CCC35)n2)cc1 ; c1ccc(-c2ccc3c(c2)c2cc(-c4ccccc4)ccc2n3-c2ccc(-c3cc(-c4ccccc4)nc(-c4ccccc4)n3)cc2)cc1 ; c1ccc(-c2cc(-c3ccc(-n4c5ccc(C6CCCCC6)cc5c5cc(C6CCCCC6)ccc54)cc3)nc(-c3ccccc3)n2)cc1 ; c1ccc(-c2ccc(-c3cc(-c4ccc(-n5c6ccccc6c6ccccc65)cc4)nc(-c4ccccc4)n3)cc2)cc1 ; c1ccc(-c2ccc(-c3cc(-c4ccc(-n5c6ccccc6c6ccccc65)cc4)nc(-c4ccc(-c5ccccc5)cc4)n3)cc2)cc1]

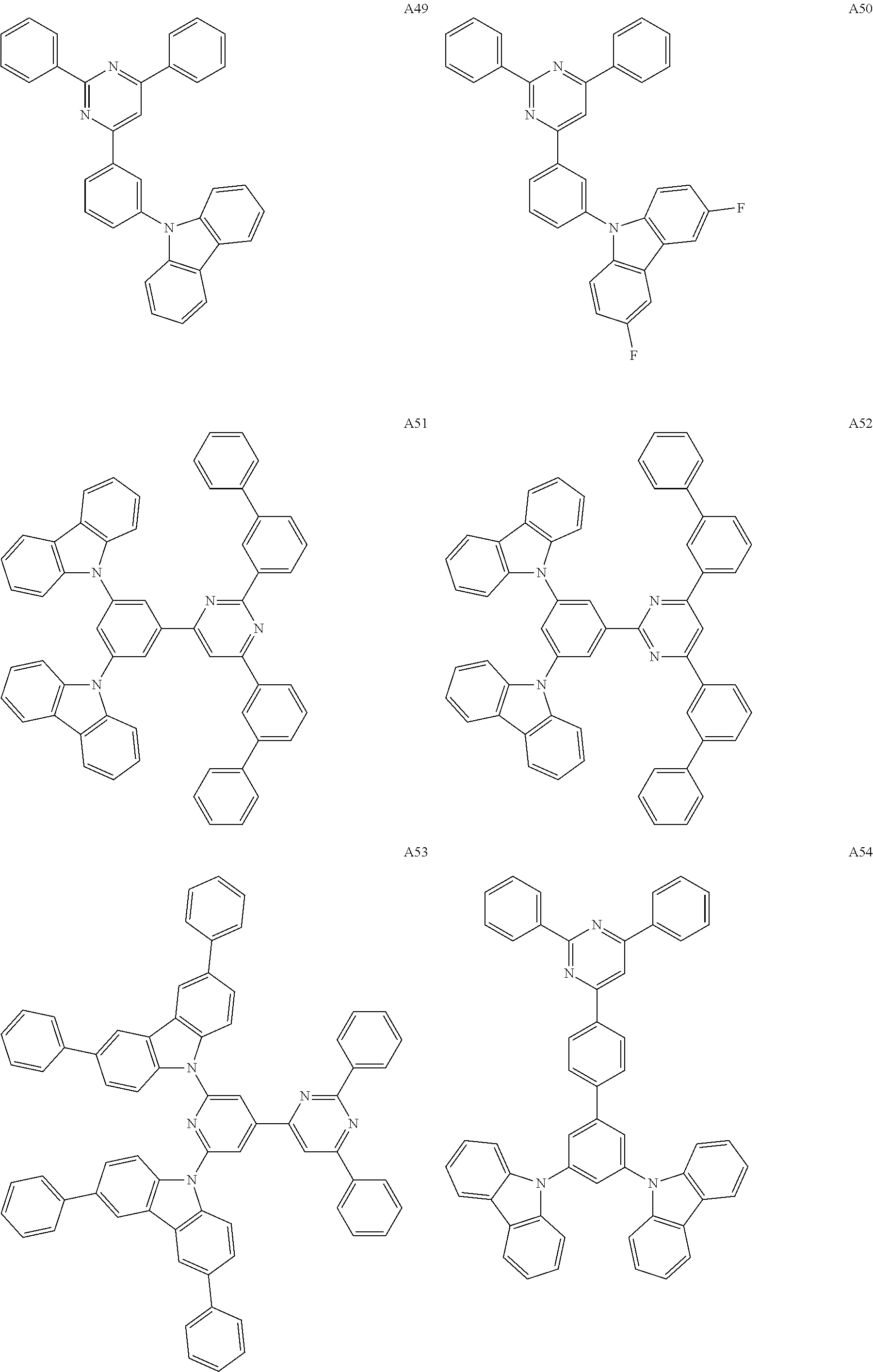

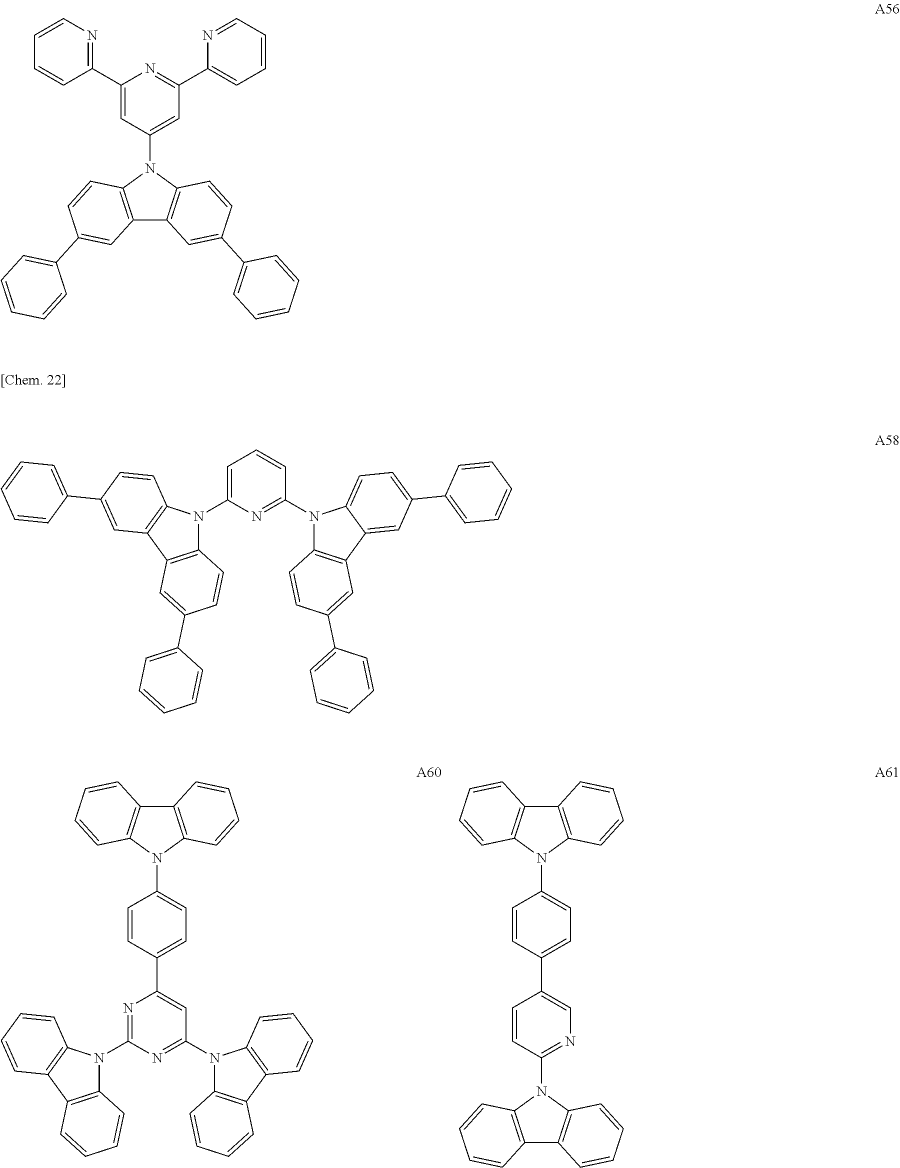 [SMILES: c1ccc(-c2ccc3c(c2)c2cc(-c4ccccc4)ccc2n3-c2cc(-c3ccccn3)nc(-c3ccccn3)c2)cc1 ; c1ccc(-c2ccc3c(c2)c2cc(-c4ccccc4)ccc2n3-c2cccc(-n3c4ccc(-c5ccccc5)cc4c4cc(-c5ccccc5)ccc43)n2)cc1 ; c1ccc2c(c1)c1ccccc1n2-c1ccc(-c2cc(-n3c4ccccc4c4ccccc43)nc(-n3c4ccccc4c4ccccc43)n2)cc1 ; c1ccc2c(c1)c1ccccc1n2-c1ccc(-c2ccc(-n3c4ccccc4c4ccccc43)nc2)cc1]

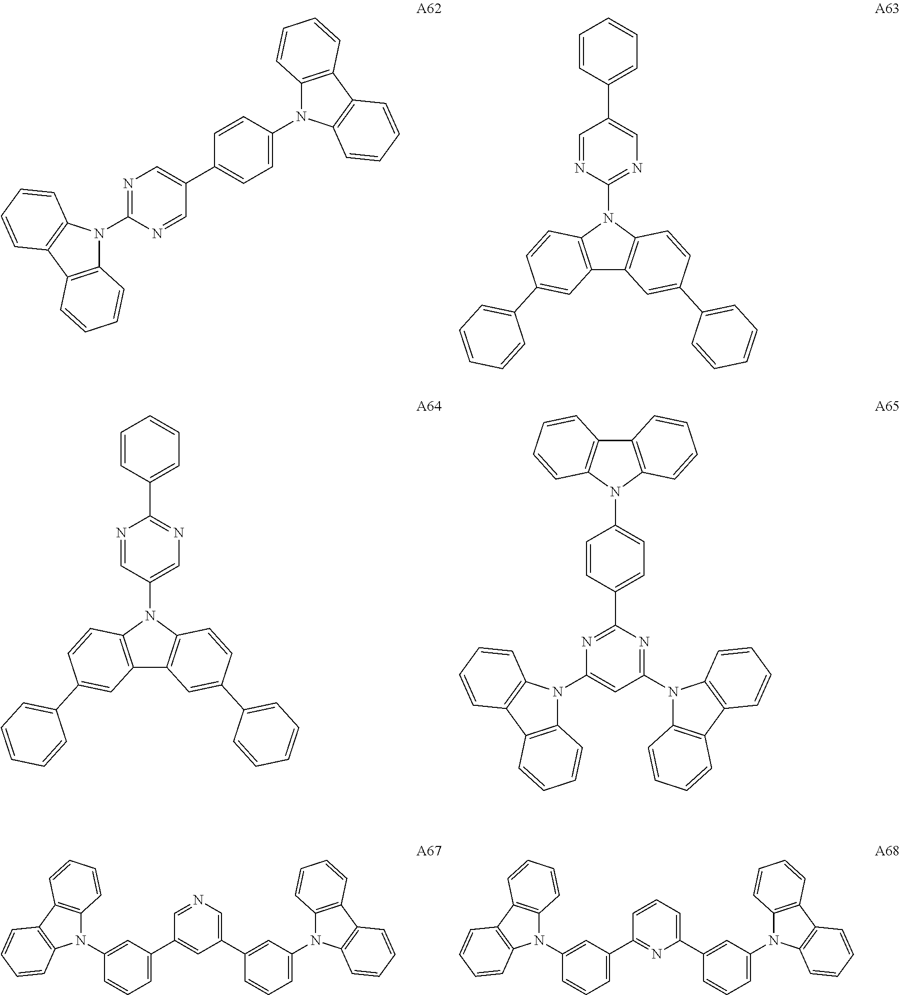 [SMILES: c1ccc2c(c1)c1ccccc1n2-c1ccc(-c2cnc(-n3c4ccccc4c4ccccc43)nc2)cc1 ; c1ccc(-c2cnc(-n3c4ccc(-c5ccccc5)cc4c4cc(-c5ccccc5)ccc43)nc2)cc1 ; c1ccc(-c2ccc3c(c2)c2cc(-c4ccccc4)ccc2n3-c2cnc(-c3ccccc3)nc2)cc1 ; c1ccc2c(c1)c1ccccc1n2-c1ccc(-c2nc(-n3c4ccccc4c4ccccc43)cc(-n3c4ccccc4c4ccccc43)n2)cc1 ; c1cc(-c2cncc(-c3cccc(-n4c5ccccc5c5ccccc54)c3)c2)cc(-n2c3ccccc3c3ccccc32)c1 ; c1cc(-c2cccc(-c3cccc(-n4c5ccccc5c5ccccc54)c3)n2)cc(-n2c3ccccc3c3ccccc32)c1]

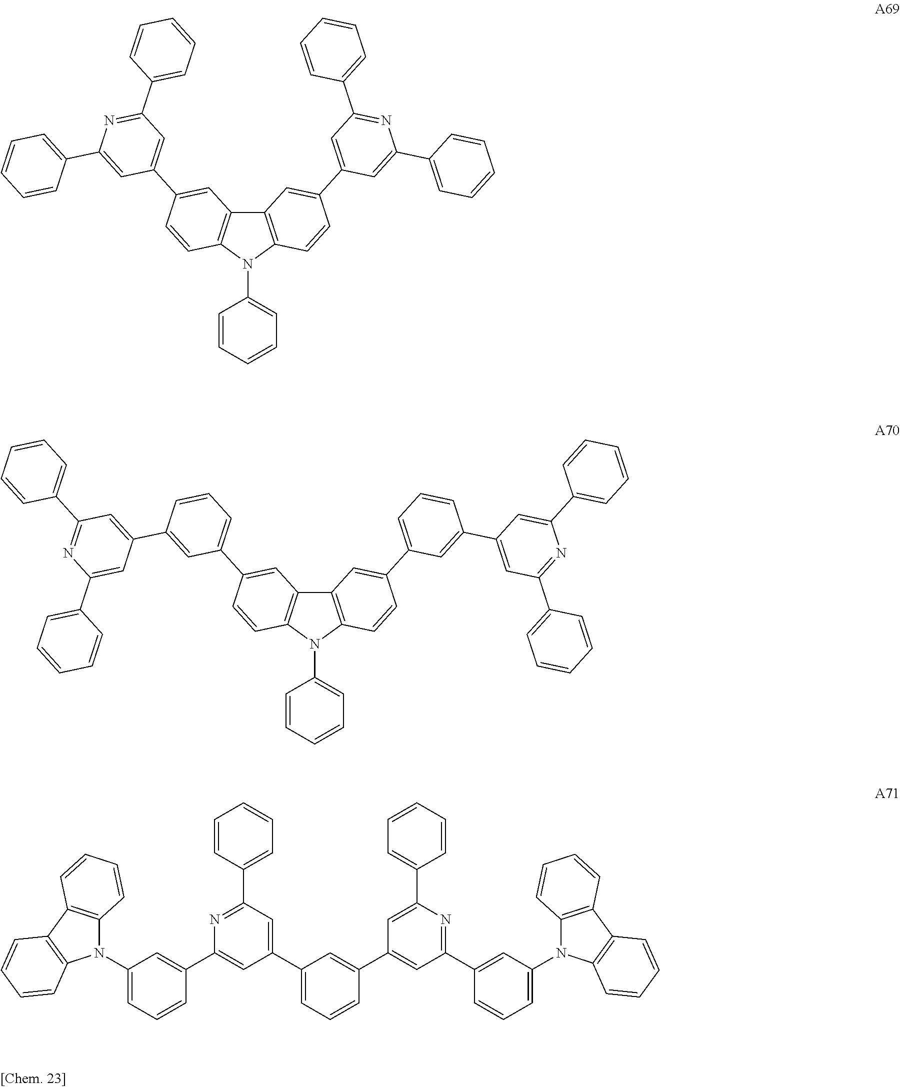 [SMILES: c1ccc(-c2cc(-c3ccc4c(c3)c3cc(-c5cc(-c6ccccc6)nc(-c6ccccc6)c5)ccc3n4-c3ccccc3)cc(-c3ccccc3)n2)cc1 ; c1ccc(-c2cc(-c3cccc(-c4ccc5c(c4)c4cc(-c6cccc(-c7cc(-c8ccccc8)nc(-c8ccccc8)c7)c6)ccc4n5-c4ccccc4)c3)cc(-c3ccccc3)n2)cc1 ; c1ccc(-c2cc(-c3cccc(-c4cc(-c5ccccc5)nc(-c5cccc(-n6c7ccccc7c7ccccc76)c5)c4)c3)cc(-c3cccc(-n4c5ccccc5c5ccccc54)c3)n2)cc1]

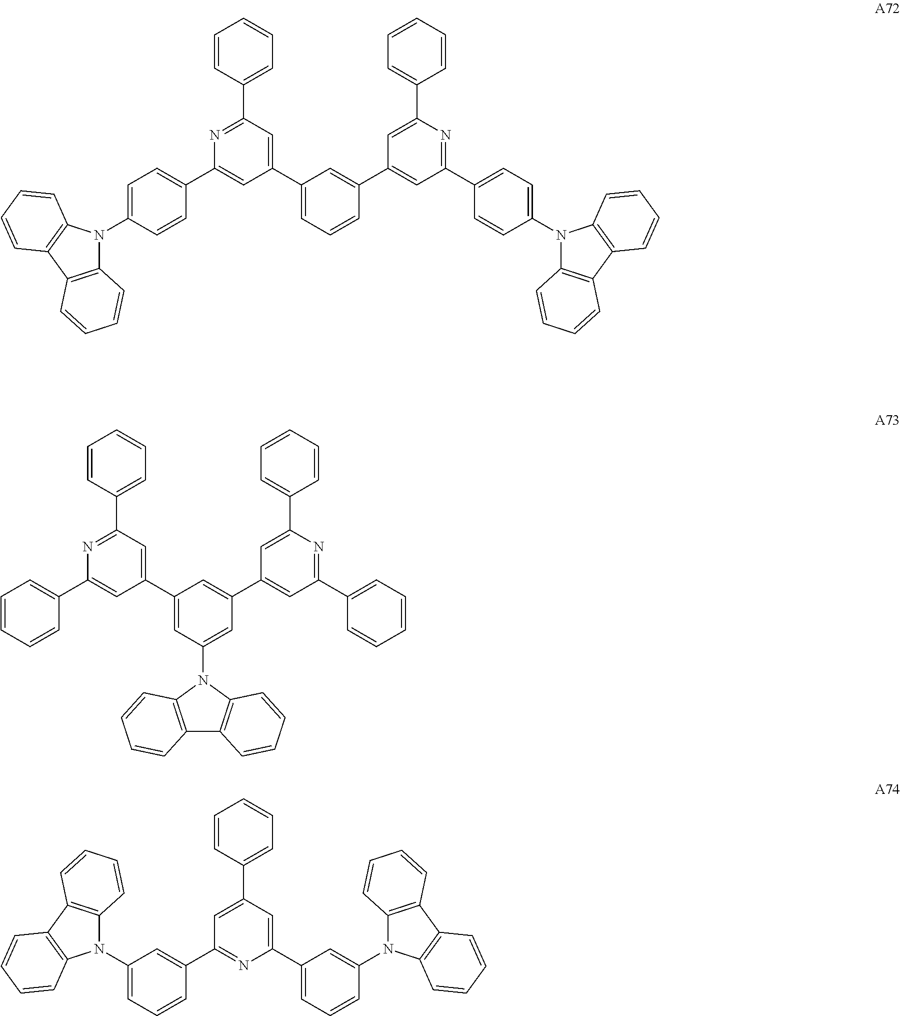

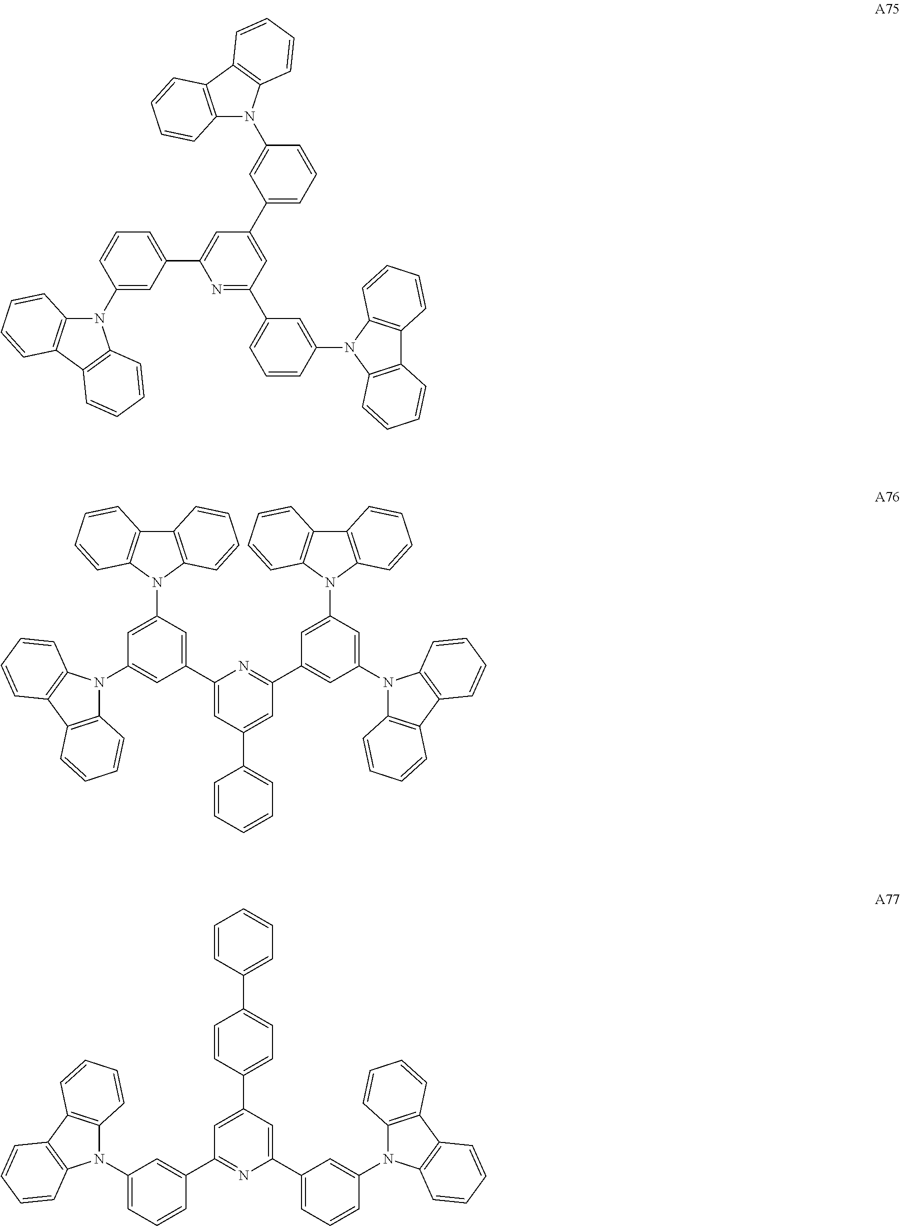 [SMILES: c1cc(-c2cc(-c3cccc(-n4c5ccccc5c5ccccc54)c3)nc(-c3cccc(-n4c5ccccc5c5ccccc54)c3)c2)cc(-n2c3ccccc3c3ccccc32)c1 ; c1ccc(-c2cc(-c3cc(-n4c5ccccc5c5ccccc54)cc(-n4c5ccccc5c5ccccc54)c3)nc(-c3cc(-n4c5ccccc5c5ccccc54)cc(-n4c5ccccc5c5ccccc54)c3)c2)cc1 ; c1ccc(-c2ccc(-c3cc(-c4cccc(-n5c6ccccc6c6ccccc65)c4)nc(-c4cccc(-n5c6ccccc6c6ccccc65)c4)c3)cc2)cc1]

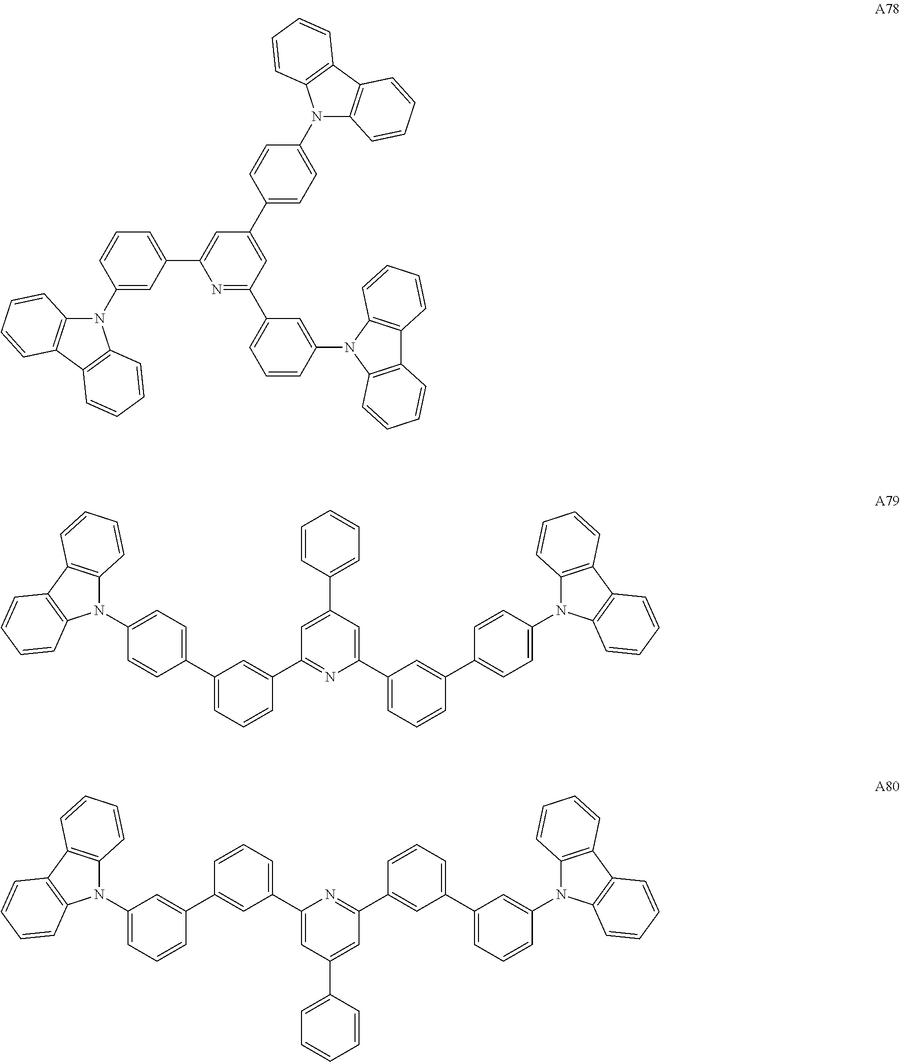 [SMILES: c1cc(-c2cc(-c3ccc(-n4c5ccccc5c5ccccc54)cc3)cc(-c3cccc(-n4c5ccccc5c5ccccc54)c3)n2)cc(-n2c3ccccc3c3ccccc32)c1 ; c1ccc(-c2cc(-c3cccc(-c4ccc(-n5c6ccccc6c6ccccc65)cc4)c3)nc(-c3cccc(-c4ccc(-n5c6ccccc6c6ccccc65)cc4)c3)c2)cc1 ; c1ccc(-c2cc(-c3cccc(-c4cccc(-n5c6ccccc6c6ccccc65)c4)c3)nc(-c3cccc(-c4cccc(-n5c6ccccc6c6ccccc65)c4)c3)c2)cc1]

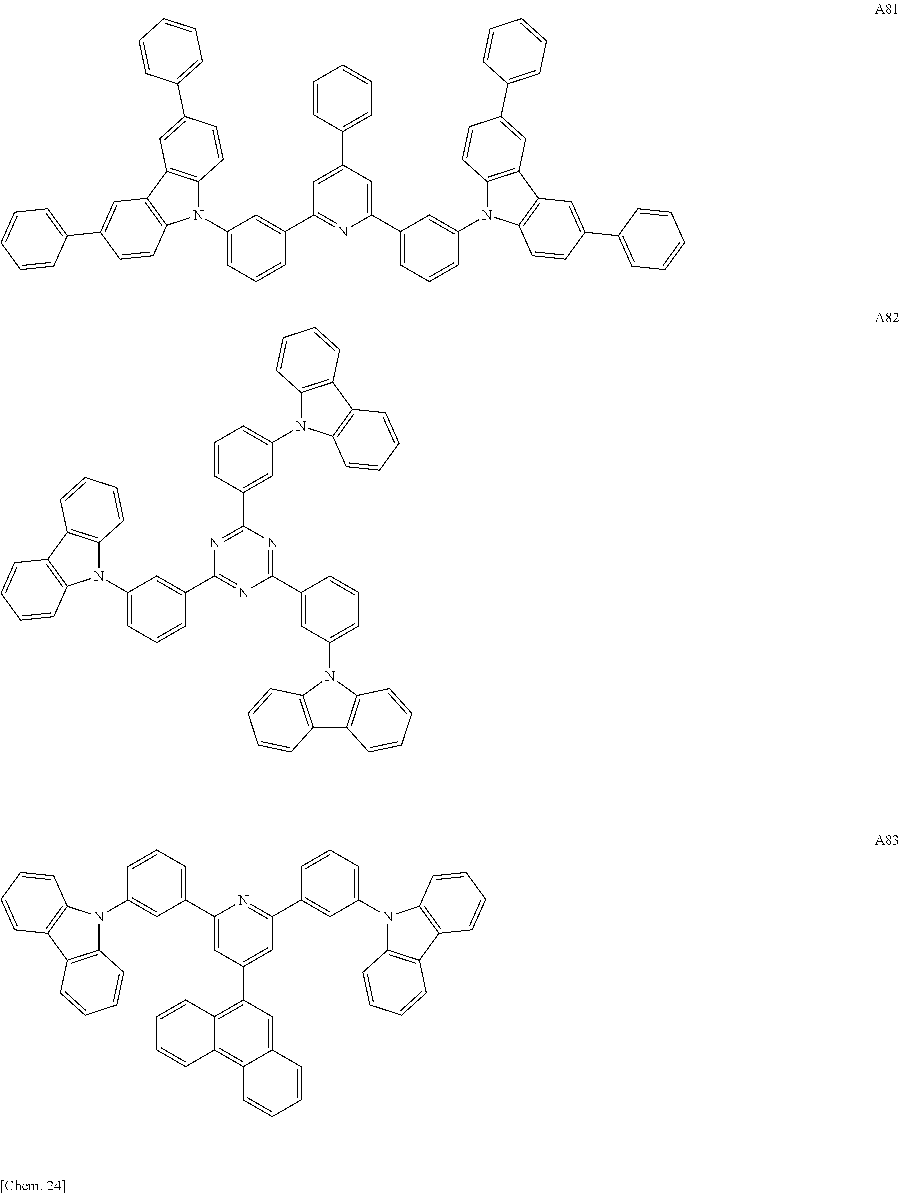 [SMILES: c1ccc(-c2cc(-c3cccc(-n4c5ccc(-c6ccccc6)cc5c5cc(-c6ccccc6)ccc54)c3)nc(-c3cccc(-n4c5ccc(-c6ccccc6)cc5c5cc(-c6ccccc6)ccc54)c3)c2)cc1 ; c1cc(-c2nc(-c3cccc(-n4c5ccccc5c5ccccc54)c3)nc(-c3cccc(-n4c5ccccc5c5ccccc54)c3)n2)cc(-n2c3ccccc3c3ccccc32)c1 ; c1cc(-c2cc(-c3cc4ccccc4c4ccccc34)cc(-c3cccc(-n4c5ccccc5c5ccccc54)c3)n2)cc(-n2c3ccccc3c3ccccc32)c1]

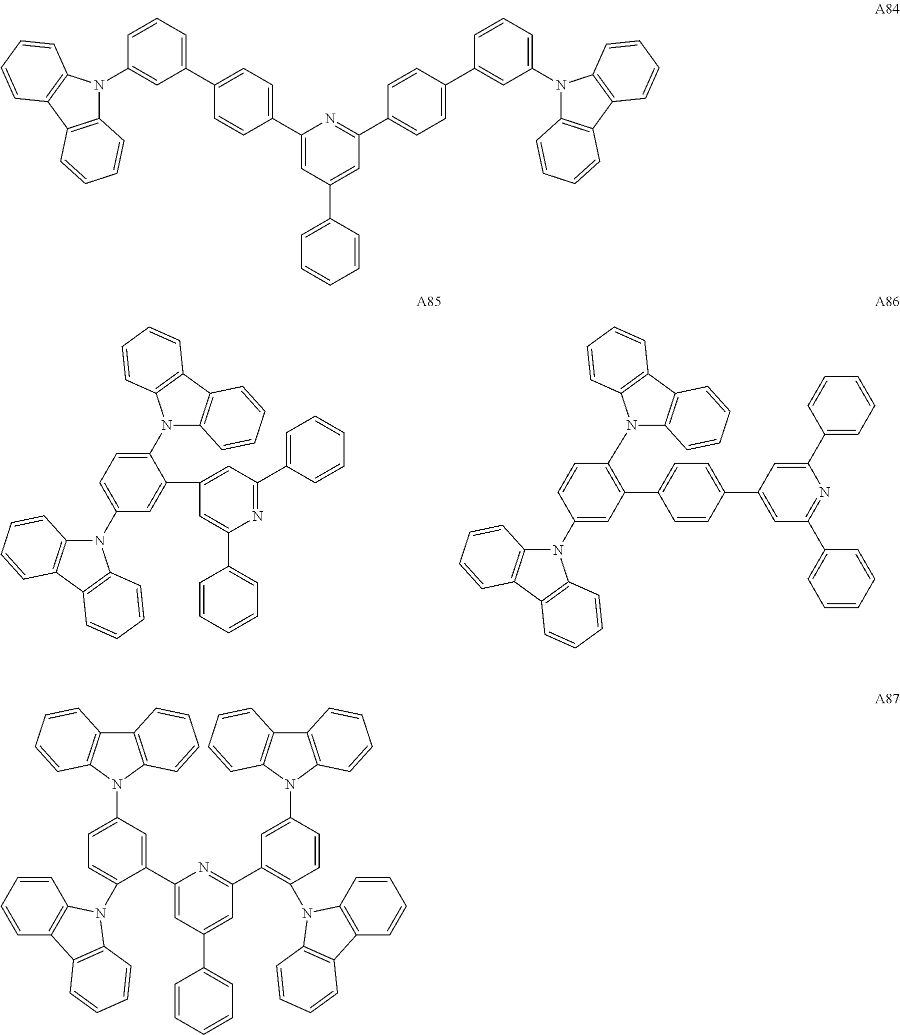 [SMILES: c1ccc(-c2cc(-c3ccc(-c4cccc(-n5c6ccccc6c6ccccc65)c4)cc3)nc(-c3ccc(-c4cccc(-n5c6ccccc6c6ccccc65)c4)cc3)c2)cc1 ; c1ccc(-c2cc(-c3cc(-n4c5ccccc5c5ccccc54)ccc3-n3c4ccccc4c4ccccc43)cc(-c3ccccc3)n2)cc1 ; c1ccc(-c2cc(-c3ccc(-c4cc(-n5c6ccccc6c6ccccc65)ccc4-n4c5ccccc5c5ccccc54)cc3)cc(-c3ccccc3)n2)cc1 ; c1ccc(-c2cc(-c3cc(-n4c5ccccc5c5ccccc54)ccc3-n3c4ccccc4c4ccccc43)nc(-c3cc(-n4c5ccccc5c5ccccc54)ccc3-n3c4ccccc4c4ccccc43)c2)cc1]

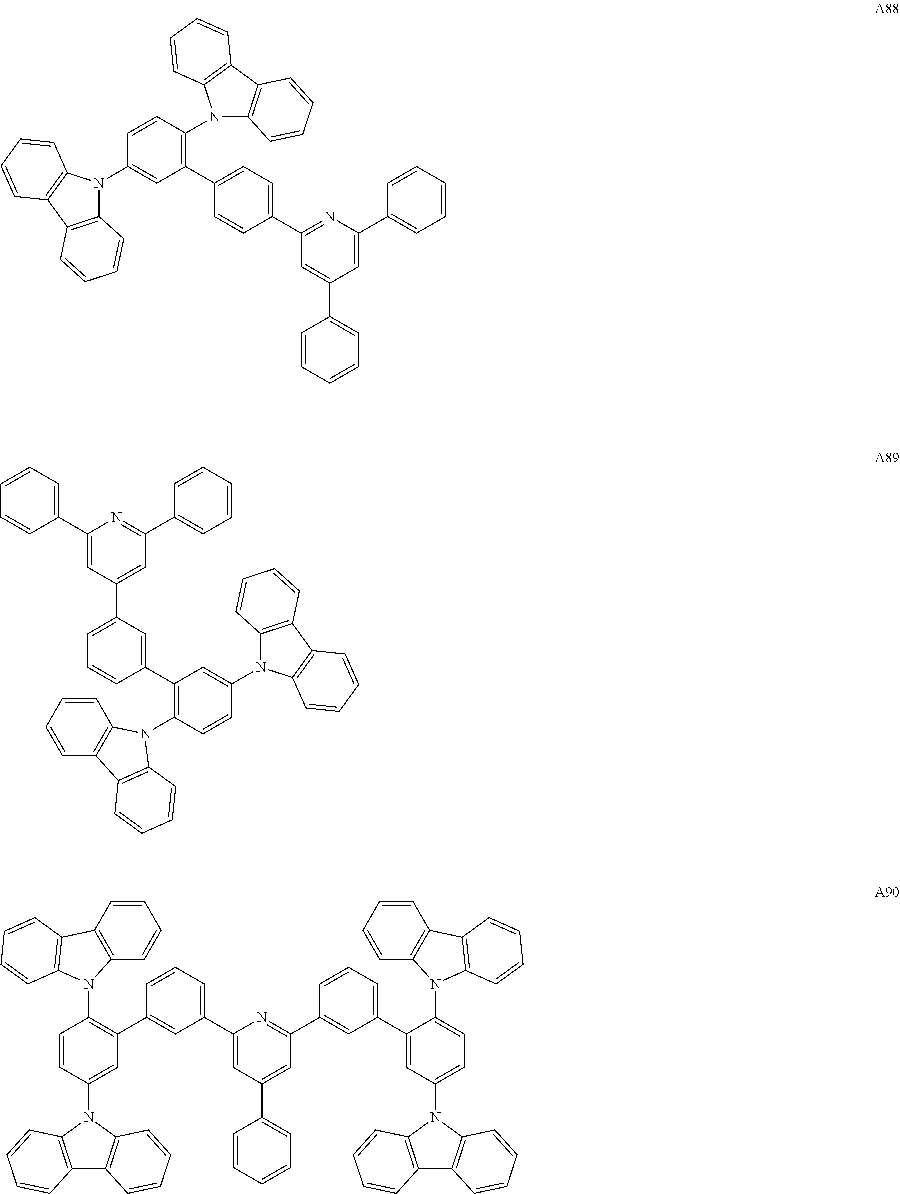 [SMILES: c1ccc(-c2cc(-c3ccccc3)nc(-c3ccc(-c4cc(-n5c6ccccc6c6ccccc65)ccc4-n4c5ccccc5c5ccccc54)cc3)c2)cc1 ; c1ccc(-c2cc(-c3cccc(-c4cc(-n5c6ccccc6c6ccccc65)ccc4-n4c5ccccc5c5ccccc54)c3)cc(-c3ccccc3)n2)cc1 ; c1ccc(-c2cc(-c3cccc(-c4cc(-n5c6ccccc6c6ccccc65)ccc4-n4c5ccccc5c5ccccc54)c3)nc(-c3cccc(-c4cc(-n5c6ccccc6c6ccccc65)ccc4-n4c5ccccc5c5ccccc54)c3)c2)cc1]

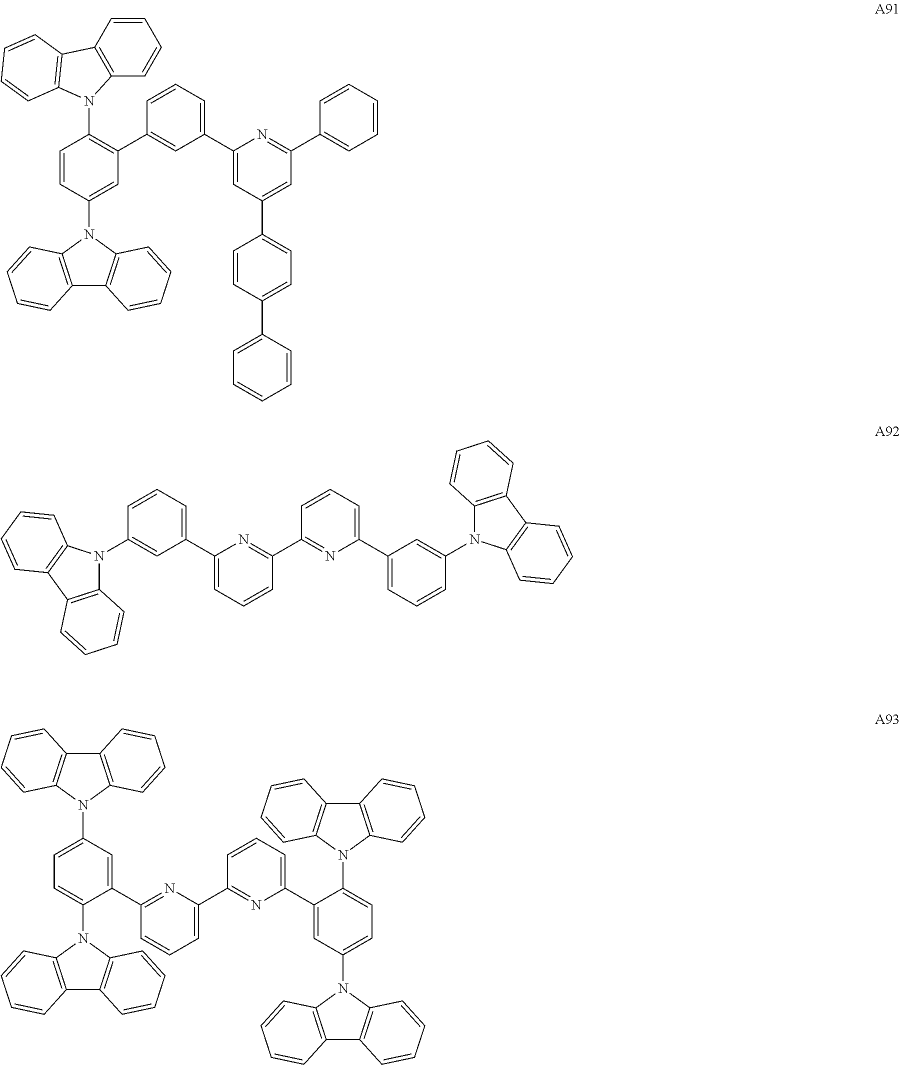 [SMILES: c1ccc(-c2ccc(-c3cc(-c4ccccc4)nc(-c4cccc(-c5cc(-n6c7ccccc7c7ccccc76)ccc5-n5c6ccccc6c6ccccc65)c4)c3)cc2)cc1 ; c1cc(-c2cccc(-c3cccc(-c4cccc(-n5c6ccccc6c6ccccc65)c4)n3)n2)cc(-n2c3ccccc3c3ccccc32)c1 ; c1cc(-c2cccc(-c3cc(-n4c5ccccc5c5ccccc54)ccc3-n3c4ccccc4c4ccccc43)n2)nc(-c2cc(-n3c4ccccc4c4ccccc43)ccc2-n2c3ccccc3c3ccccc32)c1]

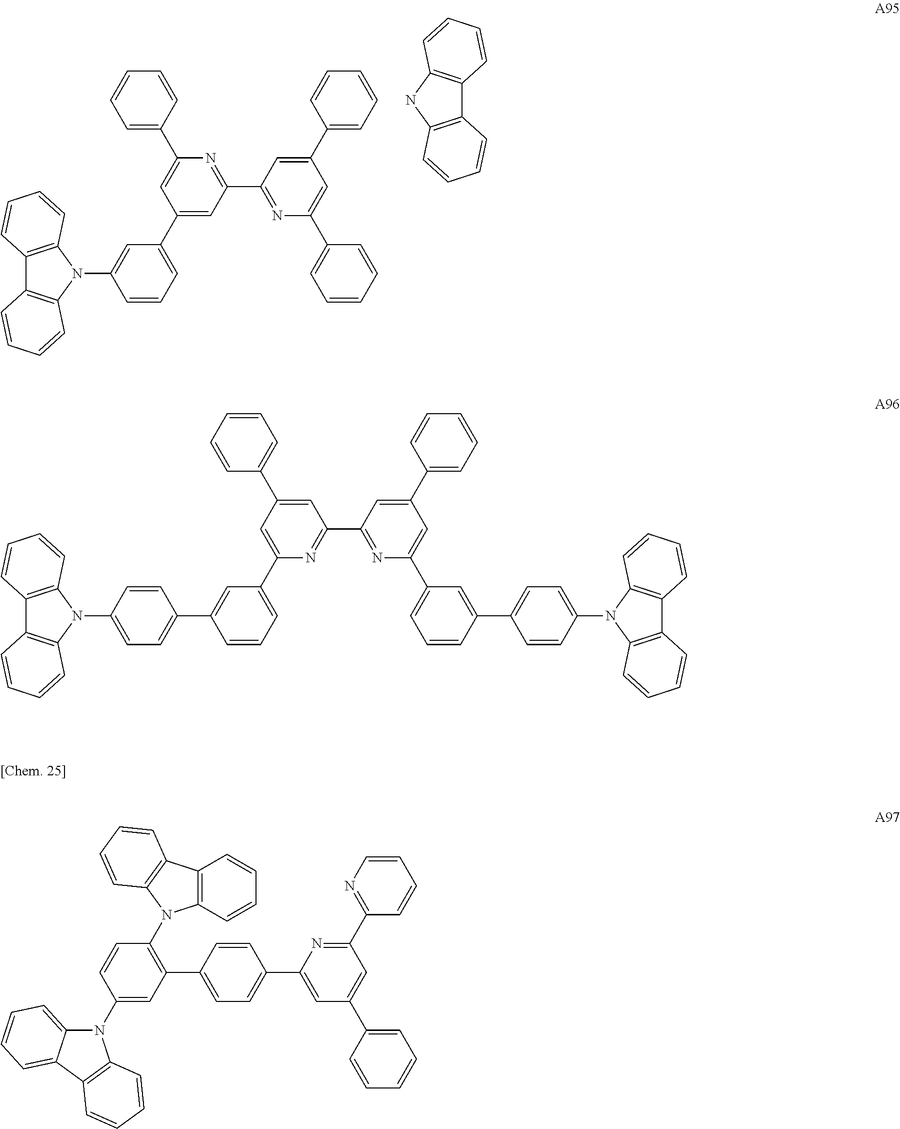

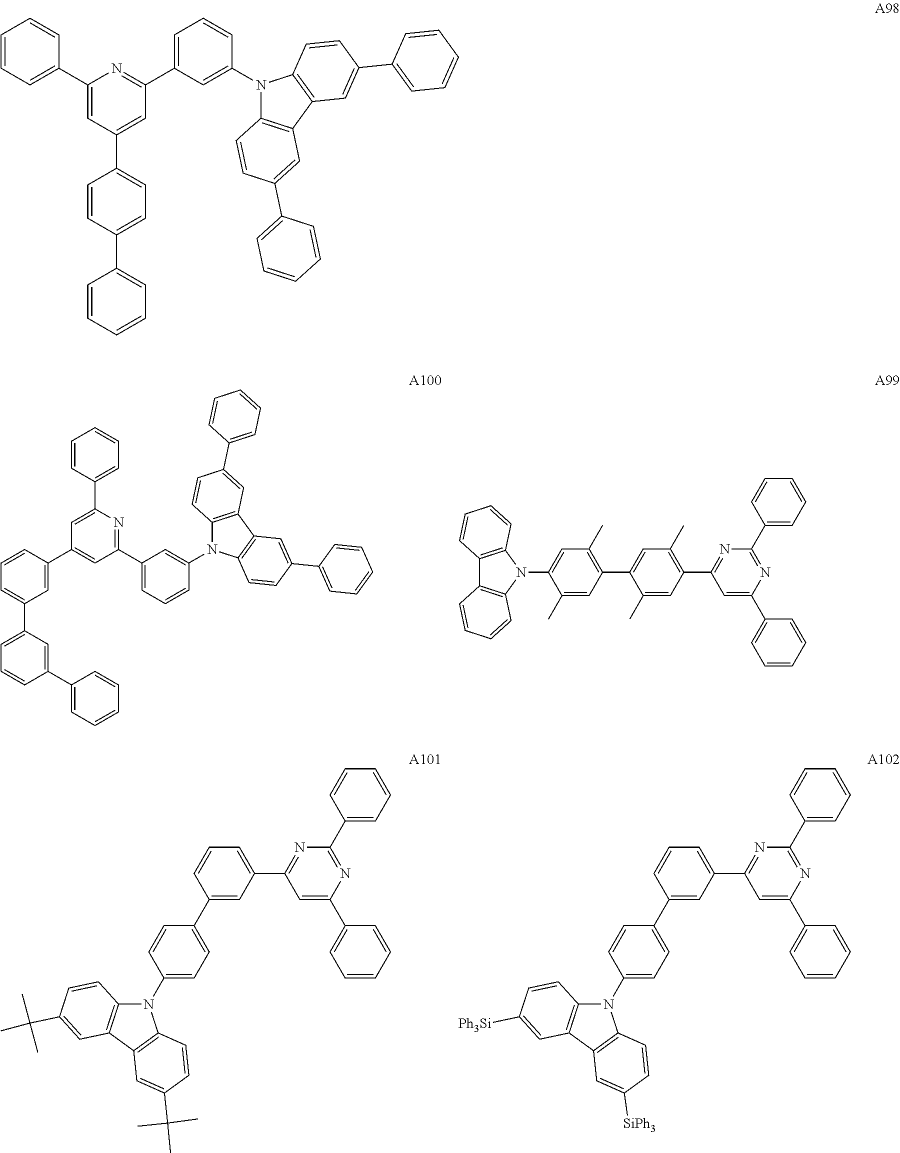

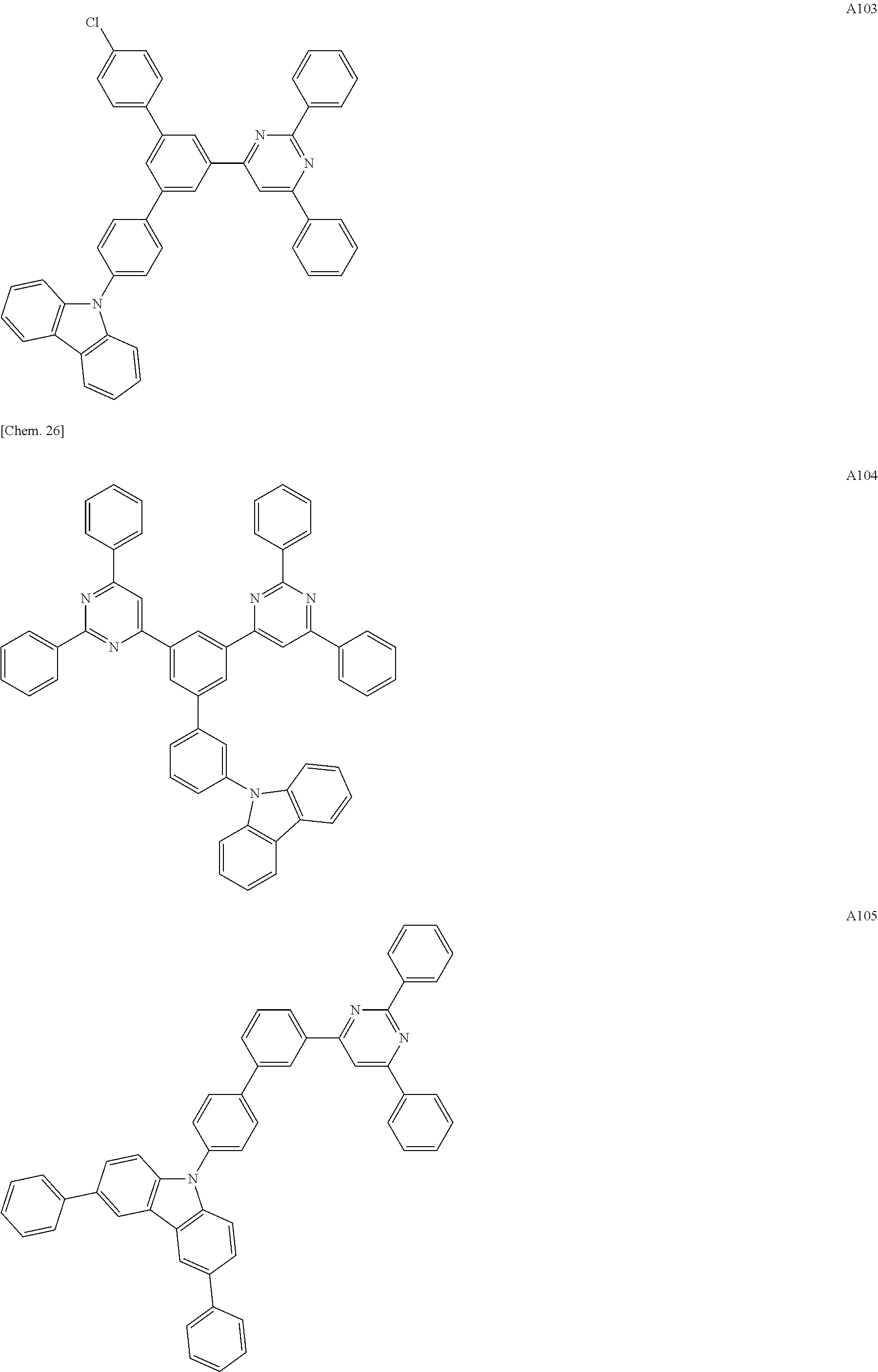 [SMILES: Clc1ccc(-c2cc(-c3ccc(-n4c5ccccc5c5ccccc54)cc3)cc(-c3cc(-c4ccccc4)nc(-c4ccccc4)n3)c2)cc1 ; c1ccc(-c2cc(-c3cc(-c4cccc(-n5c6ccccc6c6ccccc65)c4)cc(-c4cc(-c5ccccc5)nc(-c5ccccc5)n4)c3)nc(-c3ccccc3)n2)cc1 ; c1ccc(-c2ccc3c(c2)c2cc(-c4ccccc4)ccc2n3-c2ccc(-c3cccc(-c4cc(-c5ccccc5)nc(-c5ccccc5)n4)c3)cc2)cc1]

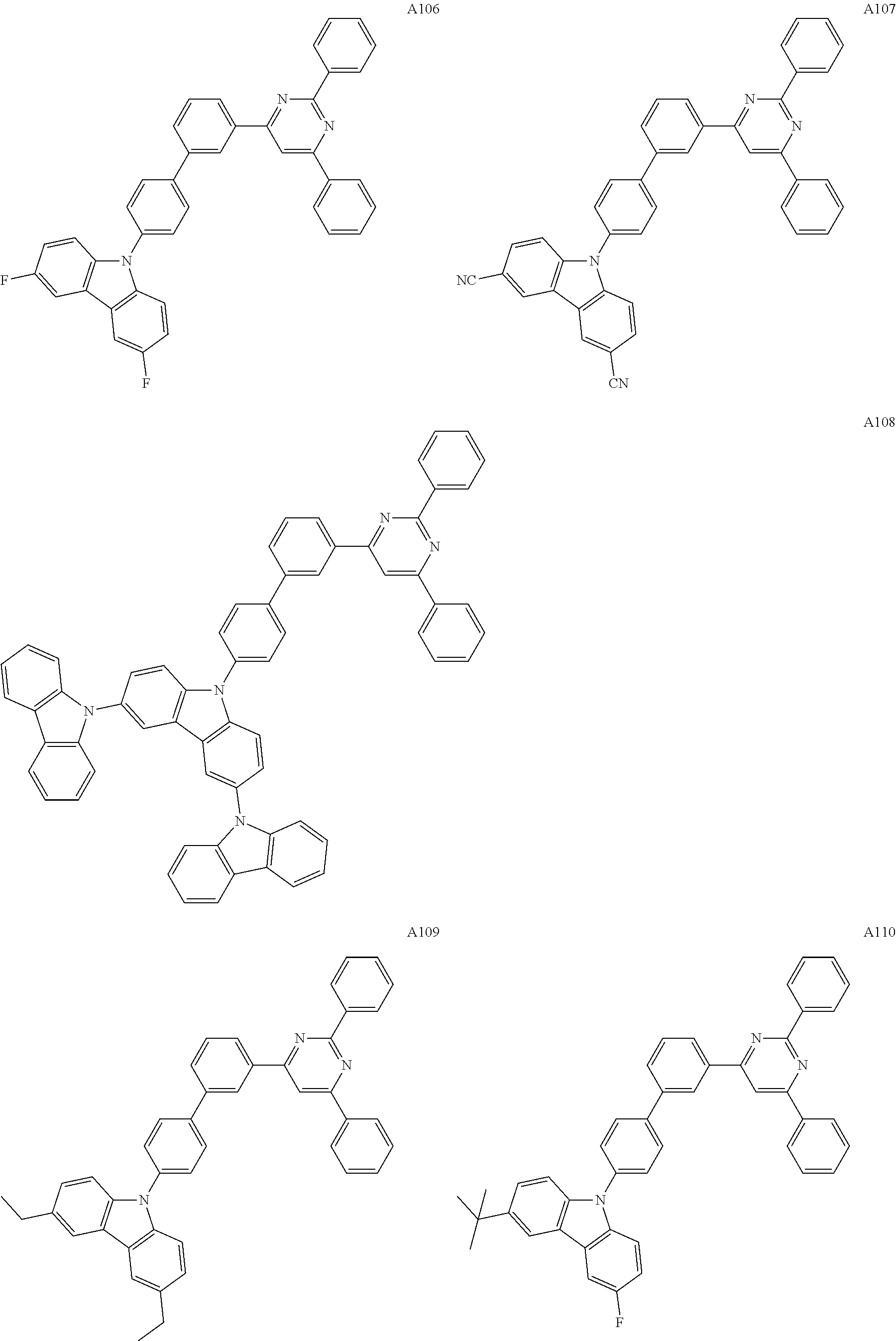 [SMILES: Fc1ccc2c(c1)c1cc(F)ccc1n2-c1ccc(-c2cccc(-c3cc(-c4ccccc4)nc(-c4ccccc4)n3)c2)cc1 ; N#Cc1ccc2c(c1)c1cc(C#N)ccc1n2-c1ccc(-c2cccc(-c3cc(-c4ccccc4)nc(-c4ccccc4)n3)c2)cc1 ; c1ccc(-c2cc(-c3cccc(-c4ccc(-n5c6ccc(-n7c8ccccc8c8ccccc87)cc6c6cc(-n7c8ccccc8c8ccccc87)ccc65)cc4)c3)nc(-c3ccccc3)n2)cc1 ; CCc1ccc2c(c1)c1cc(CC)ccc1n2-c1ccc(-c2cccc(-c3cc(-c4ccccc4)nc(-c4ccccc4)n3)c2)cc1 ; CC(C)(C)c1ccc2c(c1)c1cc(F)ccc1n2-c1ccc(-c2cccc(-c3cc(-c4ccccc4)nc(-c4ccccc4)n3)c2)cc1]

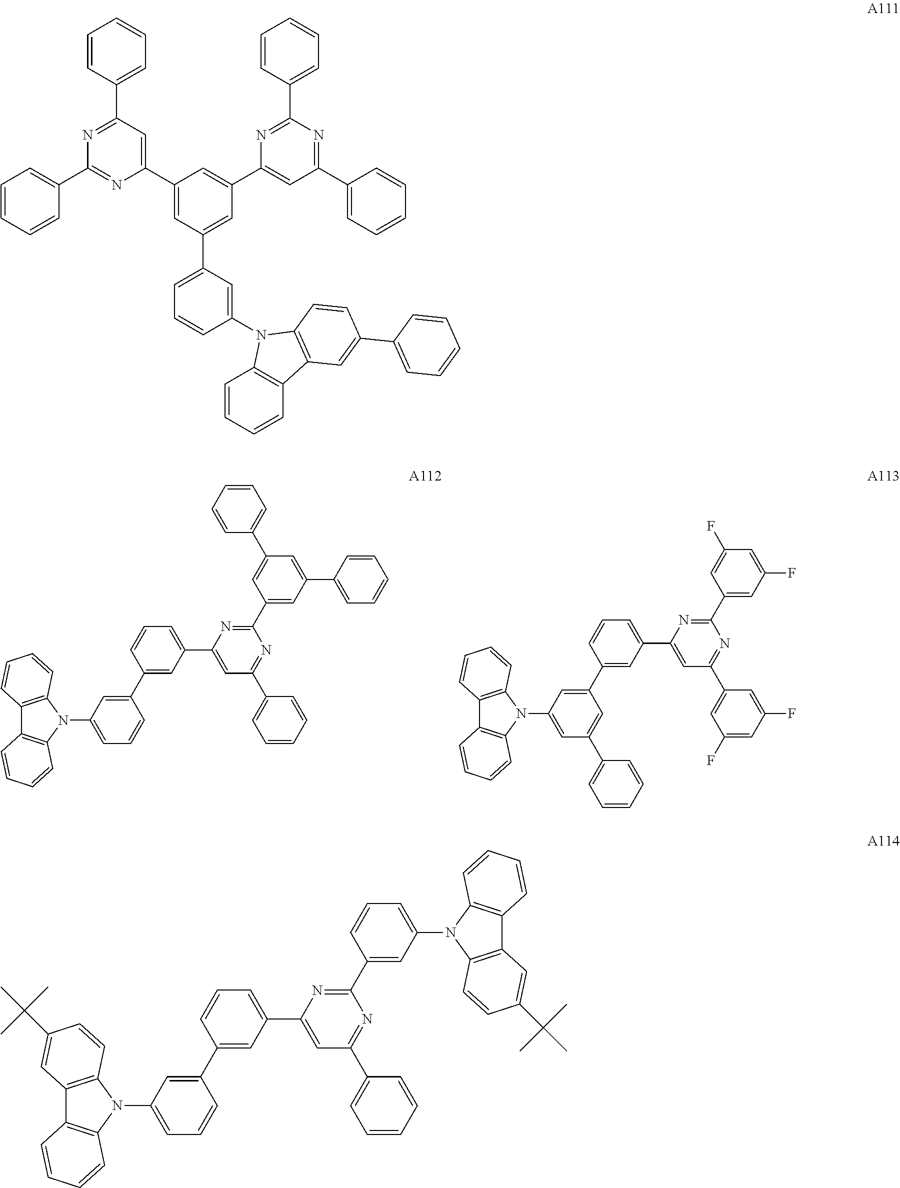 [SMILES: c1ccc(-c2ccc3c(c2)c2ccccc2n3-c2cccc(-c3cc(-c4cc(-c5ccccc5)nc(-c5ccccc5)n4)cc(-c4cc(-c5ccccc5)nc(-c5ccccc5)n4)c3)c2)cc1 ; c1ccc(-c2cc(-c3ccccc3)cc(-c3nc(-c4ccccc4)cc(-c4cccc(-c5cccc(-n6c7ccccc7c7ccccc76)c5)c4)n3)c2)cc1 ; Fc1cc(F)cc(-c2cc(-c3cccc(-c4cc(-c5ccccc5)cc(-n5c6ccccc6c6ccccc65)c4)c3)nc(-c3cc(F)cc(F)c3)n2)c1 ; CC(C)(C)c1ccc2c(c1)c1ccccc1n2-c1cccc(-c2cccc(-c3cc(-c4ccccc4)nc(-c4cccc(-n5c6ccccc6c6cc(C(C)(C)C)ccc65)c4)n3)c2)c1]

The compound exemplified as a compound represented by Formula (1) may be synthesized by various methods, such as the method described in the pamphlet of the International Publication No. WO03/080760, the method described in the pamphlet of the International Publication No. WO03/078541, the method described in the pamphlet of the International Publication No. WO05/085387, and the like.

For example, the exemplary compound A4 may be synthesized using m-bromobenzaldehide as a starting material by the method described in Paragraphs [0074] to (page 45, line 11 to page 46, line 18) of the pamphlet of the International Publication No. WO05/085387. The exemplary compound A45 may be synthesized using 3,5-dibromobenzaldehide as a starting material by the method described in page 46, line 9 to page 46, line 12 of the pamphlet of the International Publication No. WO03/080760. Further, the exemplary compound A77 may be synthesized using N-phenylcarbazole as a starting material by the method described in page 137 line 10 to page 139, line 9 of the pamphlet of the International Publication No. WO05/022962.

The compound represented by Formula (1) may be synthesized by coupling aryl halide with aryl borate (or borate ester) or carbazole as described in WO05/085387 or WO03/080760. At this time, aryl halide, which is a synthetic intermediate (for example, aryl halide having a carbazole moiety or aryl halide having a pyridine moiety), a starting material for synthesizing the synthetic intermediate, aryl halide used as an intermediate, and the like may be generated as impurities. If the sum of the mass concentration of halogen atoms selected from the group consisting of bromine, iodine and chlorine contained in the impurities such as aryl halide (that is, a halogen element-containing compound which may be contained in the preparation of the compound represented by Formula (1)) is 100 ppm or less in the compound represented by Formula (1) (that is, the amount of halogen elements is 100 mg or less in 1 kg of the compound represented by Formula (1)), it is preferred in that the compound containing bromine, iodine or chlorine as the impurities may be charge-trapped, adverse effects on device properties such as external quantum efficiency or driving durability may be favorably suppressed for the reason of high reactivity, and external quantum efficiency and driving durability may be compatible with each other at a high level. Specifically, by setting the sum of the mass concentration of halogen elements selected from the group consisting of bromine, iodine and chlorine in the compound represented by Formula (1) to 100 ppm, the driving durability is remarkably enhanced. However, in the case where the compound represented by Formula (1) has a halogen element such as bromine, iodine or chlorine, the halogen element possessed by the compound represented by Formula (1) itself is not included in “the sum of the mass concentration of halogen elements selected from the group consisting of bromine, iodine and chlorine in the compound represented by Formula (1)”. The sum of the mass concentration of halogen elements selected from the group consisting of bromine, iodine and chlorine in the compound represented by Formula (1) is more preferably set to 50 ppm or less, and still more preferably 10 ppm or less.

Ideally, the sum of the mass concentration of halogen elements selected from the group consisting of bromine, iodine and chlorine included in the impurities of the compound represented by Formula (1) of the present invention is preferably 0 ppm. Meanwhile, it is practically impossible to measure whether the sum of the mass concentration of halogen elements selected from the group consisting of bromine, iodine and chlorine in the compound represented by Formula (1) is 0 ppm as well. Further, from the viewpoint of increase in the number of manufacturing processes or purifying processes, or environmental load affected by energy increment, it is preferred to contain an extremely small amount of impurities in the transporting material of the present invention, depending on its kind. Accordingly, from the viewpoint of both of the enhancement of durability and the suppression of environmental load, the sum of the mass concentration of halogen elements selected from the group consisting of bromine, iodine and chlorine included in the impurities of the present invention is preferably 0.001 ppm to 100 ppm, more preferably 0.005 ppm to 50 ppm, and still more preferably 0.01 ppm to 10 ppm based on the compound represented by Formula (1).

The mass concentration of halogen included in the above-mentioned impurities such as aryl halide in the compound represented by Formula (1) of the present invention may be measured by Inductively Coupled Plasma-Mass Spectrometer (ICP-MS) for bromind and iodine and by coulometric titration for chlorine, and the purity of the compound represented by Formula (1) of the present invention may be calculated by high performance liquid chromatography (HPLC). In the present invention, the area ratio of absorption intensity at 254 nm is used for the index of the purity or the mass concentration of halogen elements selected from the group consisting of bromine, iodine and chlorine. The peak position of aryl halide may be confirmed by comparing with the aryl halide which is a synthetic intermediate of the compound of Formula (1) of the present invention. Further, the peak structures of other impurities may be assumed by Liquid Chromatography/mass spectrometry (LC/MS).

Further, the purity of the compound represented by Formula (1) of the present invention is preferably 99.0% by mass or more, more preferably 99.5% by mass, and still more preferably.

The compound represented by Formula (1) may be synthesized by various method such as the method described in WO05/085387 or WO03/080760.

After the synthesis, it is preferred that purification by column chromatography, recrystallization and the like is performed, and then, purification is performed by sublimation purification. By sublimation purification, organic impurities may be separated and inorganic salts, residual solvents and the like may be effectively removed.

In the present invention, the compound represented by Formula (1) may be contained in, in addition to the light emitting layer, any layer other than the light emitting layer in the organic layer, and the use thereof is not limited. An introducing layer of the compound represented by Formula (1) is preferably contained in, in addition to the light emitting layer, any one of a hole injection layer, a hole transporting layer, an electron transporting layer, an electron injection layer, an exciton blocking layer and a charge blocking layer, or a plurality thereof.

In the present invention, in order to further suppress a change in chromaticity when driving at a high temperature, the compound represented by Formula (1) is preferably contained in any of layers adjacent to the light emitting layer in addition to the light emitting layer. Further, the compound represented by Formula (1) may be contained in both of the light emitting layer and the adjacent layer.

The compound is contained in an amount of preferably 0.1% by mass to 99% by mass, more preferably 1% by mass to 97% by mass, and still more preferably 10% by mass to 97% by mass, based on the total mass of the light emitting layer.

[Light Emitting Layer Containing Compound Represented by Formula (E-I) and Compound Represented by Formula (1)]

The present invention also relates to a light emitting layer containing the compound represented by Formula (E-I) and the compound represented by Formula (1). The light emitting layer may be used in organic electroluminescence devices. The mass ratio of the compound represented by Formula (E-I) to the compound represented by Formula (1) is preferably 1/99 to 30/70, and more preferably 3/97 to 20/80.

[Composition Containing Compound Represented by Formula (E-I) and Compound Represented by Formula (1)]

The present invention also relates to a composition containing the compound represented by Formula (E-I) and the compound represented by Formula (1).

In the composition of the present invention, the content of the compound represented by Formula (E-I) is preferably 1% by mass to 40% by mass, and more preferably 3% by mass to 20% by mass based on the total solid in the composition.

In the composition of the present invention, the content of the compound represented by Formula (1) is preferably 50% by mass to 99% by mass, and more preferably 70% by mass to 97% by mass based on the total solid in the composition.

Other components which may be contained in the composition of the present invention may be organic materials or inorganic materials, and as the organic materials, any materials exemplified as a host material, a fluorescent light emitting material, a phosphorescent light emitting material, a hydrocarbon material as described below may be applied.

The composition of the present invention may form organic layers of the organic electroluminescence device by a dry film-forming method such as a vapor deposition method, a sputtering method, and the like, or a wet film-forming method such as a transfer method, a printing method and the like.

[Organic Electroluminescence Device]

The device of the present invention will be described in detail.

The organic electroluminescence device of the present invention is an organic electroluminescence device including a pair of electrodes and a light emitting layer between the electrodes, on a substrate, in which the compound represented by Formula (1) as described above and the compound represented by Formula (E-I) as described above are contained in the light emitting layer.

In the organic electroluminescence device of the present invention, the light emitting layer may be an organic layer, and may have further organic layers.

Due to properties of the luminescence device, at least one electrode of the anode and cathode is preferably transparent or semi-transparent.

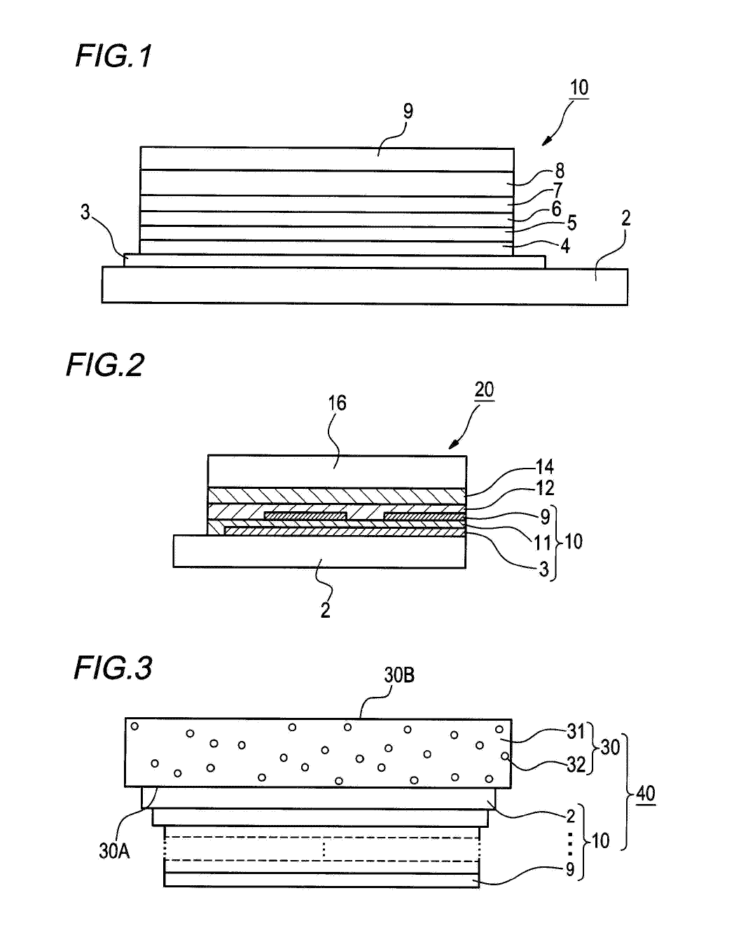

FIG. 1 illustrates an example of the configuration of an organic electroluminescence device according to the present invention. The organic electroluminescence device 10 according to the present invention, which is illustrated in FIG. 1, is on a supporting substrate 2, and a light emitting layer 6 is interposed between an anode 3 and a cathode 9. Specifically, a hole injection layer 4, a hole transporting layer 5, the light emitting layer 6, a hole blocking layer 7, and an electron transporting layer 8 are stacked in this order between the anode 3 and the cathode 9.

<Configuration of an Organic Layer>

The layer configuration of the organic layer is not particularly limited, and may be appropriately selected according to the use and purpose of the organic electroluminescence device, but is preferably formed on the transparent electrode or on the rear electrode. In this case, the organic layer is formed on the front surface or one surface on the transparent electrode or the rear electrode.

The shape, size, thickness and the like of the organic layer are not particularly limited and may be appropriately selected according to the purpose.

The specific layer configuration may include the followings, but the present invention is not limited to the configurations.

Anode/hole transporting layer/light emitting layer/electron transporting layer/cathode

Anode/hole transporting layer/light emitting layer/blocking layer/electron transporting layer/cathode

Anode/hole transporting layer/light emitting layer/blocking layer/electron transporting layer/electron injection layer/cathode

Anode/hole injection layer/hole transporting layer/light emitting layer/electron transporting layer/electron injection layer/cathode

Anode/hole injection layer/hole transporting layer/light emitting layer/blocking layer/electron transporting layer/cathode

Anode/hole injection layer/hole transporting layer/light emitting layer/blocking layer/electron transporting layer/electron injection layer/cathode.

The device configuration, substrate, cathode, and anode of the organic electroluminescence device are described in detail in, for example, Japanese Patent Application Laid-Open No. 2008-270736, and the subject matters described in the publication may be applied to the present invention.

<Substrate>

It is preferred that the substrate which is used in the present invention is a substrate which does not scatter or decay light generated from the organic layer. In the case of an organic material, it is preferred that the organic material is excellent in heat resistance, dimensional stability, solvent resistance, electrical insulation properties and processibility.

<Anode>

Typically, the anode may have a function as an electrode for supplying holes into the organic layer, is not particularly limited with respect to shape, structure, size, and the like and may be appropriately selected among the known electrode materials depending upon a use or purpose of the luminescence device. As described above, the anode is usually provided as a transparent anode.

<Cathode>

Typically, the cathode may have a function as an electrode for injecting electrons into the organic layer, is not particularly limited with respect to shape, structure, size, and the like and may be appropriately selected among the known electrode materials depending upon a use or purpose of the luminescence device.

With respect to the substrate, the anode, and the cathode, subject matters described in paragraph Nos. [0070] to [0089] of Japanese Patent Application Laid-Open No. 2008-270736 may be applied to the present invention.

<Organic Layer>

An organic layer in the present invention will be described.

—Formation of Organic Layer—

In the organic electroluminescence device of the present invention, each organic layer may be appropriately formed by any one of dry film-forming methods such as a vapor deposition method, a sputtering method, and the like, and solution coating processes such as a transfer method, a printing method, a spin-coat method, a bar-coat method and the like. It is also preferred that least one organic layer is formed by a solution coating process.

[Light Emitting Layer]

<Light Emitting Material>

The light emitting material in the present invention is preferably the compound represented by Formula (E-I).

The light emitting material in the light emitting layer is contained in an amount of 0.1% by mass to 30% by mass based on the mass of the total compounds which generally form the light emitting layer in the light emitting layer, preferably 1% by mass to 20% by mass by mass from the viewpoint of durability and external quantum efficiency, and still more preferably 3% by mass to 15% by mass.

Although the thickness of the light emitting layer is not particularly limited, typically, the thickness is preferably 2 nm to 500 nm. Among them, from the viewpoint of external quantum efficiency, the thickness is more preferably 3 nm to 200 nm, and still more preferably 5 nm to 100 nm.

The light emitting layer in the device of the present invention may be composed only of light emitting materials and may be composed of a mixed layer of a host material and a light emitting material. The light emitting material may be used either alone or in combination of two or more kinds, and may have, for example, a configuration of a mixture of an electron transporting host material and a hole transporting host material. Further, a material which does not have charge transportability and does not emit light may be included in the light emitting layer. The light emitting layer in the device of the present invention includes at least the compound represented by Formula (1) as a host material and the compound represented by Formula (E-I) as a light emitting material.

In addition, the light emitting layer may be a single layer or a multi layer of two or more layers. In the case of a plurality of light emitting layers, the compound represented by Formula (1) and the compound represented by Formula (E-I) may be contained in two or more light emitting layers. Furthermore, each light emitting layer may emit light with different light emission colors.

<Host Material>

A host material used in the present invention is preferably a compound represented by Formula (1).

The compound represented by Formula (1) is a compound capable of transporting both charges of holes and electrons, and may provide the above-described effects of the present invention by combining with the compound represented by Formula (E-I).

The host material used in the present invention may further contain the following compound. Examples of the host material include pyrrole, indole, carbazole (for example, CBP (4,4′-di(9-carbazolyl)biphenyl) and the like), azaindole, azacarbazole, triazole, oxazole, oxadiazole, pyrazole, imidazole, thiophene, polyarylalkane, pyrazoline, pyrazolone, phenylenediamine, arylamine, amino substituted chalcone, styrylanthracene, fluorenone, hydrazone, stilbene, silazane, aromatic tertiary amine compounds, styrylamine compounds, porphyrin-based compounds, polysilane-based compounds, poly(N-vinylcarbazole), aniline-based copolymers, electrically conductive high-molecular oligomers such as thiophene oligomers, polythiophene and the like, organosilanes, carbon films, pyridine, pyrimidine, triazine, imidazole, pyrazole, triazole, oxazole, oxadiazole, fluorenone, anthraquinodimethane, anthrone, diphenylquinone, thiopyran dioxide, carbodiimide, fluorenylidenemethane, distyrylpyrazine, fluorine-substituted aromatic compounds, heterocyclic tetracarboxylic anhydrides such as naphthalene perylene and the like, phthalocyanine, and a variety of metal complexes represented by metal complexes of a 8-quinolinol derivative, metal phthalocyanine, and metal complexes having benzoxazole or benzothiazole as the ligand thereof, derivatives thereof (which may have a substituent or a condensed ring) and the like.

In the light emitting layer in the present invention, it is preferred that the lowest triplet excitation energy (T₁ energy) of the host material (also including the compound represented by Formula (1)) is higher than the T₁ energy of the phosphorescent light emitting material from the viewpoint of color purity, light emission efficiency, and drive durability.

Further, the content of the host compound in the present invention is not particularly limited, but is preferably 15% by mass to 98% by mass based on the mass of the total compounds forming the light emitting layer, from the viewpoint of light emission efficiency and driving voltage.

(Fluorescent Light Emitting Material)

Examples of the fluorescent light emitting material that may be used in the present invention include, in addition to the compound represented by Formula (E-I), a benzoxazole derivative, a benzimidazole derivative, a benzothiazole derivative, a styrylbenzen derivative, a polyphenyl derivative, a diphenylbutadiene derivative, a tetraphenylbutadiene derivative, a naphthalimide derivative, a coumarin derivative, a condensed aromatic compound, a perinone derivative, an oxadiazole derivative, an oxazine derivative, an aldazine derivative, a pyralizine derivative, a cyclopentadiene derivative, a bisstyrylanthracene derivative, a quinacridone derivative, a pyrrolopyridine derivative, a thiadiazolopyridine derivative, a cyclopentadiene derivative, a styrylamine derivative, a diketopyrrolopyrrole derivative, an aromatic dimethylidyne compound, various metal complexes and the like represented by a complexe of an 8-quinolinol derivative or a complexe of a pyrromethene derivative, polymer compounds such as polythiophene, polyphenylene and polyphenylenevinylene, compounds such as an organic silane derivative, and the like.

Examples of the phosphorescent light emitting material that may be used in the present invention include phosphorescent light emitting compounds and the like described in patent documents such as U.S. Pat. No. 6,303,238B1, U.S. Pat. No. 6,097,147, WO00/57676, WO00/70655, WO01/08230, WO01/39234A2, WO01/41512A1, WO02/02714A2, WO02/15645A1, WO02/44189A1, WO05/19373A2, Japanese Patent Application Laid-Open No. 2001-247859, Japanese Patent Application Laid-Open No. 2002-302671, Japanese Patent Application Laid-Open No. 2002-117978, Japanese Patent Application Laid-Open No. 2003-133074, Japanese Patent Application Laid-Open No. 2002-235076, Japanese Patent Application Laid-Open No. 2003-123982, Japanese Patent Application Laid-Open No. 2002-170684, EP 1211257, Japanese Patent Application Laid-Open No. 2002-226495, Japanese Patent Application Laid-Open No. 2002-234894, Japanese Patent Application Laid-Open No. 2001-247859, Japanese Patent Application Laid-Open No. 2001-298470, Japanese Patent Application Laid-Open No. 2002-173674, Japanese Patent Application Laid-Open No. 2002-203678, Japanese Patent Application Laid-Open No. 2002-203679, Japanese Patent Application Laid-Open No. 2004-357791, Japanese Patent Application Laid-Open No. 2006-256999, Japanese Patent Application Laid-Open No. 2007-19462, Japanese Patent Application Laid-Open No. 2007-84635, Japanese Patent Application Laid-Open No. 2007-96259 and the like, and among them, more preferred light emitting dopants include an Ir complex, a Pt complex, a Cu complex, a Re complex, a W complex, a Rh complex, a Ru complex, a Pd complex, an Os complex, an Eu complex, a Tb complex, a Gd complex, a Dy complex and a Ce complex. An Ir complex, a Pt complex or a Re complex is particularly preferred, and among them, an Ir complex, a Pt complex, or a Re complex including at least one coordination mode of a metal-carbon bond, a metal-nitrogen bond, a metal-oxygen bond and a metal-sulfur bond are preferred. Further, from the viewpoint of light emission efficiency, driving durability, chromaticity and the like, an Ir complex, a Pt complex or a Re complex including tri- or multi-dentate ligands is particularly preferred.

The content of the phosphorescent light emitting material that may be used in the present invention (the compound represented by Formula (E-1) and/or the combined phosphorescent light emitting material) is preferably in a range of 0.1% by mass to 50% by mass, more preferably 0.3% by mass to 40% by mass, and most preferably 0.5% by mass to 30% by mass based on the total mass of the light emitting layer. Particularly, in the range of 0.5% by mass to 30% by mass, the chromaticity of the light emission of the organic electroluminescence device has small dependence on the concentration of the phosphorescent light emitting material added.

It is most preferred that the organic electroluminescence device of the present invention contains 0.5% by mass to 30% by mass of at least one compound represented by Formula (E-I) based on the total mass of the light emitting layer.

(Electric Charge Transporting Layer)

The electric charge transporting layer refers to a layer in which the electric charge movement is generated when voltage is applied on an organic electroluminescence device. Specific examples thereof include a hole injection layer, a hole transporting layer, an electron blocking layer, a light emitting layer, a hole blocking layer, an electron transporting layer or an electron injection layer. Preferred examples thereof include a hole injection layer, a hole transporting layer, an electron blocking layer or a light emitting layer. If an electric charge transporting layer to be formed by an application method is a hole injection layer, a hole transporting layer, an electron blocking layer or a light emitting layer, an organic electroluminescence device may be produced at a low cost and a high efficiency. In addition, the electric charge transporting layer is more preferably a hole injection layer, a hole transporting layer or an electron blocking layer.

—Hole Injection Layer and Hole Transporting Layer—

Each of the hole injection layer and the hole transporting layer is a layer having a function of accepting holes from the anode or the anode side to transport the holes into the cathode side.

The hole injection layer preferably contains an electron accepting dopant. Effects that the hole injection property is improved, driving voltage is reduced, efficiency is improved and the like are exhibited by containing the electron accepting dopant in the hole injection layer. The electron accepting dopant may be any of organic materials and inorganic materials as long as the dopant is a material capable of withdrawing electrons from a material to be doped to generate radical cations, but examples thereof include tetracyanoquinodimethane (TCNQ), tetrafluorotetracyanoquinodimethane (F4-TCNQ), molybdenum oxide and the like.

The electron accepting dopant in the hole injection layer is contained in an amount of preferably 0.01 mass % to 50 mass %, more preferably 0.1 mass % to 40 mass %, and still more preferably 0.5 mass % to 30 mass %, based on the mass of the total compounds forming the hole injection layer.

—Electron Injection Layer and Electron Transporting Layer—

Each of the electron injection layer and the electron transporting layer is a layer having a function of accepting electrons from the cathode or the cathode side to transport the electrons into the anode side.

The electron injection layer preferably contains an electron donating dopant. Containing the electron donating dopant in the electron injection layer results in effects that the electron injection property is improved, driving voltage is reduced, efficiency is improved, and the like. The electron donating dopant may be any of organic materials and inorganic materials as long as the dopant is a material capable of imparting electrons to a material to be doped to generate radical anions, but examples thereof include tetrathialfulvalene (TTF), tetrathianaphthacene (TTT), lithium, cesium and the like.

The hole injection layer, the hole transporting layer, the electron injection layer and the electron transporting layer are described in detail in, for example, Japanese Patent Application Laid-Open No. 2008-270736 and Japanese Patent Application Laid-Open No. 2007-266458, and subject matters described in these publications may be applied to the present invention.

In the device of the present invention, the device containing an electron accepting dopant or an electron donating dopant has enhanced relative values of the external quantum efficiency, compared to devices not containing such a dopant. Although the reason is not clear, it is considered as follows. If the electron injection property or the hole injection property is enhanced, the charge balance in the light emitting layer is destroyed, and the light emitting position is changed. If the hole injection property is enhanced, electric charges are accumulated at the cathode side interface of the light emitting layer, and the ratio of light emission at the position is increased. If the electron injection property is enhanced, electric charges are accumulated at the anode side interface of the light emitting layer, and the ratio of light emission at the position is increased. In the device not containing an electron accepting dopant or an electron donating dopant, the change in light emitting position is large, and excitons are deactivated by each of the hole blocking layer and the electron blocking layer, thereby deteriorating the efficiency, and in contrast, in the device containing an electron accepting dopant or an electron donating dopant, the light emitting position is not greatly changed, and the efficiency is maintained, resulting in enhancing the relative value of the external quantum efficiency.

The electron donating dopant in the electron injection layer is contained in an amount of preferably 0.01 mass % to 50 mass %, more preferably 0.1 mass % to 40 mass %, and more preferably 0.5 mass % to 30 mass %, based on the mass of the total compounds forming the electron injection layer.

—Hole Blocking Layer—

The hole blocking layer is a layer having a function of preventing a hole transported to the light emitting layer from the anode side from penetrating to the cathode side. In the present invention, the hole blocking layer may be formed as an organic layer adjacent to the light emitting layer on the cathode side.

Examples of the organic compound constituting the hole blocking layer include an aluminum complex such as aluminum(III) bis(2-methyl-8-quinolinato)4-phenylphenolate (simply referred to as BAIq) and the like, triazole derivatives, phenanthroline derivatives such as 2,9-dimethyl-4,7-diphenyl-1,10-phenanthroline (simply referred to as BCP) and the like, in addition to the compounds represented by Formula (1) in the present invention.

The thickness of the hole blocking layer is preferably 1 nm to 500 nm, more preferably 5 nm to 200 nm, and even more preferably 10 nm to 100 nm.

The hole blocking layer may have a single layer structure composed of one or two or more kinds of the above-described materials or may have a multilayer structure composed of a plurality of layers of the same or different compositions.

—Electron Blocking Layer—

The electron blocking layer is a layer having a function of preventing an electron transported to the light emitting layer from the cathode side from penetrating to the anode side. In the present invention, the electron blocking layer may be formed as an organic layer adjacent to the light emitting layer on the cathode side.

As an example of the organic compound constituting the electron blocking layer, for example, those exemplified as the above-described hole transporting material may be applied.

The thickness of the electron blocking layer is preferably 1 nm to 500 nm, more preferably 5 nm to 200 nm, and even more preferably 10 nm to 100 nm.

The electron blocking layer may have a single layer structure composed of one or two or more kinds of the above-described materials or may have a multilayer structure composed of a plurality of layers of the same or different compositions.

<Protective Layer>

In the present invention, the entire organic EL device may be protected by a protective layer.

With respect to the protective layer, subject matters described in paragraph Nos. [0169] and [0170] of Japanese Patent Application Laid-Open No. 2008-270736, may be applied to the present invention.

<Sealing Container>

In the device of the present invention, the entire device may be sealed by using a sealing container.

With respect to the sealing container, subject matters described in paragraph No. of Japanese Patent Application Laid-Open No. 2008-270736 may be applied to the present invention.

(Driving)

In the organic electroluminescent device of the present invention, light emission may be obtained by applying a voltage (typically 2 volts to 15 volts) of direct current (may include an alternating current component if necessary) or a current of direct current between the anode and the cathode.

With respect to the driving method of the organic electroluminescence device of the present invention, it is possible to apply driving methods described in each publication of Japanese Patent Application Laid-Open Nos. H2-148687, 6-301355, H5-29080, H7-134558 and H8-234685 and each specification of Japanese Patent No. 2784615, U.S. Pat. Nos. 5,828,429 and 6,023,308 and the like.

The luminescence device of the present invention may have a light extraction efficiency enhanced by various known manners. For example, it is possible to enhance the light extraction efficiency and thus, to enhance the external quantum efficiency by processing the surface configuration of a substrate (for example, forming a minute uneven pattern), controlling the refractive indices of the substrate, an ITO layer and an organic layer, controlling the film thicknesses of the substrate, the ITO layer and the organic layer, and the like.

As the external quantum efficiency of the luminescence device of the present invention, the external quantum efficiency is preferably 5% to 100%, more preferably 10% to 100%, still more preferably 15% to 100%, and particularly preferably 20% to 30%. As values of external quantum efficiency, it is possible to use a maximum value of the external quantum efficiency when the device is driving at 20° C. or a value of the external quantum efficiency in the vicinity of 100 cd/m² to 2000 cd/m² when the device is driving at 20° C.

The luminescence device of the present invention may be in a so-called top emission system of extracting light from the anode side.

The organic EL device of the present invention may have a resonator structure. For example, a multilayer mirror composed of a plurality of laminated films differing in the refractive index, a transparent or semi-transparent electrode, a light emitting layer, and a metal electrode are superposed on a transparent substrate. Light generated in the light emitting layer repeats reflection and resonates between the multilayer mirror and the metal electrode by using the multilayer mirror and the metal electrode as reflectors.

In another preferred embodiment, each of a transparent or semi-transparent electrode and a metal electrode functions as a reflector on a transparent substrate, and light generated in the light emitting layer repeats reflection and resonates therebetween.

In order to form a resonance structure, the effective refractive index of two reflectors and the optical path length determined from the refractive index and thickness of each layer between the reflectors are adjusted to optimal values for obtaining a desired resonance wavelength. The calculation formula in the case of the first embodiment is described in Japanese Patent Application Laid-Open No. H9-180883, and the calculation formula in the case of the second embodiment is described in Japanese Patent Application Laid-Open No. 2004-127795.

(Use of Luminescence Device of the Present Invention)

The luminescence device of the present invention may be suitably used for light emission apparatuses, pixels, display devices, displays, backlights, electrophotography, illumination light sources, recording light sources, exposure light sources, reading light sources, indicators, signboards, interiors, optical communication and the like. In particular, the luminescence device of the present invention is preferably used for a device that is driven in a region with high luminescence intensity, such as an illumination apparatus, a display apparatus and the like.

(Light Emission Apparatus)

Subsequently, the light emission apparatus of the present invention will be described with reference to FIG. 2.

The light emission apparatus of the present invention is made by using the organic electroluminescence device.

FIG. 2 is a cross-sectional view schematically illustrating an example of a light emission apparatus of the present invention.

A light emission apparatus 20 of FIG. 2 is composed of a substrate (supporting substrate) 2, an organic electroluminescence device 10, a sealing container 16 and the like.

The organic electroluminescence device 10 is configured by sequentially stacking an anode (first electrode) 3, an organic layer 11 and a cathode (second electrode) 9 on the substrate 2. In addition, a protective layer 12 is stacked on the cathode 9. Furthermore, the sealing container 16 is provided on the protective layer 12 through an adhesive layer 14. Meanwhile, a part of each of the electrodes 3 and 9, a partition wall, an insulating layer and the like are omitted.

Here, as the adhesive layer 14, a photocurable or thermosetting adhesive such as an epoxy resin and the like may be used and, for example, a thermosetting adhesive sheet may also be used.

The light emission apparatus of the present invention is not particularly limited in the use thereof and, for example, may be used not only as an illumination apparatus but also as a display apparatus such as a television set, a personal computer, a cellular phone, an electronic paper and the like.

(Illumination Apparatus)

Subsequently, an illumination apparatus according to embodiments of the present invention will be described with reference to FIG. 3.

FIG. 3 is a cross-sectional view schematically illustrating an example of the illumination apparatus according to embodiments of the present invention.

An illumination apparatus 40 according to embodiments of the present invention includes, as illustrated in FIG. 3, the above-described organic EL device 10 and a light scattering member 30. More specifically, the illumination apparatus 40 is configured such that the substrate 2 of the organic EL device 10 and the light scattering member 30 are put into contact.

The light scattering member 30 is not particularly limited as long as the member may scatter light, but in FIG. 3, a member obtained by dispersing fine particles 32 in a transparent substrate 31 is used. Suitable examples of the transparent substrate 31 include a glass substrate. Suitable examples of the fine particle 32 include a transparent resin fine particle. As the glass substrate and the transparent resin fine particle, all the products well known in the art may be used. In such an illumination apparatus 40, when light emitted from the organic electroluminescence device 10 is incident on a light incident surface 30A of the scattering member 30, the incident light is scattered by the light scattering member 30 and the scattered light is outputted as illuminating light from a light exit surface 30B.

### EXAMPLE

Hereinafter, the present invention will be described in detail with reference to Examples, but the range of the present invention is not limited thereto.

The compound represented by Formula (E-I) was synthesized with reference to a method disclosed in U.S. Patent Application Laid-Open No. 2005/0170209. For example, Compound 19 was synthesized in the method of Synthesis Example 2 described in page 9 of U.S. Patent Application Laid-Open No. 2005/0170209.

Exemplary Compound A4 and Exemplary Compound A43 were synthesized with reference to the pamphlet of International Publication No. WO03/080760, the pamphlet of International Publication No. WO03/078541, the pamphlet of International Publication No. WO05/085387, the pamphlet of International Publication No. WO05/022962 and the like. For example, the compound, Exemplary Compound A4, may be synthesized using m-bromobenzaldehide as a starting material by the method described in in paragraphs [0074] to [0075] (page 45, line 11 to page 46, line 18) of the pamphlet of the International Publication No. WO05/085387. Further, Exemplary Compound A45 may be synthesized using 3,5-dibromobenzaldehide as a starting material by the method described in page 46, line 9 to page 46, line 12 of the pamphlet of the International Publication No. WO03/080760. Further, Exemplary Compound A77 may be synthesized using N-phenylcarbazole as a starting material by the method described in page 137 line 10 to page 139, line 9 of the pamphlet of the International Publication No. WO05/022962.

For the compound represented by Formula (1) used in Examples and the compound used as a host material in Comparative Examples, after the synthesis, these compounds were purified by sublimation to be adjusted as a compound (host material) having the sum of the mass concentration of halogen elements selected from the group consisting of bromine, iodine and chlorine as shown in Table 9. The sum of the mass concentration of halogen elements selected from the group consisting of bromine, iodine and chlorine in these compouns was measured by ICP-MS for bromind and iodine and by coulometric titration for chlorine.

Further, all the orgainic materials used in the present examples were purified by sublimation, and analyesed by high-speed liquid chromatography (TOSOH CORPORATION TSKgel ODS-100Z), and found to have an absorption intensity area ratio of 99.9% or more at 254 nm.

### Comparative Example 1

Manufacture of Organic Electroluminescence Device

A glass substrate coated with ITO (10 Ω/cm² (1200 A)) was cut to a size of 50 mm×50 mm×0.7 mm, and ultrasonically washed with 2-propanol and deionized water for 5 minutes, respectively, followed by UV-ozone purification for 30 minutes. Copper phthalocyanine (CuPc) was vacuum-deposited on the ITO glass substrate (anode) to form a hole injection layer having a thickness of 600 A. Subsequently, N,N′-bis(3-methylphenyl)-N,N′-diphenyl-[1,1-biphenyl]-4,4′-diamine (TPD) was vacuum-deposited on the hole injection layer to form a hole transporting layer having a thickness of 300 A.

95 parts by mass of SDI-BH-22 as a host of a light emitting layer and 5 parts by mass of Firpic as a dopant were vacuum-co-deposited on the hole transporting layer to form a light emitting layer having a thickness of 300 A.

Thereafter, BAlq was vacuum-deposited on the light emitting layer to form a hole blocking layer having a thickness of 50 A. Subsequently, Alq3 was vacuum-deposited on the hole blocking layer to form an electron transporting layer having a thickness of 200 A. Further, LiF was vacuum-deposited on the electron transporting layer to form an electron injection layer having a thickness of 10 A, and Al was vacuum-deposited on the electron injection layer on the electron injection layer to form a cathode having a thickness of 3000 A, thereby manufacturing an organic electroluminescence device of Comparative Example 1.

### Comparative Examples 2 to 14 and Examples 1 to 18

Organic electroluminescence devices of Comparative Examples 2 to 14 and Examples 1 to 18 were obtained in the same manner as in Comparative Example 1, except that the constitutional materials and the sum of the mass concentration of halogen elements selected from the group consisting of bromine, iodine and chlorine in Comparative Example 1 were changed to the materials and concentration as shown in Table 9 below. In Table 9, the symbol “<” in the evaluation of the change in chromaticity means an inequality sign, and for example, “<0.005” means that the change in chromaticity is less than 0.005.

TABLE 9

| | | | Sum of mass | External | | | |
|---|---|---|---|---|---|---|---|
| | | | concentration of | quantum | Driving | | |
| | Constitution of light | | halogen elements | efficiency | durability | Chromaticity | Change in |
| | emitting layer | | (bromine, iodine | (Relative | (Relative | coordinates | chromaticity |
| | Dopant | Host | and chlorine) | value) | value) | (x, y) | (Δx, Δy) |
| Comparative | Firpic | SDI-BH-22 | 4 ppm | 100 | 100 | (0.170, 0.400) | (0.01, 0.02) |
| Example 1 | | | | | | | |
| Comparative | 19 | SDI-BH-22 | 4 ppm | 107 | 130 | (0.144, 0.127) | (0.02, 0.04) |
| Example 2 | | | | | | | |
| Comparative | 19 | SDI-BH-22 | 43 ppm | 103 | 113 | (0.144, 0.127) | (0.02, 0.04) |
| Example 3 | | | | | | | |
| Comparative | 19 | SDI-BH-22 | 94 ppm | 100 | 100 | (0.144, 0.127) | (0.02, 0.04) |
| Example 4 | | | | | | | |
| Comparative | 19 | SDI-BH-22 | 104 ppm | 95 | 94 | (0.144, 0.127) | (0.02, 0.04) |
| Example 5 | | | | | | | |
| Comparative | Firpic | A6 | 4 ppm | 97 | 180 | (0.170, 0.400) | (0.01, 0.02) |
| Example 6 | | | | | | | |
| Inventive | 19 | A6 | 4 ppm | 112 | 440 | (0.144, 0.127) | (<0.005, <0.005) |
| Example 1 | | | | | | | |
| Inventive | 19 | A6 | 42 ppm | 111 | 360 | (0.144, 0.127) | (<0.005, <0.005) |
| Example 2 | | | | | | | |
| Inventive | 19 | A6 | 92 ppm | 109 | 320 | (0.144, 0.127) | (<0.005, <0.005) |
| Example 3 | | | | | | | |
| Inventive | 19 | A6 | 102 ppm | 108 | 135 | (0.144, 0.127) | (<0.005, <0.005) |
| Example 4 | | | | | | | |
| Inventive | 136 | A6 | 4 ppm | 114 | 400 | (0.144, 0.135) | (<0.005, <0.005) |
| Example 5 | | | | | | | |
| Inventive | 19 | A43 | 5 ppm | 112 | 420 | (0.144, 0.127) | (<0.005, <0.005) |
| Example 6 | | | | | | | |
| Inventive | 136 | A43 | 5 ppm | 115 | 380 | (0.144, 0.135) | (<0.005, <0.005) |
| Example 7 | | | | | | | |
| Inventive | 19 | A67 | 4 ppm | 112 | 400 | (0.144, 0.127) | (<0.005, <0.005) |
| Example 8 | | | | | | | |
| Inventive | 136 | A67 | 4 ppm | 116 | 360 | (0.144, 0.135) | (<0.005, <0.005) |
| Example 9 | | | | | | | |
| Inventive | 33 | A6 | 4 ppm | 113 | 410 | (0.144, 0.135) | (<0.005, <0.005) |
| Example 10 | | | | | | | |
| Inventive | 138 | A6 | 4 ppm | 109 | 440 | (0.144, 0.135) | (<0.005, <0.005) |
| Example 11 | | | | | | | |
| Inventive | 142 | A6 | 4 ppm | 112 | 420 | (0.144, 0.135) | (<0.005, <0.005) |
| Example 12 | | | | | | | |
| Inventive | 19 | A45 | 2 ppm | 111 | 444 | (0.144, 0.127) | (<0.005, <0.005) |
| Example 13 | | | | | | | |
| Inventive | 19 | A32 | 3 ppm | 112 | 424 | (0.144, 0.127) | (<0.005, <0.005) |
| Example 14 | | | | | | | |
| Inventive | 19 | A53 | <1 ppm | 109 | 402 | (0.144, 0.127) | (<0.005, <0.005) |
| Example 15 | | | | | | | |
| Inventive | 115 | A6 | 2 ppm | 108 | 430 | (0.144, 0.135) | (<0.005, <0.005) |
| Example 16 | | | | | | | |
| Inventive | 129 | A6 | 3 ppm | 105 | 426 | (0.144, 0.135) | (<0.005, <0.005) |
| Example 17 | | | | | | | |
| Inventive | 203 | A6 | 4 ppm | 106 | 432 | (0.144, 0.135) | (<0.005, <0.005) |
| Example 18 | | | | | | | |
| Comparative | 204 | CBP | 4 ppm | 97 | 92 | (0.148, 0.140) | (0.01, 0.02) |
| Example 7 | | | | | | | |
| Comparative | 204 | Host A | 4 ppm | 99 | 96 | (0.148, 0.140) | (0.02, 0.03) |
| Example 8 | | | | | | | |
| Comparative | 205 | Host B | 5 ppm | 98 | 95 | (0.145, 0.130) | (0.02, 0.04) |
| Example 9 | | | | | | | |
| Comparative | Dopant A | A4 | 4 ppm | 99 | 99 | (0.149, 0.140) | (0.02, 0.03) |
| Example 10 | | | | | | | |
| Comparative | Firpic | A38 | 2 ppm | 100 | 130 | (0.170, 0.400) | (0.01, 0.02) |
| Example 11 | | | | | | | |
| Comparative | 19 | SDI-BH23 | 4 ppm | 109 | 132 | (0.144, 0.127) | (0.02, 0.04) |
| Example 12 | | | | | | | |
| Inventive | Dopant B | A40 | 5 ppm | 107 | 141 | (0.200, 0.320) | (0.02, 0.03) |
| Example 13 | | | | | | | |
| Inventive | Dopant B | A38 | 4 ppm | 109 | 138 | (0.200, 0.320) | (0.02, 0.03) |
| Example 14 | | | | | | | |

(Evaluation of Performance of Organic Electroluminescence Device)

The performance of each device thus obtained was evaluated as follows.

(a) External Quantum Efficiency

A direct current voltage was applied to each device by using a Source Measure Unit 2400 manufactured by Toyo Technica Corporation to allow the devices to emit light, and the luminance intensity was measured by using a luminance meter BM-8 manufactured by Topcon Corporation. Emission spectra and emission wavelengths were measured by using a spectrum analyzer PMA-11 manufactured by Hamamatsu Photonics Co., Ltd. On the basis of these, the external quantum efficiency in the vicinity of the luminance intensity of 1,000 cd/m² was calculated by a luminance intensity conversion method, and shown as a relative value by counting the value of Comparative Example 1 as 100. It is desirable that the external quantum efficiency is as large as possible.

(b) Driving Durability

Direct current voltage is applied to each device such that the luminance intensity became 1,000 cd/m² to allow the devices to continuously emit light, and the time required until the luminance intensity became 500 cd/m² was obtained as an index for durability, and shown as a relative value by counting the value of Comparative Example 1 as 100. It is desirable that the durability is as large as possible.

(c) Chromaticity Coordinates

The chromaticity coordinates of each devices were obtained as the color coordninator, CIE (x, y), by the color system established by the International Commission on Illumination. Further, as the value of x is closer to 0.1, the blue color becomes deeper, that is, the color becomes closer to pure blue, and it is desirable in the present invention. Further, as the value of y is considerably closer to 0.8, the green color becomes stronger, and it is not desirable in the present invention.

(d) Change in Chromaticity Before and after Driving

Direct current voltage was applied to each device to enable the devices to emit light such that the luminance intensity became 5,000 cd/m². The chromaticity (x, y) at this time was compared to the chromaticity (x, y) when the luminance intensity reaches 4,000 cd/m², and the differences in the x value and the y value of both the chromaticities were shown in the form of (Ax, Ay) and used as an index for the change in chromaticity before and after driving. It is desirable that the values of Ax and Ay are as small as possible.

As can be seen clearly from the results of Table 9, it is understood that the device of the present invention using the carbazole compound having a specific structructre represented by Formula (1) and an iridium complex having a specific structure represented by Formula (E-I) in the light emitting layer has an external quantum efficiency and a durability compatible with each other at a higher level, compared to the devices of Comparative Examples which do not contain both or any one of them, and has a small change in chromaticity before and after driving the device, while having an excellent property of blue chromaticity.

Further, as can be seen clearly from the results of Devices 1 to 3 of the present invention and Device 4 of the present invention, in the case where the sum of the mass concentration of halogen elements selected from the group consisting of bromine, iodine and chlorine in the compound having a specific structure represented by Formula (1) is 100 ppm or less, the external quantum efficiency and the driving durability become better, and particularly, the driving durability becomes remarkably better. In contrast, as can be seen clearly from the results of Comparative Examples 3 to 5, in the constitution using a compound that is not the compound represented by Formula (1) of the present invention as a host material, the driving durability dose not become remarkably better even in the case where the sum of the mass concentration of halogen elements selected from the group consisting of bromine, iodine and chlorine in the corresponding compound is 100 ppm or less.

In the case of light emission apparatuses, display apparatuses and illumination apparatuses, it is necessary to instantaneously emit light at a high luminance intensity through a high current density in each pixel part, and in that case, the luminescence device of the present invention is designed to increase the light emission efficiency and thus may be advantageously used.

Further, the device of the present invention is excellent in light emission efficiency or durability even when used under a high temperature environment such as use in on-board, and is suitable for light emission apparatuses, display apparatuses and illumination apparatuses.

Structures of the compounds used in Examples and Comparative Examples are shown below.

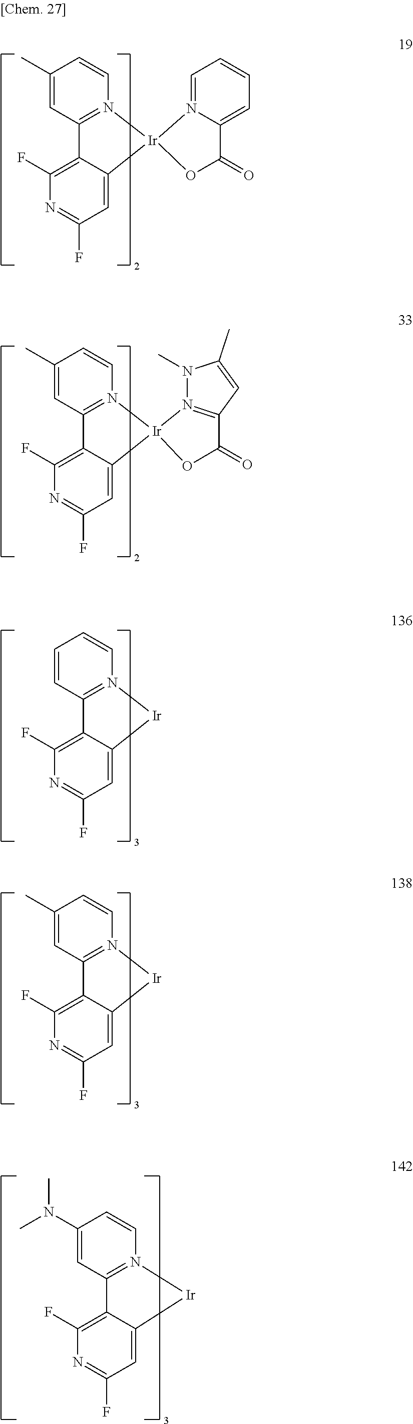

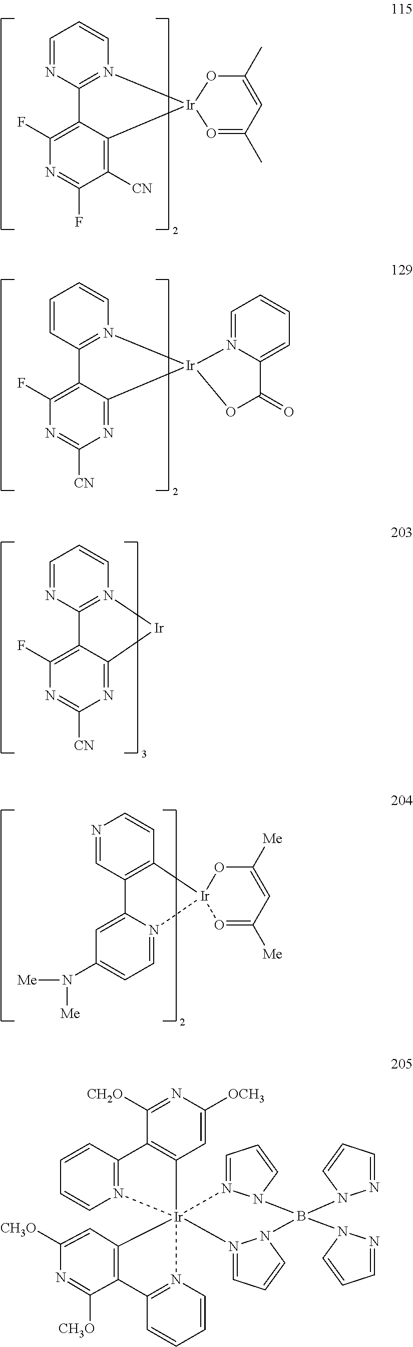

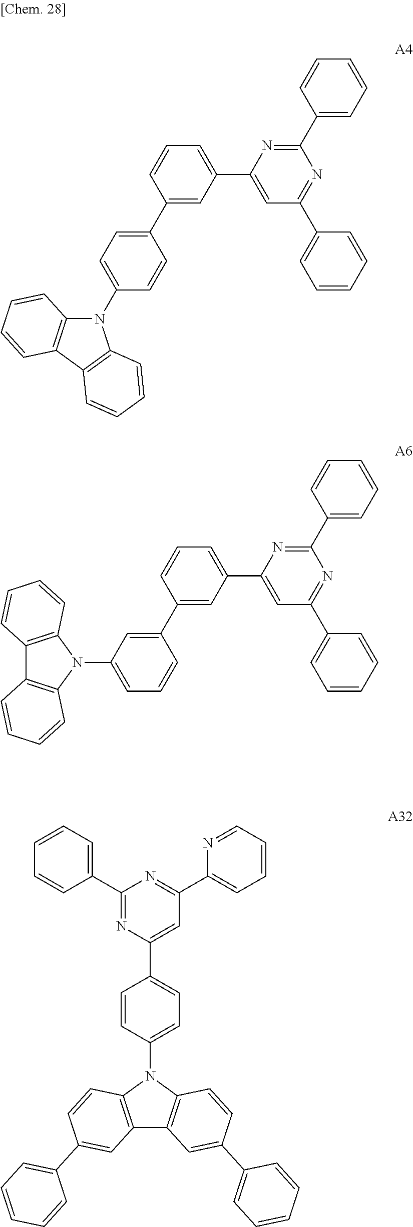 [SMILES: c1ccc(-c2cc(-c3cccc(-c4ccc(-n5c6ccccc6c6ccccc65)cc4)c3)nc(-c3ccccc3)n2)cc1 ; c1ccc(-c2cc(-c3cccc(-c4cccc(-n5c6ccccc6c6ccccc65)c4)c3)nc(-c3ccccc3)n2)cc1 ; c1ccc(-c2ccc3c(c2)c2cc(-c4ccccc4)ccc2n3-c2ccc(-c3cc(-c4ccccn4)nc(-c4ccccc4)n3)cc2)cc1]

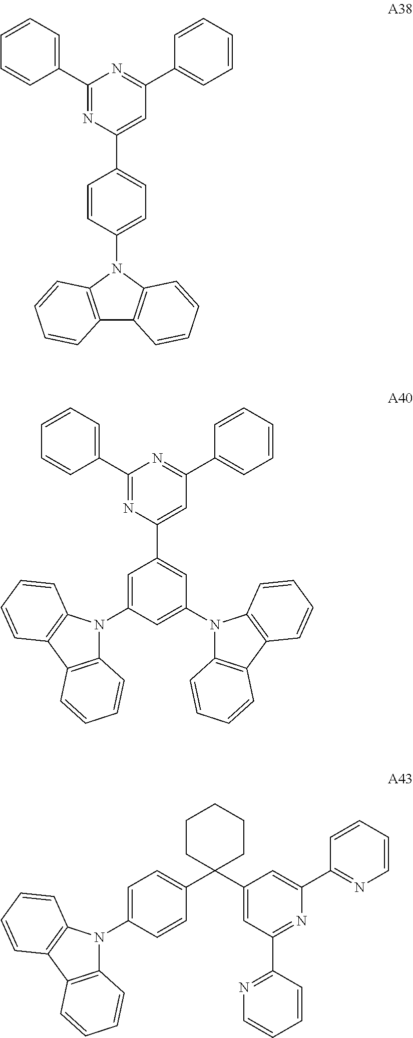 [SMILES: c1ccc(-c2cc(-c3ccc(-n4c5ccccc5c5ccccc54)cc3)nc(-c3ccccc3)n2)cc1 ; c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2cc(C3(c4ccc(-n5c6ccccc6c6ccccc65)cc4)CCCCC3)cc(-c3ccccn3)n2)nc1]

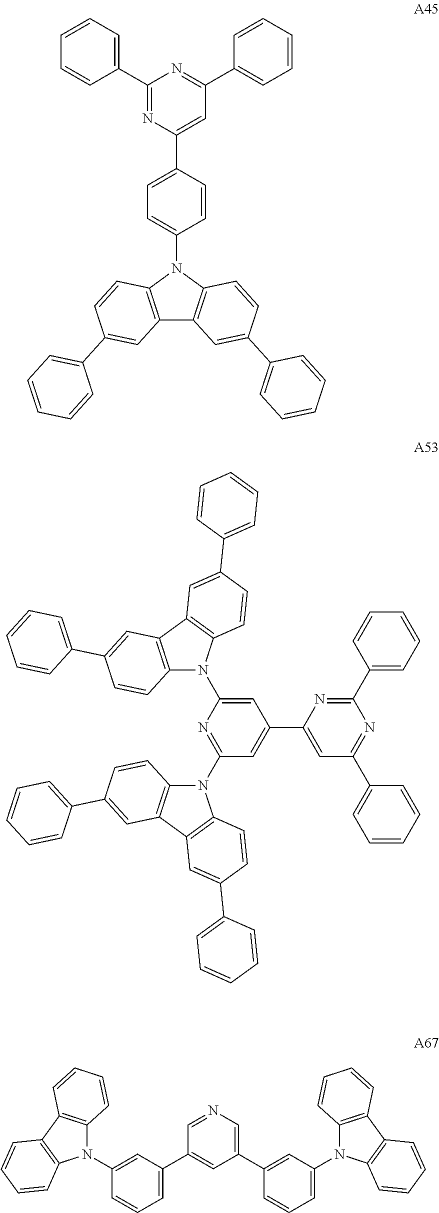 [SMILES: c1ccc(-c2ccc3c(c2)c2cc(-c4ccccc4)ccc2n3-c2ccc(-c3cc(-c4ccccc4)nc(-c4ccccc4)n3)cc2)cc1 ; c1ccc(-c2ccc3c(c2)c2cc(-c4ccccc4)ccc2n3-c2cc(-c3cc(-c4ccccc4)nc(-c4ccccc4)n3)cc(-n3c4ccc(-c5ccccc5)cc4c4cc(-c5ccccc5)ccc43)n2)cc1 ; c1cc(-c2cncc(-c3cccc(-n4c5ccccc5c5ccccc54)c3)c2)cc(-n2c3ccccc3c3ccccc32)c1]

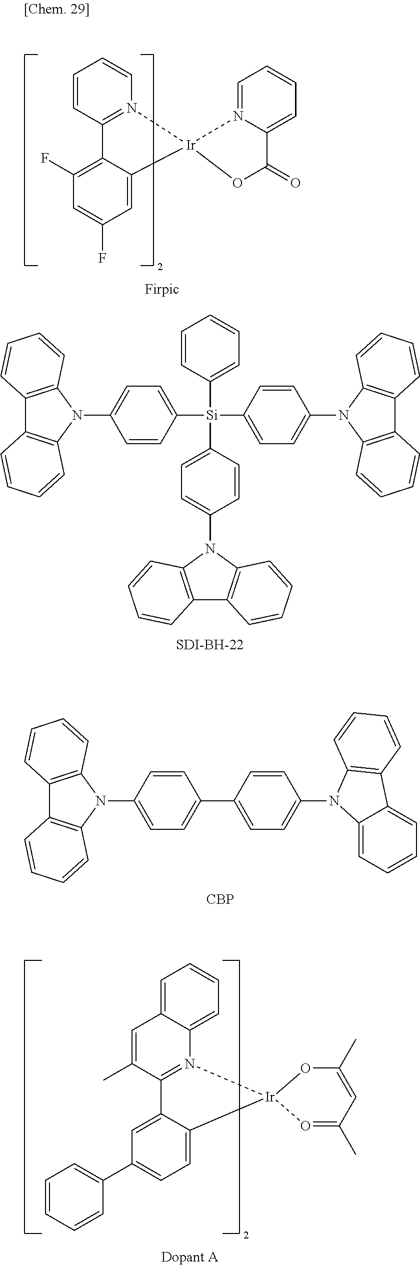

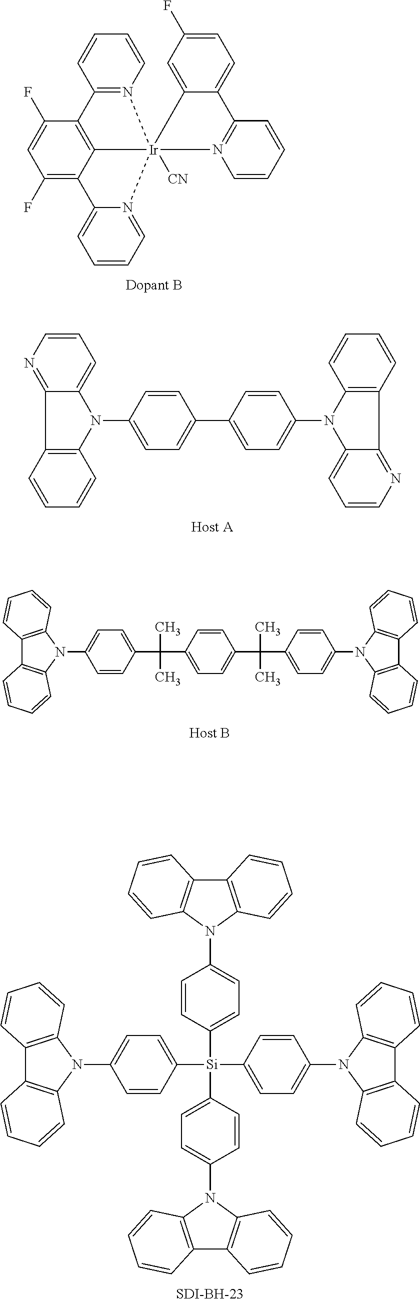

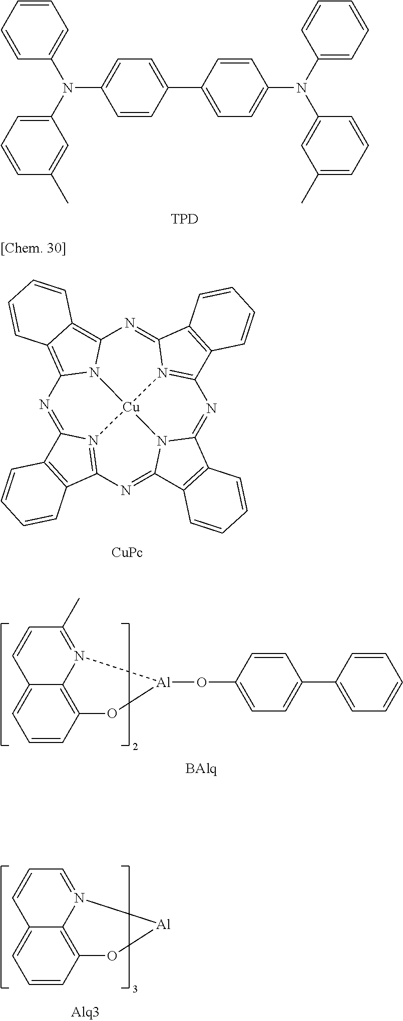

According to the present invention, it is possible to provide an organic electroluminescence device whose external quantum efficiency and driving durability are compatible with each other at a higher level compared to the conventional organic electroluminescence devices, and which has a small change in chromaticity before and after driving the device, while having an excellent property of blue chromaticity.

Although the present invention has been described with reference to detailed and specific embodiments thereof, it is obvious to those skilled in the art that various changes or modifications may be made without departing from the spirit and scope of the present invention.

The present application is based on Japanese Patent Application (Patent Application No. 2010-157351) filed on Jul. 9, 2010, the contents of which are herein incorporated by reference.

### EXPLANATION OF REFERENCE NUMERALS AND SYMBOLS

2: Substrate
3: Anode
4: Hole injection layer
5: Hole transporting layer
6: Light emitting layer
7: Hole blocking layer
8: Electron transporting layer
9: Cathode
10: Organic electroluminescence device
11: Organic layer
12: Protective layer
14: Adhesive layer
16: Sealing container
20: Light emission apparatus
30: Light scattering member
30A: Light incident surface
30B: Light exit surface
31: Transparent substrate
32: Fine particle
40: Illumination apparatus

1. An organic electroluminescence device comprising: a pair of electrodes; and a light emitting layer between the electrodes, on a substrate,
wherein a compound represented by the following Formula (1) and a compound represented by Formula (E-I) are contained in the light emitting layer:
(Cz)p-L-(A)q (1)
wherein, in Formula (1), Cz represents a substituted or unsubstituted arylcarbazolyl group or carbazolylaryl group, L represents a single bond, a substituted or unsubstituted arylene group, a substituted or unsubstituted cycloalkylene group or a substituted or unsubstituted aromatic heterocyclic ring, A represents a substituted or unsubstituted nitrogen-containing 6-membered aromatic heterocyclic ring, and each of p and q independently represents an integer of 1 to 6: 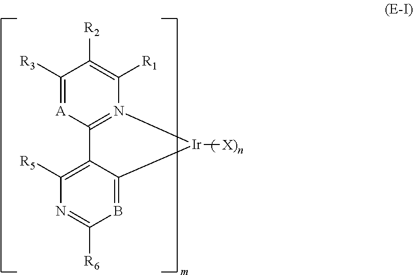
wherein, in Formula (E-I), A is C(R₄) or N, B is C(R₇) or N, each of R₁ to R₇ is independently a hydrogen atom, a cyano group, a hydroxyl group, a nitro group, a halogen atom, a substituted or unsubstituted alkyl group, a substituted or unsubstituted alkoxy group, a substituted or unsubstituted aryl group, a substituted or unsubstituted aryloxy group, a substituted or unsubstituted arylalkyl group, a substituted or unsubstituted arylalkoxy group, a substituted or unsubstituted arylamino group, a substituted or unsubstituted alkylamino group or a substituted or unsubstituted heterocyclic group, and each of any two or more adjacent substituents selected from the group consisting of R₁ to R₄, R₄ and R₅, and R₆ and R₇ may be linked with each other to form a saturated or unsaturated carbocyclic ring, or a saturated or unsaturated heterocyclic ring, X is a monoanionic bidentate ligand, m is 2 or 3, n is 0 or 1, and the sum of m and n is 3.

2. The organic electroluminescence device of claim 1, wherein the compound represented by Formula (1) is a compound represented by the following Formula (2). 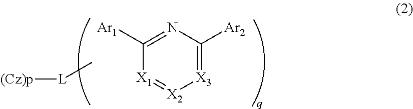
wherein, in Formula (2), Cz represents a substituted or unsubstituted arylcarbazolyl group or carbazolylaryl group, L represents a single bond, a substituted or unsubstituted arylene group, a substituted or unsubstituted cycloalkylene group or a substituted or unsubstituted aromatic heterocyclic ring, and is linked with a carbon atom of Ar₁, Ar₂, X₁, X₂ or X₃, each of Ar₁ and Ar₂ independently represents a substituted or unsubstituted aryl group or a substituted or unsubstituted aromatic heterocyclic group, and each of X₁, X₂ or X₃ independently represents a nitrogen atom or a carbon atom having a hydrogen atom or a substituent bonded thereto, and each of p and q independently represents an integer of 1 to 6.

3. The organic electroluminescence device of claim 2, wherein the compound represented by Formula (2) is a compound represented by the following Formula (3): 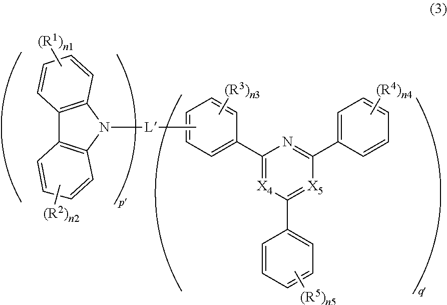
wherein, in Formula (3), each of X₄ and X₅ independently represents a nitrogen atom or a carbon atom having a hydrogen atom bonded thereto, and a ring containing X₄ and X₅ is pyridine or pyrimidine, L′ represents a single bond or a phenylene group, each of R¹ to R⁵ independently represents a fluorine atom, a methyl group, a phenyl group, a cyano group, a pyridyl group, a pyrimidyl group, a silyl group, a carbazolyl group or a tert-butyl group, each of n1 to n5 independently represents 0 or 1, and each of p′ and q′ independently represents 1 or 2.

4. The organic electroluminescence device of claim 1 wherein the compound represented by Formula (E-I) is a compound represented by the following Formula (E-II): 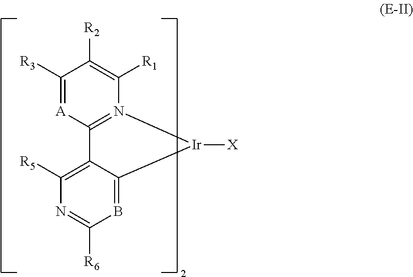
wherein, in Formula (E-II), A is C(R₄) or N, all of R₁, R₂ and R₄ are a hydrogen atom, R₃ is a hydrogen atom, or an electron donating group selected from the group consisting of a methyl group, a methoxy group, an isopropyl group, a phenyloxy group, a benzyloxy group, a dimethylamino group, a diphenylamino group, a pyrrolidinyl and a phenyl group, B is C(R₇) or N, each of R₅, R₆ and R₇ is independently a hydrogen atom, or an electron withdrawing group selected from the group consisting of a fluorine atom, a cyano group, a nitro group, a phenyl group substituted with a fluorine atom or a trifluoromethyl group and a trifluoromethyl group, and X is selected from the group consisting of acetylacetonate, hexafluoroacetylacetonate, picolinate, salicylanilide, quinolinecarboxylate, 8-hydroxyquinolinate, L-proline, 1,5-dimethyl-3-pyrazolecarboxylate, imineacetylacetonate, dibenzoylmethane, tetramethylheptandionate, 1-(2-hydroxyphenyl)pyrazolate and phenylpyrazole.

5. The organic electroluminescence device of claim 1, wherein the compound represented by Formula (E-I) is a compound represented by the following Formula (E-III): 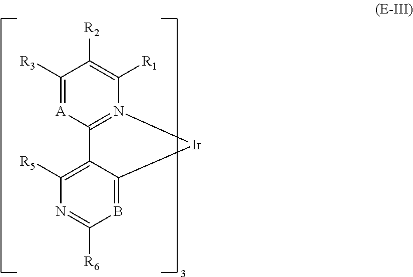
wherein, in Formula (E-III), A is C(R₄) or N, all of R₁, R₂ and R₄ are a hydrogen atom, R₃ is a hydrogen atom, or an electron donating group selected from the group consisting of a methyl group, a methoxy group, an isopropyl group, a phenyloxy group, a benzyloxy group, a dimethylamino group, a diphenylamino group, a pyrrolidinyl and a phenyl group, B is C(R₇) or N, each of R₅, R₆ and R₇ is independently a hydrogen atom, or an electron withdrawing group selected from the group consisting of a fluorine atom, a cyano group, a nitro group, a phenyl group substituted with a fluorine atom or a trifluoromethyl group and a trifluoromethyl group.

6. The organic electroluminescence device of claim 1, wherein in Formula (E-I), A is C(R₄) or N, all of R₁, R₂ and R₄ are a hydrogen atom, R₃ is a hydrogen atom, or an electron donating group selected from the group consisting of a methyl group and a dimethylamino group, B is C(R₇) or N, R₅ is a fluorine atom, R₆ is a fluorine atom or a cyano group, R₇ is a hydrogen atom or a cyano group, and X is a monoanionic bidentate ligand selected from the group consisting of acetylacetonate, picolinate and 1,5-dimethyl-3-pyrazolecarboxylate.

7. The organic electroluminescence device of claim 1, wherein the sum of the mass concentration of halogen elements selected from the group consisting of bromine, iodine and chlorine, which is contained in any of Formulas (1) to (3) contained in the light emitting layer, is 100 ppm or less.

8. A light emitting layer containing the composition according to claim 9.

9. A composition containing a compound represented by the following Formula (1) and a compound represented by the following Formula (E-I):
(Cz)p-L-(A)q (1)
wherein, in Formula (1), Cz represents a substituted or unsubstituted arylcarbazolyl group or carbazolylaryl group, L represents a single bond, a substituted or unsubstituted arylene group, a substituted or unsubstituted cycloalkylene group or a substituted or unsubstituted aromatic heterocyclic ring, A represents a substituted or unsubstituted nitrogen-containing 6-membered aromatic heterocyclic ring, and each of p and q independently represents an integer of 1 to 6: 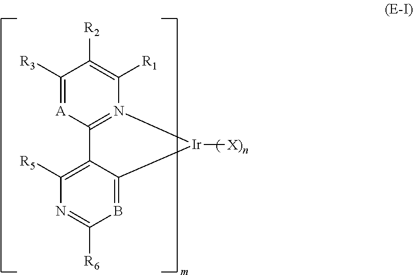
wherein, in Formula (E-I), A is C(R₄) or N, B is C(R₇) or N, each of R₁ to R₇ is independently a hydrogen atom, a cyano group, a hydroxyl group, a nitro group, a halogen atom, a substituted or unsubstituted alkyl group, a substituted or unsubstituted alkoxy group, a substituted or unsubstituted aryl group, a substituted or unsubstituted aryloxy group, a substituted or unsubstituted arylalkyl group, a substituted or unsubstituted arylalkoxy group, a substituted or unsubstituted arylamino group, a substituted or unsubstituted alkylamino group or a substituted or unsubstituted heterocyclic group, and each of any two or more adjacent substituents selected from the group consisting of R₁ to R₄, R₄ and R₅ and R₆ and R₇ may be linked with each other to form a saturated or unsaturated carbocyclic ring, or a saturated or unsaturated heterocyclic ring, X is a monoanionic bidentate ligand, m is 2 or 3, n is 0 or 1, and the sum of m and n is 3.

10. A light emission apparatus comprising the organic electroluminescence device of claim 1.

11. A display apparatus comprising the organic electroluminescence device of claim 1.

12. An illumination apparatus comprising the organic electroluminescence device of claim 1.

13. The composition of claim 9, wherein the compound represented by Formula (E-I) is a compound represented by the following Formula (E-II): 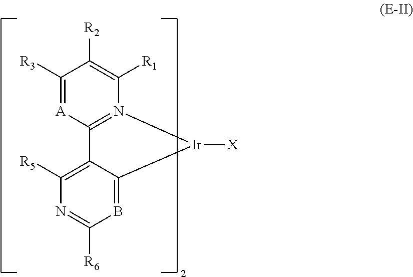
wherein, in Formula (E-II), A is C(R₄) or N, all of R₁, R₂ and R₄ are a hydrogen atom, R₃ is a hydrogen atom, or an electron donating group selected from the group consisting of a methyl group, a methoxy group, an isopropyl group, a phenyloxy group, a benzyloxy group, a dimethylamino group, a diphenylamino group, a pyrrolidinyl and a phenyl group, B is C(R₇) or N, each of R₅, R₆ and R₇ is independently a hydrogen atom, or an electron withdrawing group selected from the group consisting of a fluorine atom, a cyano group, a nitro group, a phenyl group substituted with a fluorine atom or a trifluoromethyl group and a trifluoromethyl group, and X is selected from the group consisting of acetylacetonate, hexafluoroacetylacetonate, picolinate, salicylanilide, quinolinecarboxylate, 8-hydroxyquinolinate, L-proline, 1,5-dimethyl-3-pyrazolecarboxylate, imineacetylacetonate, dibenzoylmethane, tetramethylheptandionate, 1-(2-hydroxyphenyl)pyrazolate and phenylpyrazole.

14. The composition of claim 9, wherein the compound represented by Formula (E-I) is a compound represented by the following Formula (E-III): 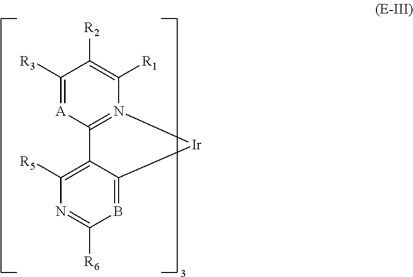
wherein, in Formula (E-III), A is C(R₄) or N, all of R₁, R₂ and R₄ are a hydrogen atom, R₃ is a hydrogen atom, or an electron donating group selected from the group consisting of a methyl group, a methoxy group, an isopropyl group, a phenyloxy group, a benzyloxy group, a dimethylamino group, a diphenylamino group, a pyrrolidinyl and a phenyl group, B is C(R₇) or N, each of R₅, R₆ and R₇ is independently a hydrogen atom, or an electron withdrawing group selected from the group consisting of a fluorine atom, a cyano group, a nitro group, a phenyl group substituted with a fluorine atom or a trifluoromethyl group and a trifluoromethyl group.

15. The composition of claim 9, wherein the compound represented by Formula (1) is a compound represented by the following Formula (2). 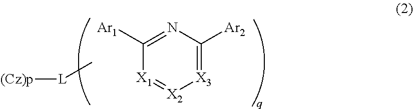
wherein, in Formula (2), Cz represents a substituted or unsubstituted arylcarbazolyl group or carbazolylaryl group, L represents a single bond, a substituted or unsubstituted arylene group, a substituted or unsubstituted cycloalkylene group or a substituted or unsubstituted aromatic heterocyclic ring, and is linked with a carbon atom of Ar₁, Ar₂, X₁, X₂ or X₃, each of Ar₁ and Ar₂ independently represents a substituted or unsubstituted aryl group or a substituted or unsubstituted aromatic heterocyclic group, and each of X₁, X₂ or X₃ independently represents a nitrogen atom or a carbon atom having a hydrogen atom or a substituent bonded thereto, and each of p and q independently represents an integer of 1 to 6.

16. The composition of claim 9, wherein the compound represented by Formula (2) is a compound represented by the following Formula (3): 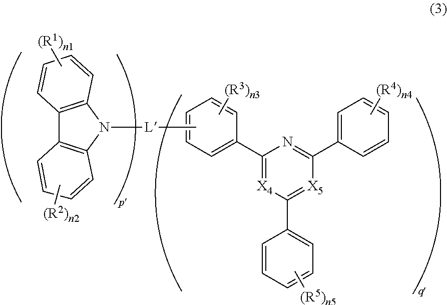
wherein, in Formula (3), each of X₄ and X₅ independently represents a nitrogen atom or a carbon atom having a hydrogen atom bonded thereto, and a ring containing X₄ and X₅ is pyridine or pyrimidine, L′ represents a single bond or a phenylene group, each of R¹ to R⁵ independently represents a fluorine atom, a methyl group, a phenyl group, a cyano group, a pyridyl group, a pyrimidyl group, a silyl group, a carbazolyl group or a tert-butyl group, each of n1 to n5 independently represents 0 or 1, and each of p′ and q′ independently represents 1 or 2.
